(19) United States
(12) Patent Application Publication
(10) Pub. No.: US 2025/0087484 A1
(43) Pub. Date: Mar. 13, 2025

(54) Gallium-Oxide-On-Silicon (GaOxS)

(71) Applicant: Board of Regents, The University of Texas System, Austin, TX (US)

(72) Inventors: Alexander A. Demkov, Austin, TX (US); Tobias Hadamek, Austin, TX (US); Agham Posadas, Round Rock, TX (US)

(21) Appl. No.: 18/911,910

(22) Filed: Oct. 10, 2024

Related U.S. Application Data
(63) Continuation-in-part of application No. PCT/US2023/017927, filed on Apr. 7, 2023.
(60) Provisional application No. 63/329,729, filed on Apr. 11, 2022.

(51) Int. Cl. H01L 21/02; C30B 23/02; C30B 25/18; C30B 29/16

(52) U.S. Cl. CPC H01L 21/02554; C30B 23/025; C30B 25/18; C30B 29/16; H01L 21/02381; H01L 21/02488; H01L 21/02609

(57) ABSTRACT

Various embodiments of the present technology generally relate to silicon (Si)-based semiconductor wafer and methods of manufacturing the same. In an aspect, an epitaxial stack structure is provided in which a thin film of gallium oxide (Ga₂O₃) is grown on a Si-substrate using one or more metal-oxide buffer layers. The metal-oxide buffer oxide layer may grow as a single crystal layer on the Si surface without oxidizing the underlying Si during growth of Ga₂O₃. Moreover, the interplanar spacing of metal oxide forming the buffer layer may approximately match one or more of the lattice parameters of Ga₂O₃ such to allow for stable stacking of Ga₂O₃ along its planes. Example buffer layers include epitaxial alumina, strontium titanate (STO), magnesium oxide (MgO), a rare earth oxide, and combinations of the same. Further described are power electronics devices advantageously integrating the wafers and manufacturing methods of the present technology.

### CROSS-REFERENCE TO RELATED APPLICATIONS

This application claims the benefit of and priority to International Application No. PCT/US2023/017927, filed on Apr. 7, 2023, which claims benefit and priority to U.S. Provisional Application No. 63/329,729, filed on Apr. 11, 2022, both of which are incorporated by reference herein in their entirety.

### FEDERALLY FUNDED RESEARCH

This invention was made with government support under Grant No. FA9550-18-1-0053 and Grant No. FA9550-12-1-0494 awarded by the Air Force Office of Scientific Research. The government has certain rights in the invention.

### TECHNICAL FIELD

Various embodiments of the present technology generally relate to silicon (Si)-based semiconductor manufacturing. More specifically, some embodiments of the present technology relate to systems and methods for integrating gallium oxide thin films on silicon (001) via a buffer layer.

### BACKGROUND

Ga₂O₃ is a promising wide band-gap semiconductor with potential applications in high power electronics, solar-blind ultraviolet (UV) photodetectors, UV-transparent conductive films, UV detectors, electro-optical devices, and possibly microwave switching and amplification [1-3, 106, 107]. Benefits of the material are an ultra-wide band gap of ˜5 eV, transparency into the deep-UV spectral range, and the availability of relatively low-cost bulk single crystals, compared to other wide band gap materials. Ga₂O₃ has a high theoretical breakdown field of about 8 MV/cm [108], higher than GaN (3.3 MV/cm) and SiC (2.5 MV/cm), which are, besides the ubiquitous Si (0.3 MV/cm), the most commonly used materials in high-power electronics [4, 5]. Larger breakdown fields can lead to the miniaturization of power electronic devices with associated reductions in cost and weight. The enhanced radiation hardness of Ga₂O₃ [6] additionally makes it suitable for space applications. Today an estimated 30% of all electricity flows through power electronics and this is projected to reach 80% in the future [7]. Efficient n-type doping of Ga₂O₃ can be achieved by Si, Ge, Sn and Nb incorporation [3]. Recently p-type doping with H has been demonstrated [8].

Six different polymorphs of Ga₂O₃ have been described: monoclinic (β), rhombohedral/trigonal (α), cubic defective spinel (γ), cubic bixbyite (δ), orthorhombic (κ), and hexagonal (ε) [9]. All Ga₂O₃ polymorphs are based on a close-packed arrangement of oxide ions (hexagonal close-packed (hcp) or face-centered cubic (fcc); distorted to some degree in most cases), and Ga ions partially fill octahedral and tetrahedral voids, which show local disorder for some structures [9]. δ-Ga₂O₃ has been speculated to be a mixture of β- and ε—Ga₂O₃ [9], and hexagonal ε—Ga₂O₃ has been shown by electron microscopy to be a multi-domain structure of orthorhombic κ-Ga₂O₃ (isostructural to κ-Al₂O₃) [10]. Recently, the orthorhombic polymorph has been referred to as either as ε—Ga₂O₃ [11, 12] or as κ-Ga₂O₃ [10]; due to the analogy with κ-Al₂O₃ and to avoid ambiguity, it will be referred to herein as κ-Ga₂O₃. The crystallographic relationships between κ-, β-, and γ-polymorphs have been described [13]. In summary, there appear to be only four truly distinct polymorphs: α, β, γ and κ.

β-Ga₂O₃ is the stable polymorph under normal conditions and crystallizes in space group C2/m with lattice parameters a=12.22 Å, b=3.04 Å, c=5.80 Å and β=103.75° [9]. A major advantage of β-Ga₂O₃ is that low-cost and high-quality single crystals are available: 4 inch β-Ga₂O₃ wafers are commercially available [14], and 6 inch wafers are in development [15]. The production of 6 inch β-Ga₂O₃ bulk wafers is projected to be about a ⅓ cheaper than the production of 6″ SiC wafers [7]. A major disadvantage of Ga₂O₃, however, is the low thermal conductivity of 0.1-0.3 Wcm⁻¹K⁻¹ [5, 108], which is detrimental for high-power applications that dissipate energy in the form of Joule heating [16, 109]. Therefore, the integration of epitaxial Ga₂O₃ onto Si would be advantageous due to the 750% higher thermal conductivity of Si compared to Ga₂O₃ [17, 110]. Currently, large-scale epitaxial films of Ga₂O₃ are unavailable commercially and bulk crystal wafers are only available up to 4 inch diameter [111]. Another benefit would be cost reduction [17], based on even larger diameter Ga₂O₃ substrates and direct process integration with Si technology. Epitaxial growth onto Si (001) wafers would open up numerous avenues for the large scale integration but, unfortunately, Ga₂O₃ cannot be directly grown on Si.

The challenge of epitaxial integration is the structural difference between silicon and gallium oxide. Si has a crystal structure with cubic symmetry, whereas β-Ga₂O₃ has monoclinic symmetry. This symmetry mismatch will unavoidably lead to a multi-orientation growth of epitaxial domains [18, 19]. Crystal grain boundaries between epitaxial domains and defects arising from the lattice mismatch to the substrate can be pernicious to the electronic properties of the epilayer.

In prior work on the integration of Ga₂O₃ with Si, a textured 1 μm β-Ga₂O₃ film was grown by HVPE on Si (111) with a ˜100 nm 3C—SiC (zinc blende structure) buffer layer [24]; randomly oriented β-Ga₂O₃ rods as well as nanosheets were grown by chemical vapor deposition (CVD) on 3C—SiC/Si (001) [25, 26]; and polycrystalline β-Ga₂O₃ was grown directly on Si (001) and Si (111) without buffer layers by pulsed laser deposition (PLD) [27]. β-Ga₂O₃ of unclear structural orientation was also grown by HVPE on SiC-buffered Si (001), Si (011) and Si (111) [28, 29]. Additional prior work includes the deposition of amorphous Ga₂O₃ on Si (001) by CVD [30], and crystallization of amorphous Ga₂O₃ on Si (111) by annealing leading to grains of β-Ga₂O₃ [31]. Recently, β-Ga₂O₃ wafers have been integrated directly, and with an alumina interlayer, onto Si and SiC wafers by wafer bonding and ion cutting [32, 33].

In many instances, Ga₂O₃ has been grown heteroepitaxially on widely available, high-structural-quality and low-cost c-plane sapphire substrates by a variety of physical and chemical vapor deposition methods: MBE [34-43], MOCVD [42, 44, 45], PLD [42, 46], rf-sputtering [47], CVD [11, 48, 49], HVPE [50-53], PVD [54, 55]. Depending on the growth method, growth parameters such as temperature and post-growth treatments, various phases and mixtures of phases of epitaxial Ga₂O₃ are created on c-plane sapphire: β-Ga₂O₃ (2̅01), (101) and (310), α-Ga₂O₃ (00.1), γ-Ga₂O₃ (111) and κ-Ga₂O₃ (001) (wrongly assigned ¿—Ga₂O₃ (00.1) [10]). The corundum crystal structure of sapphire or α-Al₂O₃ (trigonal space group R3c, 167), consists of a hcp oxygen framework with two-thirds of the octahedral interstices filled with Al [56]. It has been observed by synchrotron-based x-ray diffraction (XRD) that when Ga₂O₃ is grown by oxygen plasma-assisted MBE (PAMBE) on c-plane α-Al₂O₃, isostructural growth of α-Ga₂O₃ is observed for the first 33 Å (for a 2.3 Å/min growth rate and 600° C. substrate temperature), which then converts to (2̅01)-oriented β-Ga₂O₃ on top [40]. The (2̅01) plane of β-Ga₂O₃ has a similar local oxygen arrangement as the c-plane of α-Al₂O₃[54]. β-Ga₂O₃ with (2̅01)-, (101)- and (310)-orientations has been formed after heat treatment of κ-Ga₂O₃ on sapphire [13, 57], and the (310) and (101) orientations grow as minority phases for (2̅01)—Ga₂O₃ on sapphire [50, 54]. For β-Ga₂O₃ grown on vicinal α-Al₂O₃, the six in-plane orientations of (2̅01) that arise on non-vicinal substrates [54], are effectively reduced to one dominant one [49, 50], and a room temperature electron mobility of 106.6 cm²V⁻¹s⁻¹ can be achieved at a doping concentration of 4.83×10¹⁷ cm⁻³ [49]. For comparison, the record value for room temperature mobility of 184 cm²V⁻¹s⁻¹ in β-Ga₂O₃ was achieved with a homoepitaxial film grown by MOVPE at a doping concentration of 2.5×10¹⁶ cm⁻³ [58], and the theoretically predicted limit of the room temperature mobility of β-Ga₂O₃ is 200 cm²V⁻¹s⁻¹ [59]. (111)-oriented γ-Al₂O₃ with two in-plane rotational variants can be grown on Si (001) by e-beam evaporation of Al₂O₃ at elevated temperature, with a pseudomorphic γ-Al₂O₃ (001) interlayer showing an atomically abrupt interface between Al₂O₃ and Si [60-63]. The observation of relatively large domains with average lateral extensions of more than 100 nm for γ-Al₂O₃ (111) on Si (001) was reported [60]. γ-Ga₂O₃ in (001)-orientation has been epitaxially stabilized on spinel MgAl₂O₄ (001) substrates [65], and on MgO (001) [66].

Previous attempts at integrating Ga₂O₃ on Si highlight the difficulty of this process. A textured 1-μm-thick β-Ga₂O₃ film was grown by hydride vapor phase epitaxy (HVPE) on Si (111) with a ˜100-nm 3C—SiC (zincblende structure) buffer layer [1̅12]; randomly oriented β-Ga₂O₃ rods as well as nanosheets were grown by CVD on 3C—SiC/Si (001) [113, 114]; and polycrystalline β-Ga₂O₃ was grown directly on Si (001) and Si (111) without buffer layers using pulsed laser deposition (PLD) [115]. β-Ga₂O₃ of unspecified structural orientation was also grown by HVPE on SiC-buffered Si (001), Si (011) and Si (111) [116, 117]. Additional prior work includes the deposition of amorphous Ga₂O₃ on Si (001) by CVD [118], and crystallization of amorphous Ga₂O₃ on Si (111) by annealing, leading to grains of β-Ga₂O₃ [119]. Recently, β-Ga₂O₃ wafers have been integrated directly onto Si and SiC wafers with an alumina interlayer using wafer bonding and ion cutting [120, 121].

Epitaxial Ga₂O₃ thin films have previously been grown on some oxide substrates. The (100)-oriented epitaxial relationship was found for Ga₂O₃ grown by MOCVD on SrTiO₃ (STO) (001) after annealing the sample above 1000° C. [122]. Other examples of Ga₂O₃ growth on oxide surfaces include the deposition of κ-Ga₂O₃ (001) on STO (111) via tin-assisted pulsed-laser deposition and by mist CVD [124]. We have also recently reported the integration of β-Ga₂O₃ by plasma-assisted molecular beam epitaxy onto a γ-Al₂O₃ (111) buffer layer grown at 840° C. by e-beam evaporation on a clean Si (001) surface [125].

Integration of β-Ga₂O₃ on Si (001) is highly challenging due to multiple fundamental differences between the sesquioxide and the semiconductor substrate.

### REFERENCES

[1] S. J. Pearton, J. Yang, P. H. Cary, F. Ren, J. Kim, M. J. Tadjer, and M. A. Mastro, Appl. Phys. Rev. 5, 011301 (2018).
[2] B. Bayraktaroglu, “Assessment of Gallium Oxide Technology”-Air Force Research Laboratory Report No. AFRL-RY—WP-TR-2017-0167 (Wright-Patterson Air Force Base, OH, 2017).
[3] J. Zhang, J. Shi, D. C. Qi, L. Chen, and K. H. L. Zhang, APL Mater. 8, (2020).
[4] H. Zhang, L. Yuan, X. Tang, J. Hu, J. Sun, Y. Zhang, Y. Zhang, and R. Jia, IEEE Trans. Power Electron. 35, 5157 (2020).
[5] H. Murakami, M. Higashiwaki, Y. Kumagai, T. Masui, K. Sasaki, A. Kuramata, S. Yamakoshi, and A. Koukitu, Semicond. Sci. Technol. 31, 034001 (2016).
[6] J. Kim, S. J. Pearton, C. Fares, J. Yang, F. Ren, S. Kim, and A. Y. Polyakov, J. Mater. Chem. C 7, 10 (2019).
[7] S. B. Reese, T. Remo, J. Green, and A. Zakutayev, Joule 3, 903 (2019).
[8] M. M. Islam, M. O. Liedke, D. Winarski, M. Butterling, A. Wagner, P. Hosemann, Y. Wang, B. Uberuaga, and F. A. Selim, Sci. Rep. 10, 1 (2020).
[9] H. Y. Playford, A. C. Hannon, E. R. Barney, and R. I. Walton, Chem.-A Eur. J. 19, 2803 (2013).
[10] I. Cora, F. Mezzadri, F. Boschi, M. Bosi, M. Čaplovičová, G. Calestani, I. Dódony, B. Pécz, and R. Fornari, CrystEngComm 19, 1509 (2017).
[11] D. Oka, S. Yusa, K. Kimura, A. K. R. Ang, N. Happo, K. Hayashi, and T. Fukumura, Jpn. J. Appl. Phys. (2020).
[12] H. Nishinaka, H. Komai, D. Tahara, Y. Arata, and M. Yoshimoto, (2018).
[13] I. Cora, Z. Fogarassy, R. Fornari, M. Bosi, A. Rečnik, and B. Pécz, Acta Mater. 183, 216 (2020).
[14] ‘Tamura Corp β-Ga₂O₃ substrate specifications sheet’, accessed 2020 May 20. https://www.tamuracorp.com/file.jsp?id=13281.
[15] A. E. Romanov, S. I. Stepanov, V. I. Nikolaev, and V. E. Bougrov, Rev. Adv. Mater. Sci (2016).
[16] M. Higashiwaki, K. Sasaki, A. Kuramata, T. Masui, and S. Yamakoshi, Phys. Status Solidi Appl. Mater. Sci. 211, 21 (2014).
[17] O. Hilt, E. B. Treidel, M. Wolf, C. Kuring, K. Tetzner, H. Yazdani, A. Wentzel, and J. Würfl, IET Power Electron. 12, 3919 (2019).
[18] M. Grundmann, T. Böntgen, and M. Lorenz, Phys. Rev. Lett. 105, 1 (2010).
[19] M. Grundmann, Phys. Status Solidi Basic Res. 248, 805 (2011).
[20] D. G. Schlom, APL Mater. 3, 1 (2015).
[21] K. J. Hubbard and D. G. Schlom, J. Mater. Res. 11, 2757 (1996).
[22] H. W. Xue, Q. M. He, G. Z. Jian, S. B. Long, T. Pang, and M. Liu, Nanoscale Res. Lett. 13, 1 (2018).
[23] P. Vogt, F. V. E. Hensling, K. Azizie, C. S. Chang, D. Turner, J. Park, J. P. McCandless, H. Paik, B. J. Bocklund, G. Hoffman, and others, ArXiv Prepr. ArXiv2011.00084 (2020).
[24] S. A. Kukushkin, V. I. Nikolaev, A. V. Osipov, E. V. Osipova, A. I. Pechnikov, and N. A. Feoktistov, Phys. Solid State 58, 1876 (2016).
[25] S. Rafique, L. Han, C. A. Zorman, and H. Zhao, Cryst. Growth Des. 16, 511 (2016).
[26] S. Rafique, L. Han, J. Lee, X.-Q. Zheng, C. A. Zorman, P. X.-L. Feng, and H. Zhao, J. Vac. Sci. Technol. B, Nanotechnol. Microelectron. Mater. Process. Meas. Phenom. 35, 011208 (2017).
[27] Y. Berencen, Y. Xie, M. Wang, S. Prucnal, L. Rebohle, and S. Zhou, Semicond. Sci. Technol. 34, 0 (2019).
[28] A. V. Osipov, A. S. Grashchenko, S. A. Kukushkin, V. I. Nikolaev, E. V. Osipova, A. I. Pechnikov, and I. P. Soshnikov, Contin. Mech. Thermodyn. 30, 1059 (2018).
[29] A. S. Grashchenko, S. A. Kukushkin, V. I. Nikolaev, A. V. Osipov, E. V. Osipova, and I. P. Soshnikov, Phys. Solid State 60, 852 (2018).
[30] D. H. Kim, S. H. Yoo, T. M. Chung, K. S. An, H. S. Yoo, and Y. Kim, Bull. Korean Chem. Soc. (2002).
[31] H. W. Kim, N. H. Kim, and C. Lee, Br. Ceram. Trans. (2004).
[32] W. Xu, X. Wang, Y. Wang, T. You, X. Ou, G. Han, H. Hu, S. Zhang, F. Mu, T. Suga, Y. Zhang, and Y. Hao, in Tech. Dig.-Int. Electron Devices Meet. IEDM (2019), pp. 274-277.
[33] Y. B. Wang, W. H. Xu, T. G. You, F. W. Mu, H. D. Hu, Y. Liu, H. Huang, T. Suga, G. Q. Han, X. Ou, and Y. Hao, Sci. China Physics, Mech. Astron. 63, 1 (2020).
[34] T. Oshima, T. Okuno, and S. Fujita, Japanese J. Appl. Physics, Part 1 Regul. Pap. Short Notes Rev. Pap. 46, 7217 (2007).
[35] M.-Y. Tsai, O. Bierwagen, M. E. White, and J. S. Speck, J. Vac. Sci. Technol. A Vacuum, Surfaces, Film. 28, 354 (2010).
[36] S. J. Hao, M. Hetzl, F. Schuster, K. Danielewicz, A. Bergmaier, G. Dollinger, Q. L. Sai, C. T. Xia, T. Hoffmann, M. Wiesinger, S. Matich, W. Aigner, and M. Stutzmann, J. Appl. Phys. 125, (2019).
[37] P. Vogt, O. Brandt, H. Riechert, J. Lahnemann, and O. Bierwagen, Phys. Rev. Lett. 119, 6 (2017).
[38] M. Kracht, A. Karg, J. Schörmann, M. Weinhold, D. Zink, F. Michel, M. Rohnke, M. Schowalter, B. Gerken, A. Rosenauer, P. J. Klar, J. Janek, and M. Eickhoff, Phys. Rev. Appl. 8, 1 (2017).
[39] J. Wei, K. Kim, F. Liu, P. Wang, X. Zheng, Z. Chen, D. Wang, A. Imran, X. Rong, X. Yang, F. Xu, J. Yang, B. Shen, and X. Wang, J. Semicond. 40, (2019).
[40] Z. Cheng, M. Hanke, P. Vogt, O. Bierwagen, and A. Trampert, Appl. Phys. Lett. 111, 1 (2017).
[41] S. Ghose, M. S. Rahman, J. S. Rojas-Ramirez, M. Caro, R. Droopad, A. Arias, and N. Nedev, J. Vac. Sci. Technol. B, Nanotechnol. Microelectron. Mater. Process. Meas. Phenom. 34, 02L109 (2016).
[42] R. Schewski, G. Wagner, M. Baldini, D. Gogova, Z. Galazka, T. Schulz, T. Remmele, T. Markurt, H. Von Wenckstern, M. Grundmann, O. Bierwagen, P. Vogt, and M. Albrecht, Appl. Phys. Express 8, (2015).
[43] S. Nakagomi and Y. Kokubun, Phys. Status Solidi Basic Res. 253, 1217 (2016).
[44] F. Mezzadri, G. Calestani, F. Boschi, D. Delmonte, M. Bosi, and R. Fornari, Inorg. Chem. 55, 12079 (2016).
[45] V. Gottschalch, S. Merker, S. Blaurock, M. Kneiß, U. Teschner, M. Grundmann, and H. Krautscheid, J. Cryst. Growth 510, 76 (2019).
[46] M. Kneiß, A. Hassa, D. Splith, C. Sturm, H. Von Wenckstern, T. Schultz, N. Koch, M. Lorenz, and M. Grundmann, APL Mater. 7, (2019).
[47] H. C. Kang, Mater. Lett. 119, 123 (2014).
[48] S. Rafique, L. Han, A. T. Neal, S. Mou, M. J. Tadjer, R. H. French, and H. Zhao, Appl. Phys. Lett. 109, (2016).
[49] S. Rafique, L. Han, A. T. Neal, S. Mou, J. Boeckl, and H. Zhao, Phys. Status Solidi Appl. Mater. Sci. 215, 1 (2018).
[50] Y. Oshima, E. G. Víllora, and K. Shimamura, J. Cryst. Growth 410, 53 (2015).
[51] S. Shapenkov, O. Vyvenko, E. Ubyivovk, O. Medvedev, G. Varygin, A. Chikiryaka, A. Pechnikov, M. Scheglov, S. Stepanov, and V. Nikolaev, Phys. Status Solidi Appl. Mater. Sci. 1900892, 1 (2020).
[52] V. I. Nikolaev, A. I. Pechnikov, S. I. Stepanov, I. P. Nikitina, A. N. Smirnov, A. V. Chikiryaka, S. S. Sharofidinov, V. E. Bougrov, and A. E. Romanov, Mater. Sci. Semicond. Process. 47, 16 (2016).
[53] Y. Oshima, E. G. Víllora, and K. Shimamura, Appl. Phys. Express 8, 4 (2015).
[54] S. Nakagomi and Y. Kokubun, J. Cryst. Growth 349, 12 (2012).
[55] G. V. Chaplygin and S. A. Semiletov, Thin Solid Films 32, 321 (1976).
[56] H. P. Pinto, R. M. Nieminen, and S. D. Elliott, Phys. Rev. B 70, 125402 (2004).
[57] R. Fornari, M. Pavesi, V. Montedoro, D. Klimm, F. Mezzadri, I. Cora, B. Pécz, F. Boschi, A. Parisini, A. Baraldi, C. Ferrari, E. Gombia, and M. Bosi, Acta Mater. 140, 411 (2017).
[58] Z. Feng, A. F. M. Anhar Uddin Bhuiyan, M. R. Karim, and H. Zhao, Appl. Phys. Lett. 114, (2019).
[59] N. Ma, N. Tanen, A. Verma, Z. Guo, T. Luo, H. (Grace) Xing, and D. Jena, Appl. Phys. Lett. 109, 1 (2016).
[60] C. Merckling, M. El-Kazzi, G. Saint-Girons, G. Hollinger, L. Largeau, G. Patriarche, V. Favre-Nicolin, and O. Marty, J. Appl. Phys. 102, (2007).
[61] C. Merckling, M. El-Kazzi, G. Delhaye, M. Gendry, G. Saint-Girons, G. Hollinger, L. Largeau, and G. Patriarche, Appl. Phys. Lett. 89, 87 (2006).
[62] C. Merckling, M. El-Kazzi, V. Favre-Nicolin, M. Gendry, Y. Robach, G. Grenet, and G. Hollinger, Thin Solid Films 515, 6479 (2007).
[63] M. El Kazzi, M. Silly, F. Sirotti, C. Merckling, G. Saint-Girons, G. Grenet, and G. Holliger, Appl. Phys. Lett. 97, 1 (2010).
[64] M. Zinkevich and F. Aldinger, J. Am. Ceram. Soc. (2004).
[65] T. Oshima, Y. Kato, E. Magome, E. Kobayashi, and K. Takahashi, Jpn. J. Appl. Phys. 58, (2019).
[66] S. Nakagomi and Y. Kokubun, J. Cryst. Growth 479, 67 (2017).
[67] M. El Kazzi, C. Merckling, G. Grenet, G. Saint-Girons, M. Silly, F. Sirotti, and G. Hollinger, MRS Symp. Proc. 1155, 1 (2009).
[68] P. J. Cumpson and M. P. Seah, Surf. Interface Anal. 25, 430 (1997).
[69] T. Schoonjans, A. Brunetti, B. Golosio, M. Sanchez Del Rio, V. A. Solé, C. Ferrero, and L. Vincze, Spectrochim. Acta-Part B At. Spectrosc. 66, 776 (2011).
[70] P. Vogt and O. Bierwagen, Phys. Rev. Mater. 2, 1 (2018).
[71] T. Hahn, editor, International Tables for Crystallography. Vol. A., 5th ed. (Kluwer Academic Publishers, Dordrecht, 2002).
[72] G. Schmitz, P. Gassmann, and R. Franchy, J. Appl. Phys. 83, 2533 (1998).
[73] R. Yokoyama, K. Omote, K. Endo, and R. Matsuo, U.S. Pat. No. 6,937,694 B2 (2005).
[74] M. Birkholz, Thin Film Analysis by X-Ray Scattering (John Wiley & Sons, 2006).
[75] M.-Y. Tsai, O. Bierwagen, M. E. White, and J. S. Speck, J. Vac. Sci. Technol. A Vacuum, Surfaces, Film. 28, 354 (2010).
[76] S. Ghose, M. S. Rahman, J. S. Rojas-Ramirez, M. Caro, R. Droopad, A. Arias, and N. Nedev, J. Vac. Sci. Technol. B, Nanotechnol. Microelectron. Mater. Process. Meas. Phenom. 34, 02L109 (2016).
[77] H. C. Kang, Mater. Lett. 119, 123 (2014).
[78] R. Schewski, K. Lion, A. Fiedler, C. Wouters, A. Popp, S. V. Levchenko, T. Schulz, M. Schmidbauer, S. Bin Anooz, R. Grüneberg, Z. Galazka, G. Wagner, K. Irmscher, M. Scheffler, C. Draxl, and M. Albrecht, APL Mater. 7, (2019).
[79] P. Mazzolini, A. Falkenstein, C. Wouters, R. Schewski, T. Markurt, Z. Galazka, M. Martin, M. Albrecht, and O. Bierwagen, APL Mater. 8, (2020).
[80] S. Hofmann, Auger- and X-Ray Photoelectron Spectroscopy in Materials Science (Springer Berlin Heidelberg, Berlin, Heidelberg, 2013).
[81] M. P. Seah, J. Electron Spectros. Relat. Phenomena 71, 191 (1995).
[82] Materials, A. S. for T. and. Standard practice for calibration of the electron binding-energy scale of an x-ray photoelectron spectrometer. E 2108-00 1-16 (2000) doi: 10.1520/E2108-10.
[83] P. J. Cumpson and M. P. Seah, Surf. Interface Anal. 25, 430 (1997).
[84] J. H. Scofield, J. Electron Spectros. Relat. Phenomena 8, 129 (1976).
[85] Y. Wei, X. Hu, Y. Liang, D. C. Jordan, B. Craigo, R. Droopad, Z. Yu, A. Demkov, J. L. Edwards, and W. J. Ooms, J. Vac. Sci. Technol. B Microelectron. Nanom. Struct. 20, 1402 (2002).
[86] C. Merckling, M. El-Kazzi, G. Saint-Girons, G. Hollinger, L. Largeau, G. Patriarche, V. Favre-Nicolin, and O. Marty, J. Appl. Phys. 102, (2007).
[87] Villars, P. & Cenzual, K. Pearson's Crystal Data: Crystal Structure Database for Inorganic Compounds (on DVD), Release 2017/18, ASM International®. (2017).
[88] C. Merckling, M. El-Kazzi, V. Favre-Nicolin, M. Gendry, Y. Robach, G. Grenet, and G. Hollinger, Thin Solid Films 515, 6479 (2007).
[89] M. Björck and G. Andersson, J. Appl. Crystallogr. 40, 1174 (2007).
[90] C. Merckling, M. El-Kazzi, G. Delhaye, M. Gendry, G. Saint-Girons, G. Hollinger, L. Largeau, and G. Patriarche, Appl. Phys. Lett. 89, 87 (2006).
[91] M. El Kazzi, M. Silly, F. Sirotti, C. Merckling, G. Saint-Girons, G. Grenet, and G. Holliger, Appl. Phys. Lett. 97, 1 (2010).
[92] P. Vogt and O. Bierwagen, Phys. Rev. Mater. 2, 1 (2018).
[93] H. Lipson, J. I. Langford, and H.-C. Hu., in Int. Tables Crystallogr. (2006). Vol. C, edited by E. Prince, 1st ed. (International Union of Crystallography (IUCr), 2006), pp. 596-598.
[94] B. B. He, in Int. Tables Crystallogr. (2019). Vol. H, edited by C. J. Gilmore, J. A. Kaduk, and H. Schenk (International Union of Crystallography (IUCr), 2019), pp. 130-131.
[95] J. Als-Nielsen and D. McMorrow, Elements of Modern X-Ray Physics (John Wiley & Sons, 2011).
[96] K. Momma and F. Izumi, J. Appl. Crystallogr. 44, 1272 (2011).
[97] J. H. Hubbell and S. M. Seltzer, NIST Standard Reference Database 126: Tables of X-Ray Mass Attenuation Coefficients and Mass Energy-Absorption Coefficients from 1 KeV to 20 MeV for Elements Z=1 to 92 and 48 Additional Substances of Dosimetric Interest (National Institute of Standards and Technology, 2004).
[98] J. Wei, K. Kim, F. Liu, P. Wang, X. Zheng, Z. Chen, D. Wang, A. Imran, X. Rong, X. Yang, F. Xu, J. Yang, B. Shen, and X. Wang, J. Semicond. 40, (2019).
[99] G. Kresse and J. Furthmüller, Phys. Rev. B—Condens. Matter Mater. Phys. 54, 11169 (1996).
[100] P. E. Blöchl, Phys. Rev. B 50, 17953 (1994).
[101] V. M. Bermudez, Chem. Phys. 323, 193 (2006).
[102] T. Zacherle, P. C. Schmidt, and M. Martin, Phys. Rev. B—Condens. Matter Mater. Phys. (2013).
[103] W. Sun and G. Ceder, Surf. Sci. 617, 53 (2013).
[104] J. R. Rumble, editor, in CRC Handb. Chem. Phys., 101st ed. (CRC Press/Taylor & Francis, Boca Raton, FL, 2020).
[105] R. Schewski, K. Lion, A. Fiedler, C. Wouters, A. Popp, S. V. Levchenko, T. Schulz, M. Schmidbauer, S. Bin Anooz, R. Grüneberg, Z. Galazka, G. Wagner, K. Irmscher, M. Scheffler, C. Draxl, and M. Albrecht, APL Mater. 7, (2019).
[106] S. J. Pearton, J. Yang, P. H. Cary, F. Ren, J. Kim, M. J. Tadjer, and M. A. Mastro, Appl. Phys. Rev. 5, 011301 (2018).
[107] B. Bayraktaroglu, Assessment of Gallium Oxide Technology (Wright-Patterson Air Force Base, OH, 2017).
[108] H. Murakami, M. Higashiwaki, Y. Kumagai, T. Masui, K. Sasaki, A. Kuramata, S. Yamakoshi, and A. Koukitu, Semicond. Sci. Technol. 31, 034001 (2016).
[109] M. Higashiwaki, K. Sasaki, A. Kuramata, T. Masui, and S. Yamakoshi, Phys. Status Solidi Appl. Mater. Sci. 211, 21 (2014).
[110] O. Hilt, E. B. Treidel, M. Wolf, C. Kuring, K. Tetzner, H. Yazdani, A. Wentzel, and J. Würfl, IET Power Electron. 12, 3919 (2019).
[111] Nov. Cryst. Technol. Inc. (2021).
[1̅12] S. A. Kukushkin, V. I. Nikolaev, A. V. Osipov, E. V. Osipova, A. I. Pechnikov, and N. A. Feoktistov, Phys. Solid State 58, 1876 (2016).
[113] S. Rafique, L. Han, C. A. Zorman, and H. Zhao, Cryst. Growth Des. 16, 511 (2016).
[114] S. Rafique, L. Han, J. Lee, X.-Q. Zheng, C. A. Zorman, P. X.-L. Feng, and H. Zhao, J. Vac. Sci. Technol. B, Nanotechnol. Microelectron. Mater. Process. Meas. Phenom. 35, 011208 (2017).
[115] Y. Berencen, Y. Xie, M. Wang, S. Prucnal, L. Rebohle, and S. Zhou, Semicond. Sci. Technol. 34, 035001 (2019).
[116] A. V. Osipov, A. S. Grashchenko, S. A. Kukushkin, V. I. Nikolaev, E. V. Osipova, A. I. Pechnikov, and I. P. Soshnikov, Contin. Mech. Thermodyn. 30, 1059 (2018).
[117] A. S. Grashchenko, S. A. Kukushkin, V. I. Nikolaev, A. V. Osipov, E. V. Osipova, and I. P. Soshnikov, Phys. Solid State 60, 852 (2018).
[118] D. H. Kim, S. H. Yoo, T. M. Chung, K. S. An, H. S. Yoo, and Y. Kim, Bull. Korean Chem. Soc. 23, 225 (2002).
[119] H. W. Kim, N. H. Kim, and C. Lee, Br. Ceram. Trans. 103, 187 (2004).
[120] W. Xu, X. Wang, Y. Wang, T. You, X. Ou, G. Han, H. Hu, S. Zhang, F. Mu, T. Suga, Y. Zhang, and Y. Hao, in Tech. Dig.-Int. Electron Devices Meet. IEDM (2019), pp. 274-277.
[121] Y. B. Wang, W. H. Xu, T. G. You, F. W. Mu, H. D. Hu, Y. Liu, H. Huang, T. Suga, G. Q. Han, X. Ou, and Y. Hao, Sci. China Physics, Mech. Astron. 63, 277311 (2020).
[122] D. Wang, L. He, Y. Le, X. Feng, C. Luan, H. Xiao, and J. Ma, Ceram. Int. 46, 4568 (2020).
[123] M. Kneiß, A. Hassa, D. Splith, C. Sturm, H. Von Wenckstern, T. Schultz, N. Koch, M. Lorenz, and M. Grundmann, APL Mater. 7, 022516 (2019).
[124] H. Nishinaka, H. Komai, D. Tahara, Y. Arata, and M. Yoshimoto, Jpn. J. Appl. Phys. 57, 115601 (2018).
[125] T. Hadamek, A. B. Posadas, F. Al-Quaiti, D. J. Smith, M. R. McCartney, and A. A. Demkov, AIP Adv. 11, 045209 (2021).
[126] K. J. Hubbard and D. G. Schlom, J. Mater. Res. 11, 2757 (1996).
[127] S. Rafique, L. Han, A. T. Neal, S. Mou, J. Boeckl, and H. Zhao, Phys. Status Solidi Appl. Mater. Sci. 215, 1700467 (2018).
[128] Y. Zhang, F. Alema, A. Mauze, O. S. Koksaldi, R. Miller, A. Osinsky, and J. S. Speck, APL Mater. 7, 022506 (2019).
[129] P. Vogt, F. V. E. Hensling, K. Azizie, C. S. Chang, D. Turner, J. Park, J. P. McCandless, H. Paik, B. J. Bocklund, G. Hoffman, and others, Appl. Phys. Lett. Mater. 9, 031101 (2020).
[130] R. A. McKee, F. J. Walker, and M. F. Chisholm, Phys. Rev. Lett. 81, 3014 (1998).
[131] D. Wang, X. Ma, H. Xiao, Y. Le, and J. Ma, Mater. Sci. Semicond. Process. 128, 105749 (2021).
[132] T. Shimizu, N. Gotoh, N. Shinozaki, and H. Okushi, Appl. Surf. Sci. 117-118, 400 (1997).
[133] P. Vogt and O. Bierwagen, Appl. Phys. Lett. 108, 072101 (2016).
[134] P. Villars and K. Cenzual, “Pearson's crystal data-crystal structure database for inorganic compounds” (on DVD), ASM International (Materials Park, Ohio, USA, 2018).
[135] R. C. Hatch, K. D. Fredrickson, M. Choi, C. Lin, H. Seo, A. B. Posadas, and A. A. Demkov, J. Appl. Phys. 114, 103710 (2013).
[136] V. M. Bermudez, Chem. Phys. 323, 193 (2006).
[137] R. Schewski, K. Lion, A. Fiedler, C. Wouters, A. Popp, S. V. Levchenko, T. Schulz, M. Schmidbauer, S. Bin Anooz, R. Grüneberg, Z. Galazka, G. Wagner, K. Irmscher, M. Scheffler, C. Draxl, and M. Albrecht, APL Mater. 7, 022515 (2019).
[138] M. Grundmann, T. Böntgen, and M. Lorenz, Phys. Rev. Lett. 105, 146102 (2010).
[139] M. Grundmann, Phys. Status Solidi Basic Res. 248, 805 (2011).
[140] M. Grundmann, T. Böntgen, and M. Lorenz, Phys. Rev. Lett. 105, 146102 (2010).
[141] M. Grundmann, Phys. Status Solidi Basic Res. 248, 805 (2011).
[142] S. J. Pearton, J. Yang, P. H. Cary, F. Ren, J. Kim, M. J. Tadjer, and M. A. Mastro, Appl. Phys. Rev. 5, 011301 (2018).
[143] P. G. Staib, J. Vac. Sci. Technol. B, Nanotechnol. Microelectron. Mater. Process. Meas. Phenom. 29, 03C125 (2011).
[144] P. H. Carey, F. Ren, D. C. Hays, B. P. Gila, S. J. Pearton, S. Jang, and A. Kuramata, Jpn. J. Appl. Phys. 56, 071101 (2017).
[145] M. Hattori, T. Oshima, R. Wakabayashi, K. Yoshimatsu, K. Sasaki, T. Masui, A. Kuramata, S. Yamakoshi, K. Horiba, H. Kumigashira, and A. Ohtomo, Jpn. J. Appl. Phys. 55, 1202B6 (2016).
[146] G. Kresse and J. Furthmüller, Phys. Rev. B—Condens. Matter Mater. Phys. 54, 11169 (1996).
[147] P. E. Blöchl, Phys. Rev. B 50, 17953 (1994).
[148] V. M. Bermudez, Chem. Phys. 323, 193 (2006).
[149] T. Zacherle, P. C. Schmidt, and M. Martin, Phys. Rev. B—Condens. Matter Mater. Phys. (2013).
[150] W. Sun and G. Ceder, Surf. Sci. 617, 53 (2013).
[151] J. R. Rumble, editor, in CRC Handb. Chem. Phys., 101st ed. (CRC Press/Taylor & Francis, Boca Raton, FL, 2020).
[152] K. Eisenbeiser, J. M. Finder, Z. Yu, J. Ramdani, J. A. Curless, J. A. Hallmark, R. Droopad, W. J. Ooms, L. Salem, S. Bradshaw, and C. D. Overgaard, Appl. Phys. Lett. 76, 1324 (2000).
[153] Z. Yu, J. Ramdani, J. A. Curless, J. M. Finder, C. D. Overgaard, R. Droopad, K. W. Eisenbeiser, J. A. Hallmark, W. J. Ooms, J. R. Conner, and V. S. Kaushik, J. Vac. Sci. Technol. B Microelectron. Nanom. Struct. 18, 1653 (2002).
[154] J. Geler-Gremer, A. B. Posadas, A. A. Demkov, Preparation of clean MgO surface by oxygen plasma-assisted thermal desorption. Journal of Vacuum Science & Technology B, 38(g), 062201 (2020).

In this disclosure, references to the above sources, which are numbered in single bracket “[ ]”, are made using the corresponding number in the single brackets, in the same manner as those sources are listed above. Each of the above listed references, along with other patents, patent applications, and non-patent literature not specifically listed above, are incorporated herein by reference in their entireties.

### SUMMARY

Systems and techniques for growing Ga₂O₃ on a Si substrate are provided herein. In an aspect, a buffer layer is provided herein that allows for integration of a thin film of Ga₂O₃ on a Si surface without impacting the stability of Ga₂O₃ or impacting the crystal symmetry of Ga₂O₃. In particular, the buffer layer provided herein provides an interface between Ga₂O₃ and Si such to thermodynamically stabilize Ga₂O₃ and reduce lattice defects or disorder. By providing the buffer layer, Ga₂O₃ can be formed in an epitaxial stack structure formed by growing the buffer layer on a Si substrate, and then forming a thin film of Ga₂O₃ on the buffer layer.

As will be described in greater detail below, a buffer layer containing a metal oxide may be formed on the Si substrate. The metal oxide may include STO, MgO, alumina, a rare earth oxide, or a combination thereof. In some cases, the metal oxide may be STO or MgO onto which a seed layer may be formed. The seed layer may be an aluminum oxide material that provides for further lattice alignment at the interface between the buffer layer and the thin film of Ga₂O₃. In some embodiments, in addition to the thin film of Ga₂O₃, one or more additional layers of Ga₂O₃ may be formed on the thin film to increase the thickness of the thin film. Various techniques may be employed to form each of the buffer layer, seed layer, and thin film of Ga₂O₃, such as MBE, PAMBE, CVD and MOCVD.

In some embodiments, the epitaxial stack structure, which may also be referred to herein as a wafer, may be integrated into an electronic device. For example, the epitaxial stack structure may be in electrical communication with one or more of a positive electrode and a negative electrode to provide electrical support for an electronic device. By integrating the epitaxial stack structure into an electronic device, the advantageous characteristics and properties of Ga₂O₃ can be harnessed to enhance the performance of the device.

### BRIEF DESCRIPTION OF THE DRAWINGS

The patent or application file contains at least one drawing executed in color. Copies of this patent or patent application publication with color drawing(s) will be provided by the Office upon request and payment of the necessary fec.

Embodiments of the present technology will be described and explained through the use of the accompanying drawings.

FIG. 1 illustrates an example epitaxial stacked structure, according to an embodiment herein.

FIG. 2 illustrates a method for manufacturing a wafer, according to some embodiments of the present technology.

FIGS. 3A-3D depict reflection high-energy electron diffraction (RHEED) patterns at different stages of growth.

FIG. 4 depicts a symmetric θ/2θ coupled x-ray diffraction (XRD) scan with sample aligned to Si (004).

FIG. 5 illustrates the relationship between the conventional monoclinic unit cell with lattice vectors a, b, c, and the distorted oxygen face-centered cubic (fcc) sublattice of β-Ga₂O₃.

FIG. 6 illustrates the close-packing planes of the distorted oxygen sublattice of β-Ga₂O₃.

FIGS. 7A-7C illustrate representative interface models between the γ-Al₂O₃ (111) substrate and locally epitaxial β-Ga₂O₃ domain variants.

FIG. 8 is a pole figure at 20=31.7° of (002) and (202) Bragg reflections of β-Ga₂O₃.

FIG. 9A is a bright-field STEM image showing cross-section of gallium oxide film grown on Si (001) substrate with thin alumina buffer layer.

FIG. 9B is a high-resolution TEM image showing region of gallium oxide film adjacent to alumina buffer layer.

FIG. 10 is a plot demonstrating the sample heating mechanism in the MBE consists of a silicon carbide heater that is placed above the sample backside and heats the sample backside and sample holder radiatively.

FIG. 11 is a plot depicting alumina rate via e-beam evaporation measured by QCM at an e-gun voltage of 7.75 kV and an emission current of 50 mA resulting in an oxygen partial pressure of ˜10⁻⁷ torr without supplying additional oxygen in the form of molecular O₂ gas.

FIGS. 12A-12D depict XPS data taken in situ after growth of e-beam evaporated alumina on clean Si (001) with a VG Scienta spectrometer with monochromatic Al-Kα and R3000 hemispherical analyzer at 200 eV pass energy.

FIG. 13 depicts plots of XRR data and GenX simulation of Al₂O₃/Si.

FIG. 14 depicts results of in-plane XRD coupled 2θ_{χ}/φ scan of 5 nm thick Al₂O₃/Si conducted on the Rigaku Ultima IV with in-plane arm, using parallel beam, Ni Cu—KB filter and 0.5° vertical Soller slits on source and detector sides.

FIG. 15 depicts the θ/2θ out-of-plane diffraction pattern of the 5 nm film of alumina on

### Si.

FIGS. 16A and 16B are top-views of the oxygen-terminated surface of γ-Al₂O₃ (111).

FIG. 16C is a side-view of the oxygen-terminated surface of γ-Al₂O₃ (111).

FIG. 17A depicts a plot of gallia rate as measured by quartz crystal microbalance (QCM) at 2×10⁻⁵ torr molecular oxygen pressure and 200 W rf-plasma power and a Ga cell temperature of 880° C., assuming a mass density of 5.95 g cm⁻³.

FIG. 17B depicts a plot of the gallia deposition rate measured by the QCM increases with increasing Ga effusion cell temperature for fixed oxygen plasma settings of 200 W rf-plasma power and 2.0 10⁻⁵ torr O₂ pressure.

FIGS. 18A-18E depict XPS data taken in situ after 1st PAMBE growth of gallia at 670° C. on γ-Al₂O₃ (111) (5 nm)/Si (001) with a VG Scienta spectrometer with monochromatic Al-Kα and R3000 hemispherical analyzer at 200 eV pass energy.

FIG. 19 depicts XRR data (dots in upper panel plot, in blue) and GenX simulation of Ga₂O₃/Al₂O₃/Si according to the present technology.

FIGS. 20A-20E depict XPS data taken in situ after 2nd PAMBE growth of additional gallia at 630° C. on Ga₂O₃ (21 nm)/γ-Al₂O₃ (111) (5 nm)/Si (001) with a VG Scienta spectrometer with monochromatic Al-Kα and R3000 hemispherical analyzer at 200 eV pass energy.

FIG. 21 depicts a plot of the Kiessig fringe spacing, which indicates a total Ga₂O₃ thickness of 66 nm.

FIG. 22 depicts a plot of the sticking probability as a function of sample temperature in the PAMBE-growth of Ga₂O₃ after the model by Vogt and Bierwagen [92].

FIGS. 23A-23F depict plots of Pseudo-Voigt function fits of x-ray diffraction θ/2θ reflections from the 66 nm β-Ga₂O₃ thin film.

FIGS. 24A-24C illustrate ideally terminated surfaces with lattice planes marking the terminations studied.

FIGS. 25A-25C illustrate lowest energy terminations before and after relaxation superimposed for the (310) O-termination (FIG. 25A), (2̅01) mixed-termination (FIG. 25B), and (101) O-termination (FIG. 25C).

FIGS. 26A and 26B show RHEED patterns for the Ga₂O₃ thin films as grown on bare STO along STO [symbol] 100 [symbol] and [symbol] 110 [symbol] azimuths for a 20-nm film.

FIGS. 26C and 26D show the same azimuths as in FIGS. 26A and 26B for a 50-nm film.

FIGS. 27A-27C depict results of ex situ XRD to characterize the crystal structure of Ga₂O₃ thin films.

FIGS. 28A-28C show cross-sectional TEM images (FIGS. 28A and 28B) and Fast Fourier Transform (FIG. 28C) to characterize the epitaxial texture of the Ga₂O₃ thin films.

FIGS. 29A and 29B are structural models showing lattice matching for β-Ga₂O₃ (1̅12) and (100), respectively.

FIGS. 30A and 30B are RHEED pattern to characterize the structural, morphology, and thickness for STO <100> and STO <110>, respectively, taken with a 15 keV electron beam of Ga₂O₃/SrTiO₃/Si.

FIG. 31A depicts XRD patterns showing a θ-2θ diffractogram of a 15 nm film of Ga₂O₃ grown by PAMBE at 775° C. on the STO (100) buffer layer on Si.

FIGS. 31B and 31C depict XRD patterns showing 0-20 diffractogram of in-plane XRD scans along STO and [100], respectively.

FIG. 32A depicts an XRR curve of Ga₂O₃ grown on STO-buffered Si.

FIG. 32B depicts a low-magnification TEM image of a 15-nm Ga₂O₃ film grown at 775+C. on STO-buffered Si (001) projected along the Si (110) zone-axis (equivalent to the STO (100) zone-axis).

FIG. 33 depicts a plot of surface energies of several surface terminations along the (100), (1̅12), (2̅01), (310) and (101) surfaces with respect to the Ga chemical potential where 0 and −4.65 eV represent Ga-rich and O-rich environments, respectively.

FIGS. 34A-34C depict cross-section TEM images taken along the STO zone axis at progressively higher magnification, as indicted by the scale bar.

FIG. 34D depicts the Fast Fourier Transform of FIG. 34C.

FIG. 35 depicts an indexing of Fast Fourier Transform of a TEM image of 50-nm Ga₂O₃ film, consistent with the model of four rotational in-plane variants for the (100) and (1̅12) basal growth planes.

FIGS. 36A-36C depicts plots of XPS data taken in situ after PAMBE growth of a 50 nm gallia film on STO with a VG Scienta spectrometer with monochromatic Al-Kα and R3000 hemispherical analyzer at 200 eV pass energy.

FIGS. 37A and 37B illustrate a reciprocal space simulation δ-Ga₂O₃ (100) and (1̅12) basal in the (hk0) plane of STO.

FIGS. 38A-38C provide tables of the fitted XRD peak positions and plane spacings along with and their deviation from the bulk values of β-Ga₂O₃ from FIGS. 27A-27C.

FIGS. 39A-39D illustrate mutual orientation of the parallelepipeds for the unit cells of (100)-β-Ga₂O₃ and (001)-STO.

FIG. 40A depicts a plot showing the spectrum from the high binding energy side of the O 1s XPS peak.

FIG. 40B depicts a plot showing the EEL spectrum from REELS experiments with low-incidence-angle electrons at 1.9 keV recorded under normal exit with a Staib Auger Probe. [143].

FIGS. 41A-41C illustrate surfaces before and after relaxation superimposed for the (100) (FIG. 41A), (100)-A (FIG. 41B), and (1̅12) (FIG. 41C) mixed terminations.

FIGS. 42A and 42B illustrate a wafer according to some embodiments of the present technology.

FIG. 43 provides examples of combining oxides with semiconductors epitaxially.

FIGS. 44A-44E illustrate difficulties of oxide/semiconductor epitaxy that may arise from strain, thermal mismatch, wetting, and symmetry effects, as well as steps.

FIG. 45A shows the measured Ga flux in the absence of O-plasma of 1.35 Å/min (average min 20 to 44).

FIG. 45B shows the measured GaOₓ flux of 3.95 Å/min (average min 20 to 38), showing an increase in the accumulation rate by a factor of ˜2.9 in the presence of O-plasma.

FIGS. 46A-46C provide results of the analysis of the RHEED patterns in an example.

FIGS. 47A-47C provide XPS results of the analysis in an example.

FIG. 48 provides XRR results of the analysis in an example.

FIGS. 49A and 49B illustrate differences between the crystal structures of β-Ga₂O₃ and γ-Ga₂O₃.

FIG. 50 shows that the example provides a single domain structure 5.5% mismatch (compressive), which can be denoted as γ-Ga₂O₃ (001) [001]/STO (001) [100].

FIG. 51 illustrates expected epitaxy for β-Ga₂O₃ on STO (001), which is the same as that observed on MgO (100) substrates, for an example.

FIG. 52 shows the expected 4-domain structure of β-Ga₂O₃ (100) [020] on STO (100) [110].

FIGS. 53A and 53B depict plots of out-of-plane (oop) XRD results for the example with sample label AF99.

FIGS. 54A and 54B depict combined in-plane 2q_{□}/f plots for the example taken along two different azimuths.

FIGS. 55A-55D depict peak decompositions of each of the four features in FIGS. 54A and 54B.

FIG. 56 depicts a RHEED image along direction of β-Ga₂O₃ grown on MgO (100) single crystal.

FIG. 57 depicts a RHEED image along direction of β-Ga₂O₃ grown on MgO-buffered Si.

FIG. 58 provides an XRD scan of β-Ga₂O₃ grown on MgO-buffered Si confirming single out of plane (100) orientation and no significant amount of the (−112) competing orientation.

FIG. 59 depicts a plot of X-ray reflectivity measurement (dots) and fit (line) for 59 nm Ga₂O₃ on 8 nm MgO on Si. Model surface roughness is 1.6 nm.

FIG. 60 is a diagram of an epi-Ga₂O₃ Power MOSFET, according to some embodiments of the present technology.

FIG. 61 is a diagram of a Ga₂O₃ vertical rectifier, according to some embodiments of the present technology.

The drawings have not necessarily been drawn to scale. Similarly, some components and/or operations may be separated into different blocks or combined into a single block for the purposes of discussion of some of the embodiments of the present technology. Moreover, while the technology is amenable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

The present disclosure relates to the epitaxial integration of gallium oxide (Ga₂O₃), a wide band-gap semiconductor material, onto Si substrates for advanced electronic applications. Ga₂O₃ has garnered significant attention in high-power electronics, ultraviolet (UV) photodetectors, and other optoelectronic devices due to its ultra-wide band-gap (˜5 eV), high theoretical breakdown field (˜8 MV/cm), and relatively low cost for bulk crystal production compared to other wide band-gap semiconductors. However, despite these advantages, the integration of Ga₂O₃ onto Si poses several technical challenges, including structural and thermal incompatibilities that must be addressed to enable scalable, high-quality Ga₂O₃-based devices.

This detailed description explores the methods and materials required for overcoming these integration challenges, focusing on improving the epitaxial growth of Ga₂O₃ on Si substrates. The embodiments described herein provide solutions to the crystal symmetry mismatch and the need for buffer layers, enabling successful epitaxial growth while reducing defect densities and enhancing the performance of the resulting electronic devices. In the following description, for the purposes of explanation, numerous specific details are set forth in order to provide a thorough understanding of embodiments of the present technology. It will be apparent, however, to one skilled in the art that embodiments of the present technology may be practiced without some of these specific details.

One of the key challenges in integrating Ga₂O₃ with Si substrates arises from the structural differences between the two materials. Silicon possesses a cubic crystal structure, whereas β-Ga₂O₃, the stable phase of gallium oxide, has a monoclinic crystal structure. This symmetry mismatch results in multi-orientation growth of Ga₂O₃ epitaxial domains on the Si substrate. The resulting crystal grain boundaries between these domains, along with defects arising from lattice mismatch, can severely degrade the electronic properties of the Ga₂O₃ epilayer. Therefore, improving the crystal quality of hetero-epitaxially grown Ga₂O₃ by reducing defect densities and increasing grain sizes is critical for high-performance device applications.

Another challenge is the low thermal conductivity of Ga₂O₃ (0.1-0.3 Wcm⁻¹K⁻¹), which makes heat dissipation difficult in high-power applications. Silicon, on the other hand, has a thermal conductivity over 750% higher than Ga₂O₃, making it a desirable substrate for heat management. However, direct growth of Ga₂O₃ on Si using molecular beam epitaxy (MBE), the preferred growth technique for integration due to its ability to control growth at the atomic level, is not feasible without a buffer layer. MBE requires an activated oxygen source, such as plasma or ozone, for Ga₂O₃ growth, which would oxidize the clean Si surface, forming amorphous silicon dioxide (SiO₂) and preventing epitaxial alignment. Furthermore, Ga₂O₃ is not thermodynamically stable on Si, leading to the spontaneous formation of SiO₂ at the interface, which further inhibits epitaxial growth.

To address at least the above-identified shortcomings, a buffer layer is necessary to achieve high-quality epitaxial growth of Ga₂O₃ on Si. The buffer layer prevents the oxidation of the Si surface and enables the epitaxial alignment of Ga₂O₃. Suitable buffer layers include materials that can grow as single crystals on Si without oxidizing it, and that also possess in-plane lattice spacings compatible with at least two dimensions of the β-Ga₂O₃ unit cell. Examples of such metal-oxide buffer layers include alumina (Al₂O₃), strontium titanate (SrTiO₃), and magnesium oxide (MgO). These buffer layers facilitate the successful integration of Ga₂O₃ onto Si, enabling the growth of high-quality epitaxial films suitable for advanced electronic applications. The following sections will describe these buffer layers and the epitaxial growth process in greater detail, providing a comprehensive approach to overcoming the challenges associated with integrating Ga₂O₃ onto Si substrates.

### β-Gallium Oxide

β-Gallium Oxide (β-Ga₂O₃) is an emerging wide band-gap semiconductor with promising applications in high-power electronics and optoelectronic devices. Due to its ultra-wide band-gap of approximately 5 eV, β-Ga₂O₃ offers significant advantages over traditional semiconductors such as Si, gallium nitride (GaN), and silicon carbide (SiC), particularly in high-voltage and high-temperature applications. Its high theoretical breakdown field (˜8 MV/cm) allows for the miniaturization of power electronics, enabling smaller, lighter, and more efficient devices. However, despite its benefits, integrating β-Ga₂O₃ into conventional semiconductor technologies, particularly onto Si substrates, presents challenges due to lattice mismatch and thermal incompatibilities.

Structural Properties of β-Ga₂O₃

β-Ga₂O₃ crystallizes in a monoclinic structure, which poses integration challenges when attempting epitaxial growth on substrates like silicon, which has a cubic crystal structure. The mismatch in symmetry can lead to multi-orientation growth of epitaxial domains, resulting in grain boundaries and other defects that degrade the electronic properties of the material. For high-performance device applications, it is essential to minimize these defects by optimizing epitaxial growth methods that reduce defect densities and increase grain size.

The crystal structure of β-Ga₂O₃ is classified under space group C2/m, with lattice parameters a=12.2 Å, b=3.0 Å, c=5.8 Å, and B=104°. The gallium ions in β-Ga₂O₃ occupy octahedral and tetrahedral sites within a distorted face-centered cubic oxygen sublattice. This unique structural arrangement is responsible for the material's exceptional properties, including its high breakdown field and transparency into the deep ultraviolet (UV) range. Additionally, β-Ga₂O₃'s high radiation hardness makes it an attractive candidate for space-based applications.

Systems and Methods for Epitaxial Growth of β-Ga₂O₃

In an embodiment of the present technology, MBE is utilized for the growth of high-quality β-Ga₂O₃ thin films on Si substrates. MBE offers unparalleled atomic-level control, making it the preferred method for heteroepitaxial growth of semiconductors. However, due to the chemical and thermal instability of direct β-Ga₂O₃ growth on Si, a buffer layer is necessary to prevent the formation of amorphous silicon dioxide (SiO₂) and to facilitate epitaxial alignment. It should be appreciated that while the buffer layer is discussed in the following paragraphs, the below “Metal-oxide Buffer Layer” section provides more details on the specifics of the buffer layer.

In one embodiment, a buffer layer is formed having a thickness between 2-10 nm on a 2-inch diameter Si (001) substrate prior to the deposition of β-Ga₂O₃. The buffer layer is deposited using e-beam evaporation at a temperature greater than 800° C., resulting in a smooth, single-crystal layer that matches the underlying Si substrate without causing oxidation. The use of the buffer layer not only prevents the oxidation of Si but also provides a surface that closely matches the lattice spacing of β-Ga₂O₃, thereby enabling high-quality epitaxial growth.

Following the buffer layer deposition, β-Ga₂O₃ is deposited at substrate temperatures ranging from 625° C. to 675° C. using MBE. Gallium (Ga) is evaporated from an effusion cell at 880° C., while an activated oxygen plasma source is employed to provide the oxygen flux required for the formation of Ga₂O₃. The total growth time and conditions are controlled to achieve a stoichiometric β-Ga₂O₃ layer, with post-growth characterization confirming the formation of a high-quality epitaxial film.

The β-Ga₂O₃ thin film may be grown to have a nominal thickness of between 10-200 nm, 20-150, 30-125, 40-100, 40-80, 40-70, or 50-60 nm using MBE. Reflection high-energy electron diffraction (RHEED) patterns can be recorded at various stages of growth to confirm the epitaxial nature of the β-Ga₂O₃ layer. X-ray photoelectron spectroscopy (XPS) and x-ray reflectivity (XRR) can be used to characterize the stoichiometry and thickness of the deposited layers. XPS reveals a stoichiometric composition of Ga₂O₃, while XRR confirms the layer thickness. In some embodiments, the β-Ga₂O₃ thin film may have an average sticking coefficient of 59% under the given growth conditions.

To further increase the film thickness for x-ray diffraction (XRD) characterization, in some embodiments, one or more additional layers of Ga₂O₃ film may be deposited at a lower substrate temperature, such as a temperature of less than 640° C. (e.g., 630° C.). With the additional layers of Ga₂O₃ film, a total thin film thickness may be approximately 66 nm, which is sufficient for detailed structural analysis. Symmetric θ/2θ XRD scans can be performed to reveal clear diffraction peaks corresponding to the β-Ga₂O₃ polymorph. Analysis of the peak intensities and positions can also confirm the presence of multiple out-of-plane orientations of β-Ga₂O₃, with estimated volume fractions of 71% for the (310) orientation, 13% for the (101) orientation, and 16% for the (2̅01) orientation.

### Polymorph and Orientation Analysis

The epitaxial growth of β-Ga₂O₃ on a buffer layer may result in a textured thin film with distinct in-plane and out-of-plane orientations. Due to the monoclinic symmetry of β-Ga₂O₃, there are several possible growth planes, including (2̅01), (101), and {310}. Each of these orientations can gives rise to multiple in-plane rotational variants due to the six-fold symmetry of the underlying buffer layer, such as when the buffer layer is γ-Al₂O₃ (111). The resulting epitaxial film consists of up to 48 rotational variants, making it critical to optimize growth conditions to reduce the number of variants and improve crystal quality.

The epitaxial growth of β-Ga₂O₃ is further complicated by the presence of twin domains, which arise due to 180° rotations about the c-axis. These twin domains can be observed in XRD and RHEED patterns and contribute to the overall complexity of the film's microstructure. By carefully controlling the growth temperature and oxygen flux during MBE deposition, it is possible to minimize the formation of twin domains and other defects.

### Metal-Oxide Buffer Layer

As noted above, there are significant challenges to growing β-Ga₂O₃ on Si. For successful epitaxial integration of β-Ga₂O₃ onto Si, a metal-oxide buffer layer, also referred to herein as a “buffer layer” or “epi-oxide buffer layer,” is required since the interface between Ga₂O₃ and Si is not thermodynamically stable [126]. Integration via a metal-oxide buffer layer is therefore an important step that provides a high-quality, well-defined template layer for subsequent growth by a faster method such as CVD, metal-organic CVD (MOCVD), or the recently reported suboxide MBE [127-129]. By using the metal-oxide buffer layers described herein, β-Ga₂O₃ can successfully be grown on a Si substrate. As such, large scale β-Ga₂O₃ thin films may be formed for use in electrical products, thereby allowing the electrical transport properties of β-Ga₂O₃ epitaxial films to be leveraged.

The metal-oxide buffer layer described herein may be formed from a variety of metal oxides that grow as a single crystal on the Si surface without oxidizing the underlying Si within the growing conditions required for Ga₂O₃. Moreover, the metal oxide used to form the buffer layer should provide in-plane lattice spacing that closely matches two of the dimensions of the unit cell of β-Ga₂O₃. As described in greater detail below, metal oxides that are able to meet the above requirements include alumina, STO (SrTiO₃) and MgO. Accordingly, as provided herein the buffer layer used to integrate Ga₂O₃ onto a Si substrate includes STO and MgO, and in some embodiments, alumina.

As noted above, one factor in selecting a respective metal oxide as a buffer layer for growing β-Ga₂O₃ on Si is that the metal oxide be unreactive with Si within the operating conditions required for growing the Ga₂O₃ thin film. As exemplified in the below Examples 2 and 5 for STO and MgO, respectively, both STO and MgO are stable and non-reactive with Si within the oxidizing conditions required to grow Ga₂O₃ thin film. While STO is stable on Si only at temperatures below 850° C., the STO is stable at the growing temperature of Ga₂O₃ which is below 800° C. MgO on the other hand is completely unreactive with Si at all practical temperatures up to the melting point of Si (˜1400° C.) due to the large formation energy of MgO.

Another factor for selecting a metal oxide as a buffer layer for Ga₂O₃ growth on Si is matching of at least two crystal dimensions of β-Ga₂O₃. That is, the selected metal oxide should match at least two of the lattice parameters of β-Ga₂O₃, which are a=12.2 Å, b=3.0 Å, c=5.8 Å, β=104, as noted above. STO and MgO approximately match the b and c lattice parameters of β-Ga₂O₃ when their interplanar spacing is doubled. For example, for STO (110), the interplanar spacing has a length of 5.52 Å, which represents an 4.8% mismatch to the β-Ga₂O₃ c lattice parameter of 5.8 Å, and for MgO (110), the interplanar spacing has a length of 5.96 Å which represents a 0.7% mismatch to twice the β-Ga₂O₃ b lattice parameter of 3.0 Å. Based on the relatively low mismatch between the interplanar spacing of the STO and MgO and the b and c lattice parameters of β-Ga₂O₃, both STO and MgO are suitable metal oxides for forming a buffer layer to stabilize the stacking of β-Ga₂O₃ along its 100 planes.

In some embodiments, matching of the lattice structure with the Si surface may also be desirable. Both STO and MgO are able to comprehensively match the lattice structure of Si. For example, the primitive surface unit cell of Si when it is unreconstructed is a square with length 3.84 Å rotated by 45 deg from the conventional unit cell. This is well matched to the lattice constant of SrTiO₃ of 3.9 Å (e.g., a 1.6% mismatch) but not as closely matched with MgO (e.g., a 8.8% mismatch). However, because the MgO crystal has a large formation energy, MgO adopts a 4:3 coincident site epitaxy with Si such that there are 4 MgO conventional unit cells (4.21 Å) for every 3 Si conventional unit cells (5.43 Å), which results in a more manageable 3.3% mismatch. Accordingly, when viewed comprehensively, both MgO and STO are considered to contain a matching lattice structure to Si.

As demonstrated by Examples 2-5 provided below, STO and MgO, respectively, can each be epitaxially integrated onto Si, and hence can act as a buffer layer for growth of Ga₂O₃ on Si, which would then lead to the availability of large area Ga₂O₃ epitaxial films. Per Example 2, strontium titanate (SrTiO₃ or STO) is an oxide material that can be integrated with Si substrates, and thus can be used as a buffer layer for the epitaxial growth of other materials such as Ga₂O₃. These examples illustrate that STO and MgO provide for structural compatibility with Si. As illustrated by Example 2, due to the lattice match between STO and Si, using STO as a buffer layer allows for high-quality epitaxial integration, which is crucial for subsequent epitaxial growth processes. As illustrated by Example 5, while MgO provides for a slightly lower match with Si, due in part to a partial plane tilt of MgO planes relative to Si, MgO still allows for the (100) orientation of Ga₂O₃ to remain intact when grown on top of the MgO.

Another consideration for selecting a metal oxide for the buffer layer, in some embodiments, includes the ability of that respective metal oxide to be doped. For example, STO is able to be doped with niobium (Nb), allowing it to function as a conductive template layer and as a bottom electrode, which is particularly useful in electronic devices where the Ga₂O₃ layer acts as the active material. This dual functionality is particularly advantageous in Ga₂O₃-based devices, where the buffer layer not only acts as a structural buffer but also contributes to the overall electrical performance of the device.

### Epitaxial Stack Structure

To integrate Ga₂O₃ onto a Si substrate (e.g., wafer), an epitaxial stack structure may be formed. As will be described in the following discussion, the epitaxial stack structure, which is also referred to herein as a layered stack, may include a Si substrate or wafer, a metal-oxide buffer layer, and a thin film of Ga₂O₃. In some embodiments, an optional seed layer of alumina (Al₂O₃) may be included as part of the buffer layer or on top of the buffer layer to improve lattice matching.

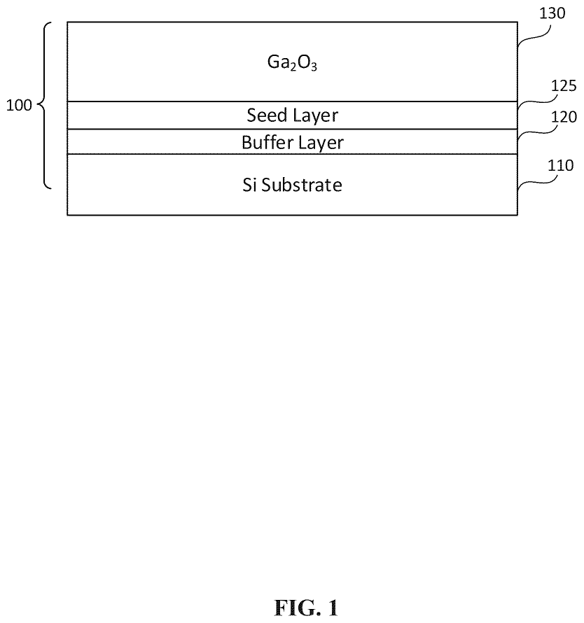

Referring now to FIG. 1, an example epitaxial stack 100 is illustrated, according to an embodiment herein. As illustrated, the epitaxial stack structure may include a Si substrate 110, a buffer layer 120, and a thin film 130 containing Ga₂O₃. In some embodiments, a seed layer 125 may be included as part of the buffer layer 120 or on top of the buffer layer 120. Various deposition techniques may be employed to achieve the epitaxial stack structure 100 described herein, including MBE, PAMBE, and metal-organic chemical vapor deposition (MOCVD). Each layer of the epitaxial stack structure 100 including the Si substrate 110, the metal-oxide buffer layer 120, optional seed layer 125, and the epitaxial Ga₂O₃ thin film 130, are described in turn below.

### 1. Buffer Layer 120 Layer Formation on the Si Substrate 110

The epitaxial stack structure 100 includes a buffer layer 120 to address the challenge of directly growing the thin film 130 of Ga₂O₃ on the Si substrate 110. Without the buffer layer 120, the Ga₂O₃/Si interface formed between the thin film 130 and the Si substrate 110 becomes thermodynamically unstable, favoring the formation of silicon dioxide (SiO₂). To prevent the formation of SiO₂ and allow for integration of the thin film 130 onto the Si substrate 110, the buffer layer 120 may be formed. As described above, the buffer layer 120 may include a metal-oxide, such as STO or MgO.

In some embodiments, the Si substrate 110, typically a silicon, single-side-polished wafer, undergoes one or more cleaning processes. This can involve immersion of the Si substrate 110 in one or more of acetone, 2-propanol, and deionized water, with each step performed in an ultrasonic bath to effectively remove organic contaminants and particles. After the wet cleaning, the Si substrate 110 may be subjected to ultra-high vacuum (UHV) degassing to remove any residual moisture or organic residues, ensuring the surface is pristine for subsequent growth.

Once cleaned and degassed, the Si substrate 110 is loaded into an MBE chamber. In the chamber, the Si substrate 110 is exposed to a high-vacuum environment and preheated to a temperature between 800° C. and 900° C. to desorb the native SiO₂ layer.

With Si surface prepared, the buffer layer 120 is epitaxially grown on the Si substrate 110. The growth process is carefully controlled, with the substrate temperature maintained between 400° C. and 800° C., which optimizes the quality of the buffer layer 120. The buffer layer 120 is grown to a thickness ranging from 5 nm to 20 nm, which provides a smooth and thermally stable interface that prevents reactions between the Si substrate 110 and any subsequent materials grown on top.

The epitaxial growth of the buffer layer 120 on the Si substrate 110 is monitored using reflection high-energy electron diffraction (RHEED) to confirm the formation of a high-quality, lattice-matched interface. This interface serves as an ideal template for subsequent growth steps, facilitating the deposition of additional layers, such as the β-Ga₂O₃ thin film 130, without inducing defects or compromising the structural integrity of the films.

2. Thin Film 130 of Gallium Oxide (Ga₂O₃) Epitaxial Growth

Following the formation of the buffer layer 120, one or more Ga₂O₃ thin films 130 are deposited, typically ranging from 20 to 100 nm in thickness. The Ga₂O₃ growth of the thin film 130 may be achieved using either PAMBE or MOCVD techniques. In the case of PAMBE, the Si substrate 110 temperature is maintained between 670° C. and 775° C., with the gallium cell heated to approximately 880° C. Oxygen plasma may be employed throughout the process to enhance the growth kinetics, leading to deposition rates of 1-4 Å/min. The oxygen plasma also increases the Ga₂O₃ growth rate by a factor of ˜2.8 due to improved surface kinetics compared to metal gallium. In some cases, RHEED may be employed during the growth process to monitor the crystallinity of the thin film 130 in real-time, and post-deposition analysis using XRD, XPS, and TEM ensures that the Ga₂O₃ thin film 130 adheres to the desired crystalline quality. Post-growth treatments such as annealing can further improve the thin film's 130 structural properties.

### 3. Seed Layer 125 Formation

In some embodiments, a compositionally graded alumina (Al₂O₃) seed layer 125 may be introduced between the buffer layer 120 and the Ga₂O₃ thin film 130 to improve lattice matching. This seed layer 125 is typically grown using MBE or MOCVD, with the Al₂O₃ seed layer 125 thickness ranging from 5 to 20 nm. By employing an Al₂O₃ seed layer 125, any lattice mismatch between the buffer layer 120 and the Ga₂O₃ thin film 130 can be minimized, resulting in improved initial film quality.

To further optimize lattice matching, a compositionally graded AlₓGa₁₋ₓO₃ alloy may be used for the seed layer 125 in which the aluminum content (x) gradually transitioning from 1 to 0, enabling a smooth transition from the Al₂O₃ seed layer 125 to the Ga₂O₃ thin film 130. This approach helps reduce defects during early stages of Ga₂O₃ growth, ultimately improving the crystalline quality of thicker films. As with the Ga₂O₃ films 130, the seed layer 125 benefits from post-growth treatments like annealing and etching to improve smoothness and crystalline quality.

While initial epitaxial Ga₂O₃ growth on the Si substrate 110 may result in some defects due to lattice mismatch, the crystalline quality improves significantly with increasing film thickness. In some embodiments, the buffer layer 120 may include the seed layer 125 that supports further Ga₂O₃ growth through MOCVD or similar methods. Compositionally graded seed layers 125 such as AlₓGa₁₋ₓO₃ further enhance lattice matching, and post-growth treatments like annealing, polishing, and etching contribute to producing high-quality, free-standing Ga₂O₃ films 130 or epitaxial stack structure the 100.

### 4. Methodologies for Forming the Epitaxial Stack Structure 100

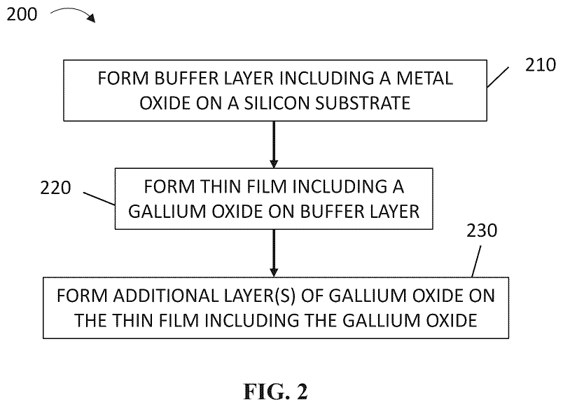

Referring now to FIG. 2, an example operational flow 200 for forming the epitaxial stack structure 100 is illustrated, according to an embodiment herein. In particular, the flow 200 may illustrate a method for manufacturing a wafer, such as a semiconductor wafer, according to some embodiments of the present technology. As shown, the flow 200 includes forming a buffer layer, such as the buffer layer 120, on a Si substrate, such as the Si substrate 110 (210). As described above, the buffer layer may include a thin film of an epitaxial material, such as STO or MgO to stabilize the interface between the Si substrate and the Ga₂O₃ thin film.

In one embodiment, forming the buffer layer (210) may involve a multi-step process. In such embodiments, forming the buffer layer may include forming a first layer of a metal oxide on the Si substrate, such as STO or MgO, followed by forming a second layer including a second metal oxide, such as aluminum oxide. The second layer may serve as an additional seed layer, such as the seed layer 125, which can further improve the lattice matching between the gallium oxide film and the underlying substrate.

In one embodiment, the buffer layer may be formed of aluminum oxide as the metal oxide material for the buffer layer. For example, the buffer layer may be or include gamma-aluminum oxide (γ-Al₂O₃), which provides a suitable template for the subsequent growth of gallium oxide. In another embodiment, the buffer layer could include an aluminum-gallium oxide alloy, either in addition to or as a replacement for γ-Al₂O₃, to improve the lattice matching between the buffer layer and the gallium oxide thin film. In other words, in some cases the buffer layer 120 may be formed from aluminum oxide (or an alloy thereof), while in other cases, the buffer layer 120 may be formed from another metal oxide (e.g., STO or MgO), with a subsequent seed layer 125 containing aluminum oxide formed thereon.

In another embodiment, the buffer layer may be formed using a rare earth oxide such as gadolinium oxide (Gd₂O₃) or erbium oxide (Er₂O₃). These materials provide an alternative to the metal oxides described above and can be used to support the heteroepitaxial growth of gallium oxide in cases where better lattice matching is required. In such cases, the buffer layer may be formed via a first layer of rare earth oxide on the Si substrate, followed by a second layer of gallium-rare earth alloy oxide. The thin film of gallium oxide may then be grown on this layered structure to create a stable, high-quality epitaxial stack.

In some embodiments, forming the buffer layer (210) may involve creating a compositionally graded buffer layer to improve the transition between the Si substrate and the gallium oxide film.

Once the buffer layer is formed on the Si substrate (210), the flow 200 may include forming a thin film of gallium oxide, such as the thin film 130, on the buffer layer (220). The Ga₂O₃ film may be grown epitaxially as described above to ensure high-quality crystal formation. In some embodiments, the thin film of Ga₂O₃ may be formed to be or include a gamma-gallium oxide (γ-Ga₂O₃), while in other embodiments, the thin film of Ga₂O₃ may be or include beta-gallium oxide (β-Ga₂O₃), which can be grown either in place of or in addition to gamma-gallium oxide to enhance the functionality of the film for specific applications. In some cases, both variants of Ga₂O₃ may be grown, depending on the desired material properties for the final application.

In an example, forming the thin film of gallium oxide (220) may involve growing the thin film Ga₂O₃ layer on the seed layer. As described above, the seed layer may include aluminum oxide layer formed as γ-Al₂O₃, which enhances the stability of the gallium oxide growth. In another example, forming the thin film of gallium oxide (220) may involve hetero-epitaxially integrating the Ga₂O₃ thin film onto the Si substrate via the buffer layer.

In some embodiments, the flow 200 may also include forming one or more additional layers of gallium oxide on the initial thin film (230). In an example, forming the additional layers Ga₂O₃ (230) may include growing the additional layers using CVD, which enables the production of thicker, bulk-like Ga₂O₃ layers. For example, forming the additional layers of Ga₂O₃ films (230) may form bulk-like crystals that are essential for certain high-performance applications. In some embodiments an aluminum-gallium oxide alloy may formed as part of the additional thin film layers (230) to improve the quality and stability of the epitaxial stack structure. In cases where the buffer layer includes aluminum oxide, formation of the additional layers of Ga₂O₃ may include first forming a layer of aluminum-gallium alloy oxide, followed by further layers of Ga₂O₃. In cases where the buffer layer includes a rare earth oxide, the process may involve forming a layer of gallium-rare earth alloy oxide before the additional Ga₂O₃ layers are deposited.

As noted above, once the thin film of Ga₂O₃ is grown on the buffer layer, the flow 200 may include one or more additional steps such as etching, polishing, or annealing to smoothen the surface and enhance the crystalline quality of the Ga₂O₃ thin film.

In any of the embodiments described herein with reference to FIG. 2, the flow 200 may further include the step of forming at least one of the following: a microelectronic device, an optoelectronic device, a micro-electromechanical system (MEMS), a field-effect transistor, a sensor, or a semiconductor device on the thin film of gallium oxide or on the additional layers of gallium oxide. Furthermore, the flow 200 may include operably coupling one or more components of a power electronics device to the thin film or the additional gallium oxide layers, making this technology particularly suited for power-electronics applications. As noted above, the epitaxial stack structure can be used to create power electronics devices by coupling components to the epitaxial stack, such as illustrated in FIGS. 54 and 55 in Example 6 provided below, leveraging the excellent material properties of Ga₂O₃ for high-performance applications.

### 5. Applications and Future Directions

The epitaxial stack structure 100 formed by the Si substrate 110, the buffer layer 120, and the Ga₂O₃ thin film 130 offers a scalable solution for growing Ga₂O₃ films on large-area silicon wafers (200-300 mm). This is critical for applications in power electronics and optoelectronics, where large-area, bulk-like Ga₂O₃ films are required. The large-scale production capability enabled by this stack structure 100 supports a wide range of applications, including the fabrication of field-effect transistors, power devices, and UV-sensitive optoelectronic devices. Moreover, the combination of β-Ga₂O₃ with Si provides improved heat dissipation, addressing another limitation of β-Ga₂O₃ in high-power applications.

The successful integration of β-Ga₂O₃ on Si substrates has significant implications for the development of next-generation power electronics. The ability to grow high-quality-Ga₂O₃ thin films on large-scale Si wafers enables the fabrication of devices that leverage the high breakdown field and thermal stability of β-Ga₂O₃ while benefiting from the established infrastructure of Si technology. Examples of such electronic devices are illustrated in FIGS. 60 and 61 described in below Example 6, such as the power electronic devices 6000 and 6100 into which the epitaxial staked structure 100 may be incorporated.

Accordingly, the present technology provides a scalable method for the epitaxial growth of β-Ga₂O₃ on Si substrates using buffer layers. By addressing the challenges of lattice mismatch, thermal instability, and defect formation, the approach provided herein paves the way for the widespread adoption of β-Ga₂O₃ in power electronics, UV photodetectors, and other advanced semiconductor devices.

### EXAMPLES

### Example 1: Gallia on Alumina-Buffered Silicon

### Experimental Conditions

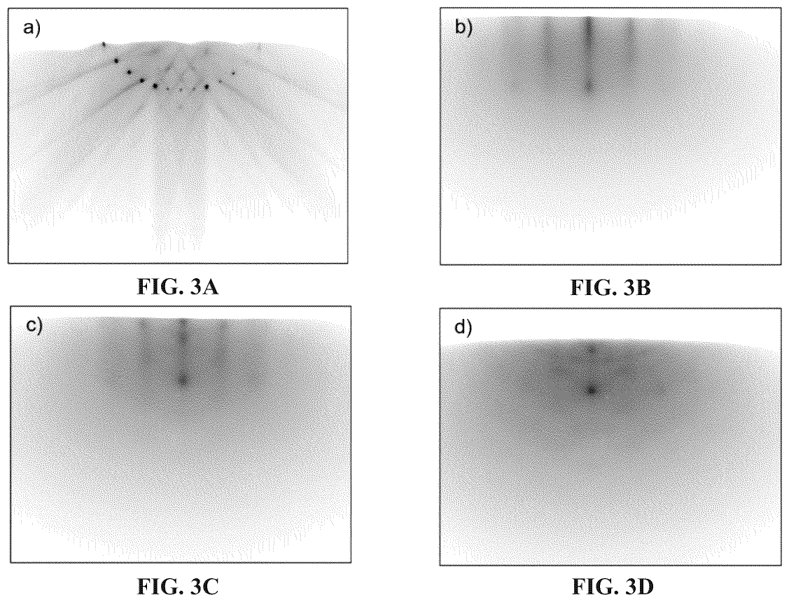

In an embodiment of the present technology, a 5 nm γ-Al₂O₃ (111) layer was deposited on a 2 inch diameter Si (001) substrate with 2×1 surface reconstruction, akin to references [60-62]. FIGS. 3A-3D depict reflection high-energy electron diffraction (RHEED) patterns at different stages of growth: FIG. 3A is the Si (001) 2×1 surface after SiO₂ desorption with Sr along Si azimuth; FIG. 3B is the post-growth surface of 5 nm e-beam-evaporated γ-Al₂O₃ (111) grown at 840° C. along Si azimuth with 12-fold rotational symmetry; FIG. 3C is the post-growth surface of 21 nm gallia (Ga₂O₃) grown at 670° C. along Si azimuth; and FIG. 3D is the post-growth surface of additional 45 nm Ga₂O₃ grown at 630° C. along Si [100] azimuth. The RHEED pattern after growth showed a 12-fold symmetry and is shown along with the 2×1 Si surface in FIGS. 3C and 3D. Details of the growth and characterization by RHEED, x-ray reflectivity (XRR), x-ray photoelectron spectroscopy (XPS) and x-ray diffraction (XRD) are detailed in the section below entitled “Supplemental Material For Example 1.” As discussed in greater detail there, the characterization results are in good agreement with what is reported in the literature [60-63, 67].

Following the characterization, the alumina (“Al₂O₃”)-buffered 2 inch Si wafer was re-loaded into the ultra-high vacuum (UHV) system after ex situ cleaning with acetone, 2-propanol, de-ionized water, drying with N₂ and UV/ozone for 30 min. Ga₂O₃ was then deposited at 670° C. substrate temperature. Ga (99.99% purity) was evaporated from a dual filament (hot lip) effusion cell held at 880° C., and an O plasma was generated by an rf-plasma source operated at 2.0×10⁻⁵ torr O₂ partial pressure and 200 W plasma power. The total pressure was monitored by an ion gauge located in the upper part of the molecular-beam epitaxy (MBE) chamber (above the sample), whereas a residual gas analyzer/quadrupole mass spectrometer (RGA/QMS) located at the side of the chamber (below the sample) measured an O₂ to O ratio of approximately 10, from which an absolute O flux of ˜10 nm⁻²s⁻¹ is estimated. The sample exposed to oxygen plasma was annealed for 30 min at 670° C. prior to growth. The Ga₂O₃ deposition rate on the quartz crystal microbalance (QCM) sensor before the anneal was 3.15 Å/min.

The film was grown for 174.5 min for a nominal Ga₂O₃ thickness of 55 nm. Post-growth RHEED showed a streaky surface with qualitatively similar pattern as the underlying γ-Al₂O₃, although with more modulation along the streaks as shown in FIG. 3C. XPS determined a stoichiometric Ga₂O₃ and revealed a sample that was thicker than the information depth in XPS (>5λ≈10 nm, λ is the kinetic-energy-dependent effective attenuation length for photoelectrons in Ga₂O₃ [68]), i.e., no substrate signal (Al or Si) was seen in the spectra. XRR determined an actual thickness of 20.6 nm for the stoichiometric Ga₂O₃ layer, resulting in an average sticking coefficient of 38% for the given growth conditions (XPS and XRR data are discussed below in “Supplemental Material For Example 1”).

The resulting Ga₂O₃ film was too thin for comprehensive characterization with a laboratory x-ray diffractometer (Al and Ga are weak Rayleigh x-ray scatterers [69]). Hence, additional Ga₂O₃ was deposited. The 2 inch wafer was first diced into 10×10 mm² pieces. After dicing, a 10×10 mm² piece obtained from the center of the wafer was re-cleaned following the above cleaning protocol and loaded into UHV on a molybdenum sample holder. After a 40 min anneal at 630° C. in oxygen plasma, an additional Ga₂O₃ layer was deposited at the lower substrate temperature of 630° C. to enhance the sticking probability [70], with GaOₓ rate ˜0.3 nm/min, at otherwise identical growth conditions for 256 min (76.8 nm additional Ga₂O₃ nominally). The XRR revealed an additional Ga₂O₃ thickness of 45 nm (see “Supplemental Material For Example 1,” below), indicating an increased average sticking probability of 59%, leading to a total film thickness of ˜66 nm, sufficiently thick for XRD characterization. RHEED post-growth shown in FIG. 3D displays a less streaky pattern with strong modulation along the streaks. This change in the RHEED pattern could be related to decrease in crystalline quality at the lower growth temperature, or due to surface roughening as the film thickness increased. XPS showed again stoichiometric Ga₂O₃ (see “Supplemental Material For Example 1,” below).

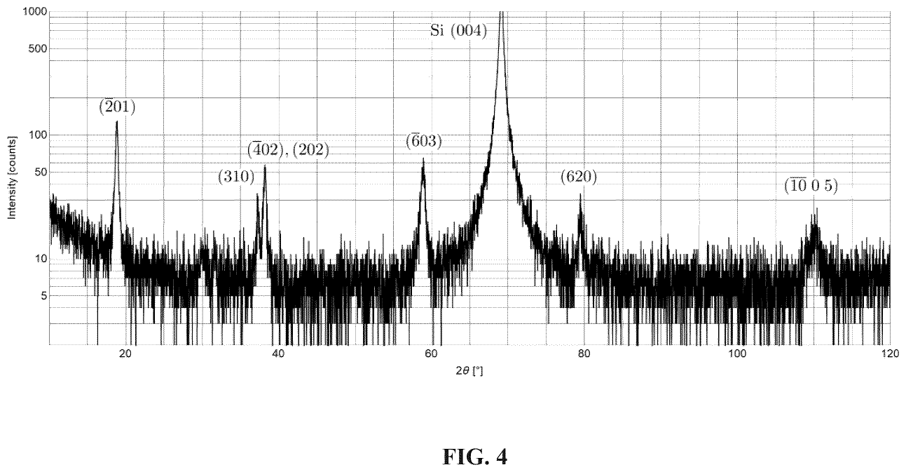

In order to identify the polymorph and orientation of the stoichiometric and crystalline Ga₂O₃ layer, an ex situ θ/2θ XRD scan with sample alignment to Si (004) was conducted on a Rigaku Ultima IV diffractometer with Cu-Kα anode, parallel beam geometry (multilayer mirror), and a 2-bounce Ge monochromator. The scan was recorded with slit settings of 1.0 mm for the divergence slit and 0.5 mm for both scattering and receiving slits, without the use of Soller slits. The settings were chosen to enhance the weak film signal and allow the observation of lattice planes that have normals slightly tilted away from the Si surface. A 5.0 mm height-limiting slit was used to limit the spread of the beam perpendicular to the scattering plane and keep the x-ray beam from spilling over the sample edges. FIG. 2 depicts a symmetric θ/2θ coupled XRD scan with sample aligned to Si (004). Six film peaks are apparent and are attributed to the β-Ga₂O₃ polymorph labeled by their Miller indices. The scan shown in FIG. 4 reveals six clearly identifiable film peaks along with the Si (004) substrate peak.

### Results and Discussion

Fitting of the peak profiles to pseudo-Voigt functions is presented in FIGS. 23A-23F, and discussed in greater detail, below, in the section entitled “Supplemental Material For Example 1.” By analysis of the respective integrated peak areas and 20 positions, we conclude the presence of the harmonics of the β-Ga₂O₃ polymorph {310}, (101) and (2̅01) plane families, with estimated scattering volume fractions of 71%, 13% and 16% for the three phases. With this model, the agreement between calculated and experimental intensities is reasonable-see Table 1, below.

TABLE 1
Experimental and bulk structure Bragg angles, lattice constants, and integrated peak
intensities for the 66 nm β-Ga₂O₃ film on Al₂O₃/Si. The ΣI_{β} column for the expected
intensity is based on the summed intensities for 71%, 13% and 16% scattering volume
fractions for the {310}, (101) and (2̅01) out-of-plane orientations, respectively.
Intensity values are normalized to the (2̅01) reflection.

| | 2θ_{bulk} | 2θₑₓₚ | Δ2θ | d_{bulk} | dₑₓₚ | Δd | | |
|---|---|---|---|---|---|---|---|---|
| (h k 1) | [°] | [°] | [°] | [Å] | [Å] | [Å] | ΣI_{β} | Iₑₓₚ |
| (2̅ 0 1) | 18.94 | 18.80 | 0.14 | 4.68 | 4.72 | −0.04 | 1.00 | 1.00 |
| (3 1 0) | 37.30 | 37.23 | 0.07 | 2.41 | 2.41 | −0.00 | 0.17 | 0.17 |
| (4̅ 0 2), | 38.42, | 38.17 | 0.25, | 2.34, | 2.36 | −0.01, | 0.50 | 0.50 |
| (2 0 2) | 38.43 | | 0.26 | 2.34 | | −0.01 | | |
| (6̅ 0 3) | 59.14 | 58.84 | 0.30 | 1.56 | 1.57 | −0.01 | 0.79 | 0.82 |
| (6 2 0) | 79.50 | 79.46 | 0.04 | 1.20 | 1.21 | −0.00 | 0.17 | 0.20 |
| (8̅ 0 4), | 82.29, | x | x | 1.17, | x | x | 0.04 | x |
| (4 0 4) | 82.32 | | | 1.17 | | | | |
| (1̅0̅ 0 5) | 110.67 | 110.10 | 0.62 | 0.94 | 0.94 | −0.00 | 0.29 | 0.35 |
| (0 0 4)_{Si} | 69.120 | 69.140 | 0.020 | 1.3579 | 1.3576 | 0.003 | x | x |

The volume fractions obtained indicate that there are differences in nucleation and growth rate for the different basal growth planes. A non-uniform vertical distribution of the three out-of-plane orientations is also possible. By using the full-width-at-half-maxima of the peak profiles in the Debye-Scherrer equation, the coherence length of the scattering crystallites along the out-of-plane direction is estimated to be ˜21 nm for the (2̅01) reflection, ˜19 nm for the (310) reflection, ˜24 nm for the (4̅02)/(202) reflection. It is evident from Table 1 that the peaks of the (2̅01) and (101) phases show larger 20 shifts from the bulk value when compared with {310}. This difference could be explained by a difference in strain values leading to differing lattice relaxation behavior. Probable orientations of other Ga₂O₃ polymorphs can be excluded as majority phases due to the absolute peak positions and relative peak areas (see Table 5, below, in the section entitled “Supplemental Material For Example 1”). The {310}, (101) and (2̅01) planes are plausible basal growth planes for growth on γ-Al₂O₃ (111) due to their local oxygen arrangement, as will be described below. Evidence for a thin interlayer of γ-Ga₂O₃ (111) could not be found from the θ/2θ diffractogram of FIG. 4.

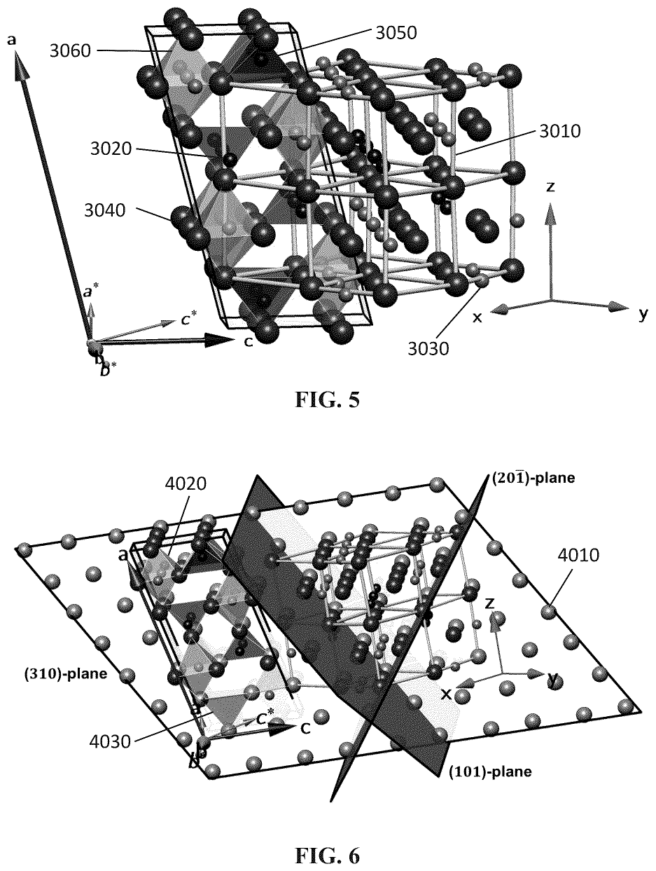

The crystal structure of β-Ga₂O₃ has a low symmetry, base-centered monoclinic C2/m space group (12) with only one mirror plane (perpendicular to b-axis in standard setting [71]), one two-fold rotation axis (parallel to b-axis), and an inversion center (origin) as its non-trivial symmetry operations. However, β-Ga₂O₃ is characterized by oxygen ions forming a sublattice with a distorted fcc arrangement [72], where the smaller gallium ions fill interstitial spaces of tetrahedral (Ga1) or octahedral (Ga2) symmetry. FIG. 5 illustrates the relationship between the conventional monoclinic unit cell with lattice vectors a, b, c, and the distorted oxygen fcc sublattice of β-Ga₂O₃. A possible oxygen face-centered cubic (fcc) unit cell is highlighted by the yellow cage (labeled 3010 in FIG. 3), tetrahedrally bonded Ga1 ions are in blue (labeled 3020 in FIG. 3), octahedrally bonded Ga2 ions in green (labeled 3030 in FIG. 3), and O ions are in red (labeled 3040 in FIG. 3), and the monoclinic unit cell is highlighted by its parallelepiped. The crystal structure of β-Ga₂O₃ alongside with a visualization of the polyhedral Ga—O bonding, and the relationship of the conventional monoclinic unit cell to the oxygen ion distorted fcc sublattice, are pictured in FIG. 5.

By looking at the distorted tetrahedra (blue, labeled 3050 in FIG. 5) and octahedra (green, labeled 3060 in FIG. 5) formed by the Ga—O bonds centered around the Ga ions in FIG. 5 it can be seen that the structure locally exhibits a pseudo-three-fold symmetry for oxygen ions contained on the face planes of the polyhedra. Overall, there are four distinct sets of parallel face planes to the polyhedra, which mark planes of local (approximate) three-fold symmetry for the oxygen ions contained in the face planes. The sets of parallel face planes are approximated by the crystallographic planes (2̅01), (101), (310) and (310) when given by their Miller indices. The latter two are crystallographically equivalent, related by mirror symmetry and henceforth summarized as {310}. Diffraction peaks for these planes are the ones observed in the θ/2θ diffractogram of FIG. 3. However, growth along {310} and along its negative {310} give rise to two crystallographically distinct twin orientations, the twin variant arises by a 180° rotation about the c-axis (which is not a space group symmetry operation of β-Ga₂O₃). Hence, there are four distinct growth planes: (2̅01), (101), {310} and {310}. The existence of a {310} twin variant is not immediately obvious, but its existence is revealed by the pole figure pattern presented below.

The basal growth planes under discussion can also be thought as of being the close-packing planes of the distorted fcc O sublattice of β-Ga₂O₃, i.e. the planes that are perpendicular to the body-diagonal directions of the fcc cage in FIG. 5. This is visualized in FIG. 6, which illustrates the close-packing planes of the distorted oxygen sublattice of β-Ga₂O₃: (2̅01), (101), and (310), where the O ions contained in the (310) plane are highlighted in gold (labeled 4010 in FIG. 6) for illustration of their nearly equilateral triangular arrangement in the plane. In FIG. 6, oxygen ions contained in the (310) plane are shown in gold (labeled 4010 in FIG. 6) to show their triangular arrangement in the plane. The triangular arrangement is also highlighted by the polyhedron faces shown in green (labeled 4020 in FIG. 6) and blue (labeled 4030 in FIG. 6), some of which are intersecting the (310) plane. If we mirror the (310) about the mirror plane perpendicular to the b-axis, we obtain the (310) plane (not shown), which is crystallographically identical to the (310) plane. However, as described in greater detail herein, the (310) gives rise to a twin variant in the texture on γ-Al₂O₃ (111).

Due to the missing global three-fold symmetry (indeed absence of any non-trivial rotational symmetry) of β-Ga₂O₃ when rotated about the basal growth plane normals, each distinct growth plane should give rise to a minimum of six in-plane variants of β-Ga₂O₃ when grown on the six-fold symmetric surface of γ-Al₂O₃ (111) shown in FIGS. 16A and 16B, as discussed in greater detail, below, in the section entitled “Supplemental Material for Example 1” [18, 19]. Combined with the two in-plane variants of γ-Al₂O₃ (111) observed on Si (001), there should be a minimum of 4 (#distinct growth planes)×6 (#film rotations with respect to (“w.r.t.”) substrate)×2 (#substrate orientations)=48 crystallographically distinct in-plane variants of β-Ga₂O₃ observable for this thin film.

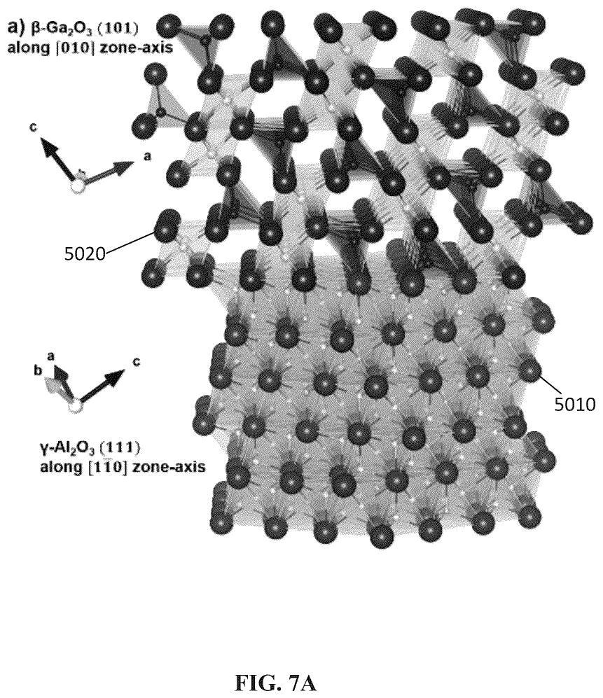

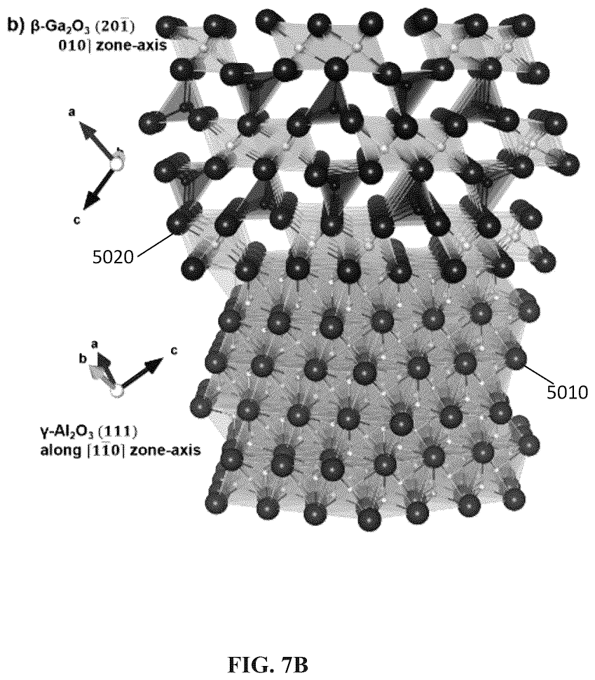

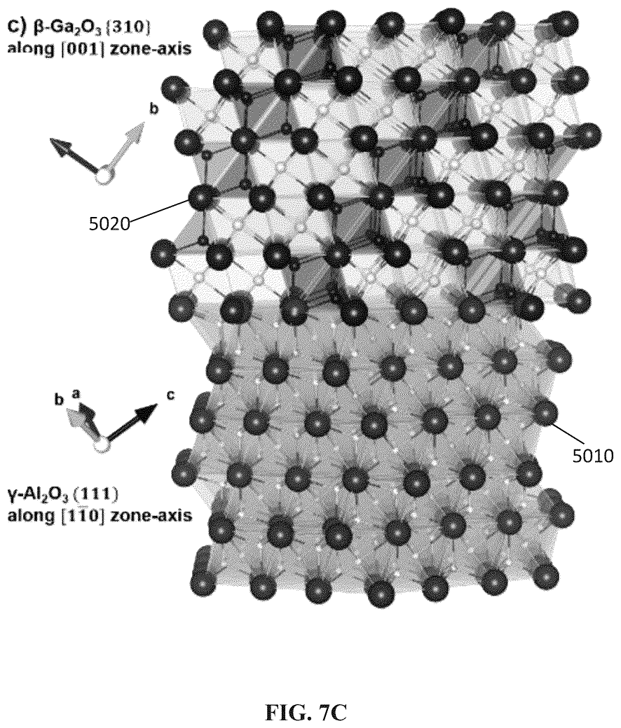

FIGS. 7A-7C illustrate representative interface models between the γ-Al₂O₃ (111) substrate and locally epitaxial β-Ga₂O₃ domain variants: FIG. 7A is (101); FIG. 7B is (2̅01); and FIG. 7C is {310}. The oxygen ions of each structure (red and purple spheres, respectively labeled 5010 and 5020 in FIGS. 7A-7C) are matched in position in the interface plane. The matching is not perfect for the bulk structures, and compressive strain is indicated near the interface for β-Ga₂O₃. Each epitaxial orientation domain gives rise to 6 in-plane variants which are obtained by rotating the β-Ga₂O₃ by multiples of 60° about the out-of-plane direction.

Representative atomistic models of feasible β-Ga₂O₃/γ-Al₂O₃ interfaces with alignment of the oxygen ions in the interface plane are presented in FIGS. 7A-7C with their crystallographic orientation relationship expressed as follows:
[010] β-Ga₂O₃ (101)∥ [symbol] 11̅0 [symbol] γ-Al₂O₃ (111) (FIG. 7A);
[010] β-Ga₂O₃ (2̅01)∥ [symbol] 11̅0 [symbol] γ-Al₂O₃ (111) (FIG. 7B);
[001] β-Ga₂O₃{310}∥ [symbol] 11̅0 [symbol] γ-Al₂O₃ (111) (FIG. 7C); and
[001] β-Ga₂O₃ {3̅1̅0}∥ [symbol] 11̅0 [symbol] γ-Al₂O₃ (111) (twin of FIG. 7C obtained by 180° rotation about the β-Ga₂O₃ c-axis).

The crystallographic relationships between γ-Al₂O₃ and Si are (1̅12) Y—Al₂O₃ (111)∥Si (001) and (110) γ-Al₂O₃ (111)∥Si (001) [60]. From FIGS. 7A-7C it can be seen that the oxygen atoms at the interface do not align perfectly when using the bulk structures. Hence, compressive strain and structural distortions are expected near the interface in the thin films due to the larger bond lengths in Ga₂O₃.

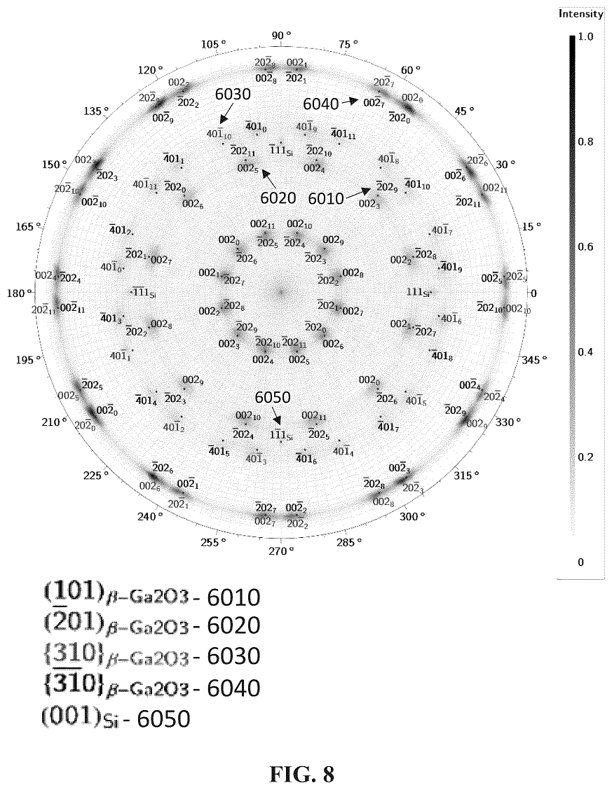

To confirm the presence of 48 in-plane variants, a full pole figure scan with 2θ_{Bragg} angle of 31.7° was conducted on the Rigaku Ultima IV diffractometer with use of parallel beam in a non-coplanar measurement geometry with an in-plane detector axis [73]. The scan was done with 2.5° vertical Soller slits on both source and detector sides, 0.5 mm divergence slit, 5.0 mm width-limiting slit, 1.0 mm receiving slit, and 1.0 mm scattering slit. A thin Ni foil was used to block out Cu—KB radiation. The 2θ angle of 31.7° corresponds to the (002) and (202) reflections of β-Ga₂O₃, which are strong intensity reflections of β-Ga₂O₃ with only two-fold multiplicity, which makes them suitable for a pole figure scan. FIG. 8 is a pole figure at 20=31.7° of (002) and (202̅) Bragg reflections of β-Ga₂O₃. The polar angle is mapped linearly onto the radial axis and extends from 0° (north pole) to 90° (equator). The experimental measurement grid is overlaid on the data, as well as the expected peak positions based on the bulk lattice constants of β-Ga₂O₃ utilizing the model of 12 in-plane variants for each of the four distinct out-of-plane orientations of (101), (2̅01), {310} and {310}. The β-Ga₂O₃ peaks are labeled with the notation hklₙ, where hkl are the Miller indices of the reflection, and the integers n € [0, 11] denote the twelve rotational variants for each out-of-plane orientation (101), (2̅01), {310} and {3̅1̅0} (color-code and numbering legend is shown in the lower left corner of FIG. 8).

The resulting pole figure is shown in FIG. 8 along with an overlay of a grid of azimuthal and polar coordinates used in the experiment, and of the calculated peak coordinates as dots (in red in colorized version) based the bulk structure lattice constants and the model of 48 in-plane variants oriented with respect to the Si substrate, as described above.

The polar angle (measured from the north pole downwards) is represented linearly on the radial axis of the plot of FIG. 8 and was measured in steps of 2.0°. To avoid total external reflection at large polar angles a minimum incidence angle of 0.4° was set in the measurement software. A polar angle of 0° corresponds to the Si out-of-plane direction. The azimuthal angle was measured in steps of 2.5°, and an azimuthal angle of 0° corresponds to the Si in-plane direction. The intensity was recorded for 5 seconds per grid point and is represented as the intensity value (in gray value) in FIG. 6. The maximum of the recorded intensity was 553 counts in the raw data. For a neater display, and to partially account for change in sampling volume and absorption with polar angle, the intensity was scaled by multiplication with the cosine of the polar angle, which is to first order proportional to the reciprocal of the absorption factor in this measurement geometry [73, 74], and then normalized by the resulting maximum. To explain the pole figure pattern fully we had to include the β-Ga₂O₃ (401) reflection, which is the closest nearby reflection in terms of Bragg scattering angle at 20=30.5°, for the {310} and the {310} orientations. The azimuthal arrangement of those (401) reflections suggests the presence of both twin variants. Due to their relative angles with respect to the growth plane normals, the (002) and (202) peaks arising from different domain variants overlap nearly on top of each other. The β-Ga₂O₃ peaks are labeled with the notation hklₙ, where hkl are the Miller indices of the reflection, the integers n € [0,11] denote the twelve rotational variants for each out-of-plane orientation (101), (2̅01), {310} and {3̅1̅0}. Additionally, we note the observation of four Si (111) reflections at polar angles of 54.7° labelled with purple-colored indices (6050). The Si (111) 2θ value is 29.3°, but its tail is picked up in this scan since it is a strong peak. γ-Al₂O₃ (220) is at 20=32.0°, but not detected in this scan because of low intensity owing to the buffer layer thickness of only 5 nm. The qualitative and quantitative agreement between the calculated peak coordinates and the peak coordinates of the experimental data is reasonable when considering the finite angular step size (for simulated pole positions, see Table 6, below, in the section entitled “Supplemental Material for Example 1”). Pole figures of plausible lattice orientations of other Ga₂O₃ polymorphs (as mentioned above) give a qualitatively and quantitatively very distinct pattern for the Bragg angle under consideration. The pole diagram of FIG. 8 therefore substantiates our model of the β-Ga₂O₃ polymorph with 48 domain variants. Deviations from the calculated peak positions can likely be explained by strain-induced deformations or by slight tilt and twist misorientations of the film. The angular resolution and step size of the scan are not sufficient to quantify strain or tilt and twist misorientations.

The morphology of the β-Ga₂O₃ thin films was observed using an image-corrected FEI Titan 80-300 high-resolution electron microscope (HREM) operated at 300 kV and a probe-corrected JEOL ARM200F scanning transmission electron microscope (STEM) operated at 200 kV. Suitable cross-section samples were prepared in the form of thin (50-100 nm) lamellae using focused-ion-beam milling and lift-out techniques, and all images were recorded with the incident electron beam aligned parallel with a Si zone axis.

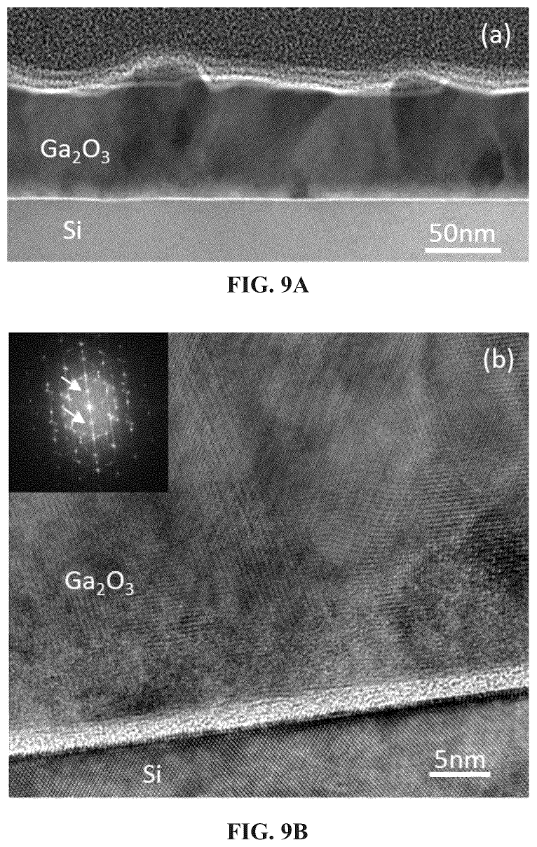

FIGS. 9A and 9B depict STEM and TEM images, respectively, of the present technology. Specifically, FIG. 9A is a bright-field STEM image showing cross-section of gallium oxide film grown on Si (001) substrate with thin alumina buffer layer, and FIG. 9B is a high-resolution TEM image showing region of gallium oxide film adjacent to alumina buffer layer. The inset of FIG. 9B shows corresponding Fast Fourier Transform (FFT)-arrows that indicate spots corresponding to β-Ga₂O₃ (2̅01)-type lattice spacings with a measured lattice spacing of 4.70 Å. FIG. 9A is a bright-field STEM image showing a representative cross section of the gallium oxide film. The contrast variations across the field of view are consistent with the multi-grain nature of the film predicted by the XRD data, while the unevenness of the top surface confirms the view that the growth rate of different crystallites depends on their relative orientation. The film thickness was estimated to be in the range of 65-70 nm, in close agreement with the XRR data. FIG. 9B shows an enlarged HREM view of the gallium oxide film close to the region of alumina-oxide buffer layer. The crystallinity of the film is clearly evident, as also shown by the inset FFT of FIG. 9B, and strong film texture is also apparent both in the image and in the FFT (see arrowed spots). Moreover, the TEM images in FIG. 9 show no evidence that the β-Ga₂O₃ film is layered (in the sense that different basal growth planes (2̅01), (101), (310) are not visibly stacked on top of each other).

Depending on the growth method and temperature, different ratios of (2̅01), (101), and 310 are observed when β-Ga₂O₃ is grown on sapphire, with some studies describing the observation of (2̅01) only [13, 34, 36, 37, 39, 40, 43, 45, 48-50, 52, 55, 57, 75-77]. This could be due to differences in dependence of the nucleation and growth rate of the individual planes on the growth temperature. A speculated growth temperature dependence of the observed planes could be related to the microscopic growth kinetics or to the surface energies of the individual planes. The surface energies for the (2̅01), (101), and (310) planes were calculated using density functional theory as detailed, below, in the section entitled “Supplemental Material for Example 1.” The (101) plane has a significantly higher surface energy of ˜1.5 Jm⁻² than the (2̅01) plane with ˜0.8 Jm⁻²; these compare favorably with the literature values of ˜ 1.8 Jm⁻² and ˜0.9 Jm⁻², respectively [78]. A calculation of the surface energy of (310) plane has to our knowledge so far not been published, here we have calculated a minimal surface energy of ˜2.1 Jm⁻² under O-rich conditions for a non-stoichiometric slab. This surface energy is larger than for both (2̅01) and (101). The surface energies of different planes of β-Ga₂O₃ have been positively correlated with the growth rates for PAMBE on these planes [79]. No obvious correlation is seen between the surface energies and the volume fractions for the film documented here. However, the (310) shows the largest surface energy and the largest volume fraction by far implicating such a relationship could exist to some degree in this thin film. Based on different growth rates, one can expect film roughening with increasing film thickness due to different growth rates of the distinct growth planes present in the film. Further work should seek to reduce the number of in-plane variants by utilizing vicinal Si (001) substrates akin to reference [49], and adjusting the growth temperature and growth conditions to see if the occurrence of the amount of distinct growth planes can also be reduced in order to prevent film roughening and achieve the goal of increased crystal grain size.

### Concluding Remarks for Example 1

In conclusion, strongly textured growth of β-Ga₂O₃ with (2̅01), (101), and {310} orientations was demonstrated on a two-domain γ-Al₂O₃ (111) e-beam evaporated buffer on Si (001). Structural order in the film texture is achieved by continuation of the oxygen sublattice from the γ-alumina buffer layer into the β-gallia film with three distinct growth planes that correspond to the close-packing planes of the oxygen sublattice of β-Ga₂O₃ plus one twin variant {310}. Each basal growth plane gives rise to 6 in-plane variants for each of the two in-plane orientations of the γ-Al₂O₃ pseudo-substrate, resulting in a total of 48 rotational domain variants. The structural integration of β-Ga₂O₃ onto Si (001) is of technological relevance as it would enable Ga₂O₃-based semiconductor devices on Si semiconductor technology, large scale wafer substrates, and the use of heat transfer technologies that are employed for Si-based high-power electronics for use in Ga₂O₃-based high-power applications. This work shows that, in principle, such a structural integration is possible and serves as a proof of concept, addressing the challenges of Si oxidation, thermodynamic instability of a Ga₂O₃/Si interface and the symmetry and lattice mismatch between Ga₂O₃ and Si. The PAMBE-grown thin films could serve as templates for a faster growth technique such as MOVPE, HVPE [2], or recently described SMBE [23], and thus enable large scale integration with Ga₂O₃ thicknesses appropriate for power-device applications.

### Supplemental Material for Example 1

This Supplemental Material contains additional data and analysis for the above described Example 1, including growth rate analysis by QCM and XRR, stoichiometry analysis by in situ XPS, additional XRD experiments and supporting analysis and supplemental tables for the XRD data of this Example 1, a further discussion on the growth model and the oxygen to gallium ratio, and finally density functional theory surface energy calculations of growth surfaces discussed above.

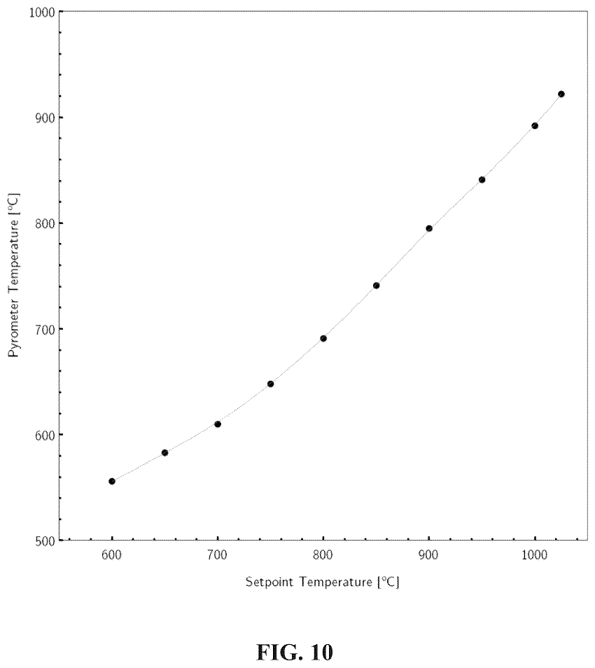

FIG. 10 is a plot demonstrating the sample heating mechanism in the MBE consists of a silicon carbide heater that is placed above the sample backside and heats the sample backside and sample holder radiatively. The sample temperatures in this Example 1 are temperatures of the SiC heater read out by a thermocouple corrected by the displayed calibration curve. The calibration curve relates the actual growth temperature on the sample surface to the manipulator setpoint temperature. The calibration curve was obtained by aiming a pyrometer through a viewport in the MBE chamber located below the sample at the growth side of a 20×20 cm² Si sample attached with a spring clip on the sample backside to a molybdenum sample holder.

### XPS Data Analysis

For a homogenous thin film f containing the element f1 with smooth coverage on the substrate s containing the element s1 we can write for the ratio A_{f,f1nl}/A_{s,s1n′l′} of measured photoelectron intensity of subshell n1 of element f1 to the measured photoelectron intensity of subshell n′l′ of element $1 [80]:

$$\frac{{A}_{f , f 1 nl}}{{A}_{s , s 1 {n}^{′} {l}^{′}}} = \frac{T ( {EK}_{f 1 , nl} )}{T ( {EK}_{s 1 , {n}^{′} {l}^{′}} )} \frac{{λ}_{f} ( {EK}_{f 1 , nl} )}{{λ}_{s} ( {EK}_{s 1 , {n}^{′} {l}^{′}} )} \frac{1 - exp [ - \frac{d}{{λ}_{f} ( {EK}_{f 1 , nl} )} ]}{exp [ - \frac{d}{{λ}_{f} ( {EK}_{s 1 , {n}^{′} {l}^{′}} )} ]} \frac{{σ}_{f 1 , n1}}{{σ}_{s 1 , {n}^{′} {l}^{′}}} \frac{{n}_{f 1}}{{n}_{s 1}} \frac{{ρ}_{f} / {M}_{f}}{{ρ}_{s} / {M}_{s}} \qquad ( 1 )$$

Here T is the analyzer response function also denoted as transmission function, EK_{f1,nl} is the kinetic energy of the ejected photoelectron from element f1 and subshell nl, λf (λₛ) is the effective attenuation length (EAL) for electrons in the film (substrate), d is the film thickness, σ_{f1,nl} is the photoelectric cross section of element f1 and subshell nl, M_{f} (Mₛ) is the molar mass of the molecules comprising the film (substrate) material, n_{f1} (nₛ₁) is the stoichiometric coefficient of element f1 (s1) in the molecules comprising the film (substrate). This equation can be solved numerically as an estimate of the thin film thickness d, as long as d≤5λ. The transmission function of our VG Scienta spectrometer was characterized, for the used experimental conditions, by a method devised by the National Physical Laboratory (NPL) of the United Kingdom [81], where survey spectra from in situ Ar sputter-cleaned copper, silver and gold samples were acquired and then referenced back to a spectrum determined on a well characterised spectrometer at NPL. The binding energy (BE) scale was calibrated using the Au 4f_{7/2}, Ag 3d_{5/2} and Cu 2p_{3/2} core-levels [82]. The EAL is estimated by using the so-called CS2-formula [80, 83]. For the theoretical photoelectric cross-sections we use the Scofield values [84].

Once the thickness d of the film layer is known (by the above estimate or another more accurate method like XRR) we can evaluate the stoichiometry of the film. The ratio of the stoichiometric coefficients n_{f2}/n_{f1} of elements f1 and f2 contained in the film layer is given by [80]:

$$\frac{{n}_{f 2}}{{n}_{f}} = \frac{{A}_{f , f 2 {n}^{′} {l}^{′}}}{{A}_{f , f 1 nl}} \frac{T ( {EK}_{f 1 , nl} )}{T ( {EK}_{f 2 , {n}^{′} {l}^{′}} )} \frac{{λ}_{f} ( {EK}_{f 1 , nl} )}{{λ}_{f} ( {EK}_{f 2 , {n}^{′} {l}^{′}} )} \frac{1 - exp [ - \frac{d}{{λ}_{f} ( {EK}_{f 1 , nl} )} ]}{1 - exp [ - \frac{d}{{λ}_{f} ( {EK}_{f 2 , {n}^{′} {l}^{′}} )} ]} \frac{{σ}_{f 1 , n1}}{{σ}_{f 2 , {n}^{′} {l}^{′}}} \qquad ( 2 )$$

Using this approach of determining the stoichiometry from fundamental parameters we found that it is necessary to adjust the O 1s Scofield cross-section [84], empirically to 0.75 times its tabulated value for a variety of investigated oxides (including Ga₂O₃, Al₂O₃, SrTiO₃, La₂O₃, Nb₂O₅) in order to arrive at the correct oxygen to metal ratio for these materials. γ-Al₂O₃ growth on Si (001)

Silicon (001) wafers with 2 inch diameter (50.8 mm), n-type phosphorous doped, single-side polished of 200 μm thickness were used as substrates (Virginia Semiconductor). The substrates were ex situ cleaned by immersion in solvent and sonication for 10 min each with acetone, 2-propanol and de-ionized water. Thereafter the substrate was blow dried with N₂ and exposed to an ozone/UV treatment for 15 min to break-up residual hydrocarbons on the surface, after which the substrate was loaded into the UHV system on a molybdenum sample holder without backplate. The UHV system consisted of a DCA MBE chamber connected via a buffer line to a VG Scienta XPS system. The SiO₂ layer was desorbed in situ in the MBE chamber using the Sr desorption method [85], resulting in a 2×1 surface reconstruction of Si (001) observed by reflection high-energy electron diffraction (RHEED) shown in FIG. 3A.

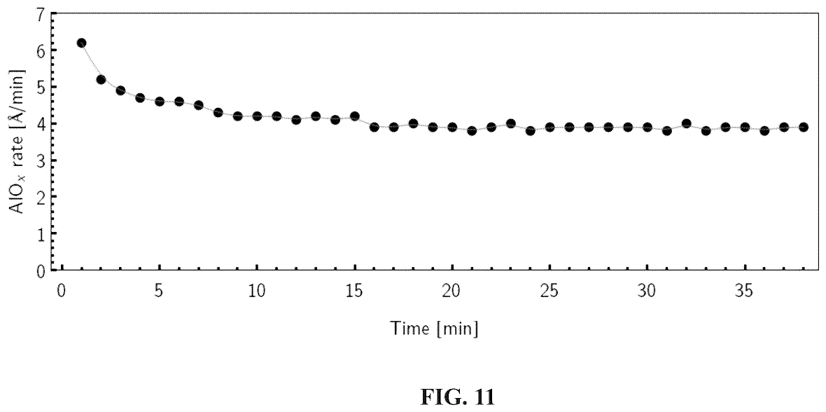

FIG. 11 is a plot depicting alumina rate via e-beam evaporation measured by QCM at an e-gun voltage of 7.75 kV and an emission current of 50 mA resulting in an oxygen partial pressure of ˜10⁻⁷ torr without supplying additional oxygen in the form of molecular O₂ gas. The rate of about 3.9 Å/min, and also the O₂ partial pressure resulting from the alumina evaporation were very stable over time. After the aforementioned Sr desorption, the sample was then heated to the deposition temperature of 840° C. Al₂O₃ was deposited by e-beam evaporation with an acceleration voltage of 7.75 kV and an emission current of 50 mA, which resulted in a very stable alumina deposition rate of 3.9 Å/min determined by a quartz crystal microbalance placed near the substrate before growth (FIG. 11), and an oxygen partial pressure of ˜10⁻⁷ torr measured by a residual gas analyzer/quadrupole mass spectrometer (RGA/QMS) and by an ion gauge.

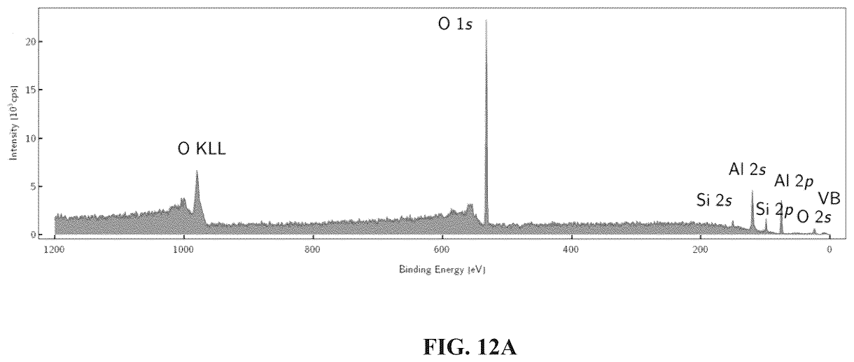

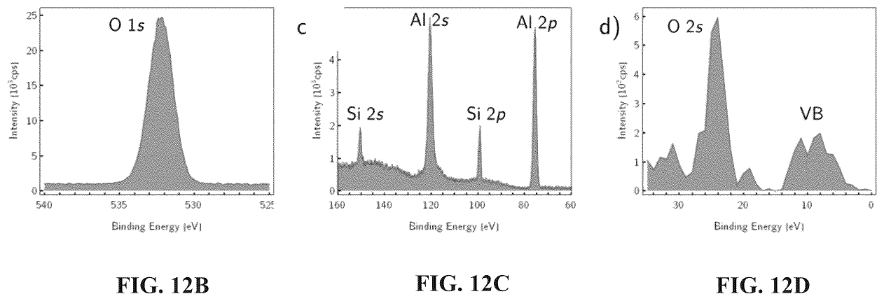

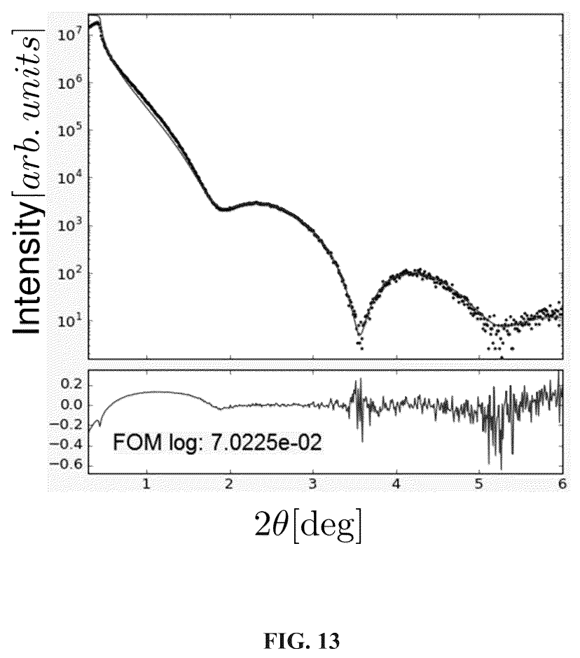

FIGS. 12A-12D depict XPS data taken in situ after growth of e-beam evaporated alumina on clean Si with a VG Scienta spectrometer with monochromatic Al-Kα and R3000 hemispherical analyzer at 200 eV pass energy. FIG. 12A is a survey spectrum showing no impurity elements or surface contamination within the accuracy of XPS. FIG. 12B is the O 1s core-level. FIG. 12C shows the Si 2s, Al 2s, Si 2p and Al 2p core-levels, indicating a thin layer of aluminum oxide on Si without the presence of Si—O bonds at the interface. Al 2s sits on the plasmon loss peak of Si 2p. FIG. 12D is the low count and low-resolution valence band spectrum from the survey spectrum of FIG. 12A (step size 1 eV). FIG. 13 depicts plots of XRR data (dots in upper panel plot, in blue) and GenX simulation (curves, in red, in upper and lower panels) of Al₂O₃/Si. The simulation parameters are 5.0 nm Al₂O₃ thickness. Surface roughness σ value of 5.8 Å and a molecular density of 0.020 Al₂O₃ formula units per Å³, very close to the bulk value of 0.021 Al₂O₃ formula units per Å3 of Y—Al₂O₃. The Si substrate roughness value was modeled with ø=1.4 Å.

The alumina source consisted of alumina pellets (1-3 mm pieces of 99.99% purity). Alumina was deposited on the substrate at 840° C. without supplying additional oxygen for two hours. This resulted in a stoichiometric Al₂O₃ layer of 5.0 nm without the formation of SiO₂ at the Al₂O₃/Si interface as determined ex situ by x-ray reflectivity (XRR) and in situ by x-ray photoelectron spectroscopy (XPS) (see FIGS. 12A-12D and 11, and Tables 2, 3 and 4, below). The determined thickness amounts to an average sticking probability for alumina on silicon of about 11% under the given growth conditions. It is speculated that the high substrate temperature protects the Si surface from oxidation by residual oxygen generated by e-beam irradiation of the alumina source but also leads to re-evaporation of arriving alumina/aluminum suboxide. The RHEED pattern after growth, displayed in FIG. 3B, repeats every 30° and therefore shows a 12-fold rotational symmetry. The streaky 12-fold RHEED pattern indicates the formation of a smooth γ-Al₂O₃ (111) with two in-plane variants, as described previously [86].

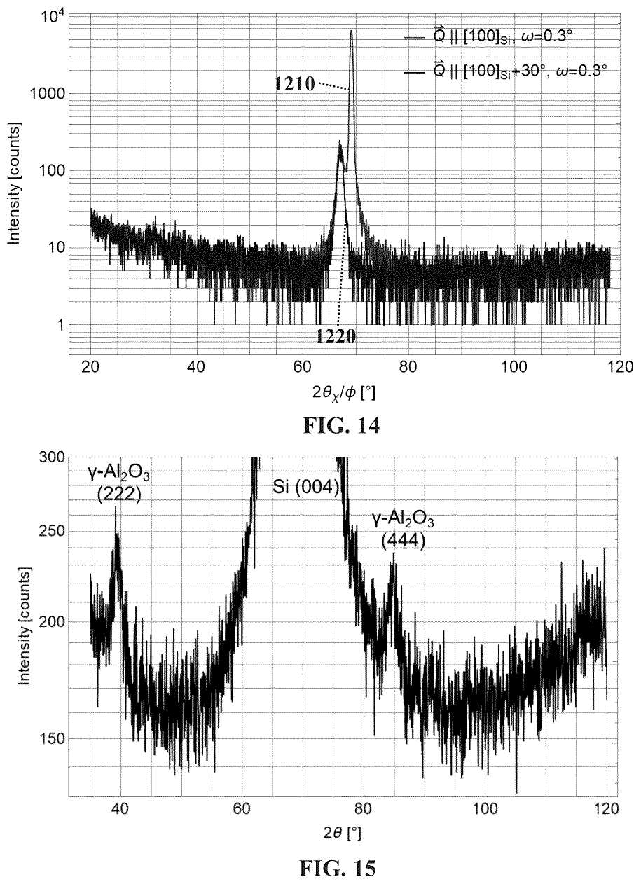

FIG. 14 depicts results of in-plane XRD coupled 2θ_{χ}/φ scan of 5 nm thick Al₂O₃/Si conducted on the Rigaku Ultima IV with in-plane arm, using parallel beam, Ni Cu—KB filter and 0.5° vertical Soller slits on source and detector sides. The incidence angle was 0.3° slightly above the critical angle of bulk Al₂O₃ for Cu-Kα radiation. The Q-vectors were parallel to Si (red curve 1210) and 30° off from Si (blue curve 1220). The peak positions were fitted by pseudo-Voigt functions. For γ-Al₂O₃ (440) along [100]_{Si}+30°: 20%=67.091°, d=1.394 Å→Y-Al₂O₃a=7.886 Å, FWHM=1.13°→crystallite size ˜83 Å. For γ-Al₂O₃ (440) along si: 20%=67.114°, d=1.394 Å→γ-Al₂O₃a=7.886 Å, FWHM=1.39°→crystallite size ˜67 Å. For Si (004) along [100]_{Si}: 2θ_{χ}=69.173°, d=1.357 Å→Si a=5.428 Å, FWHM=0.51° (limited by in-plane Soller slit resolution of 0.5° Soller slits)→crystallite size ˜190 Å (very underestimated due to low in-plane resolution).

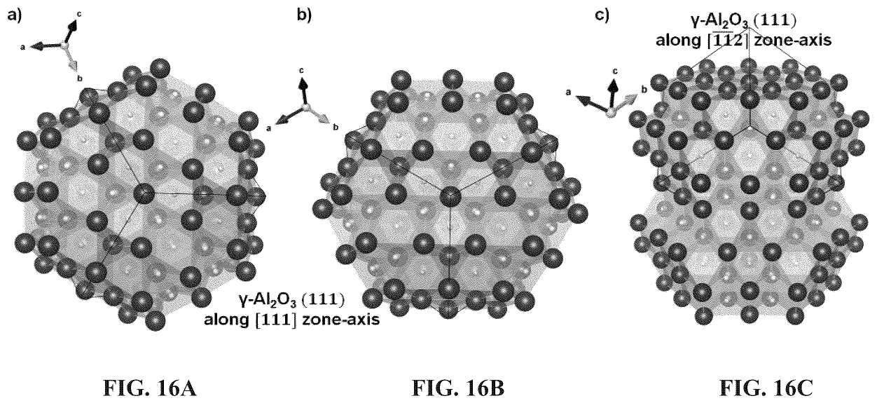

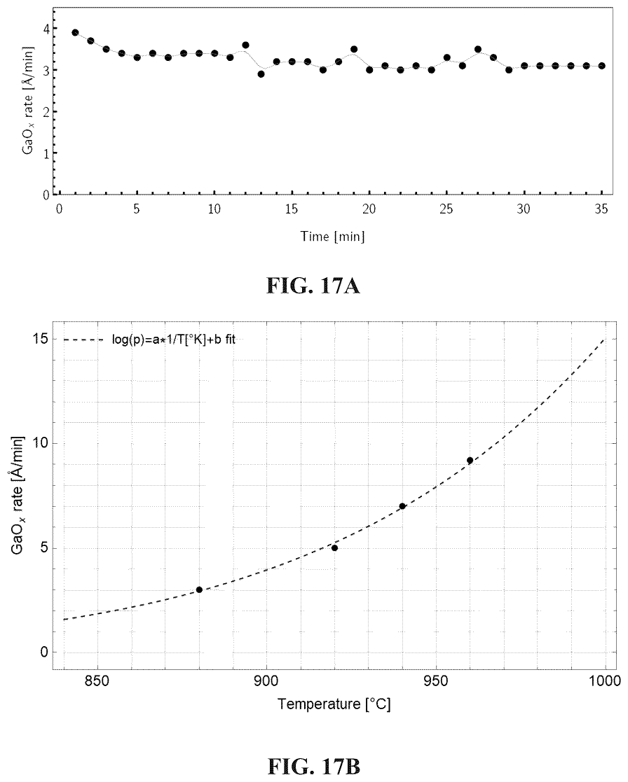

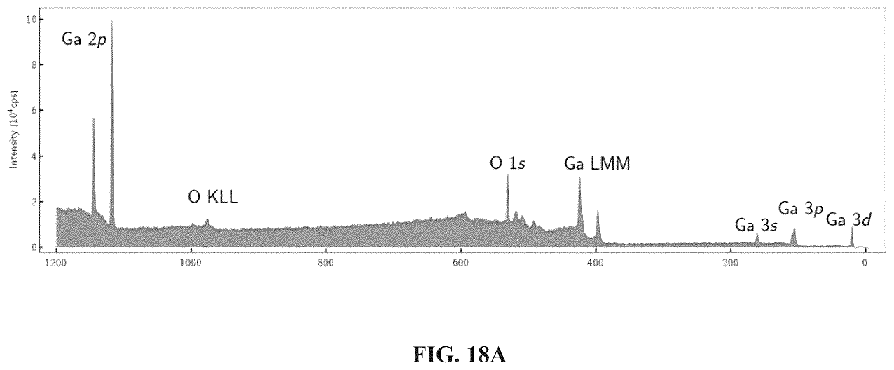

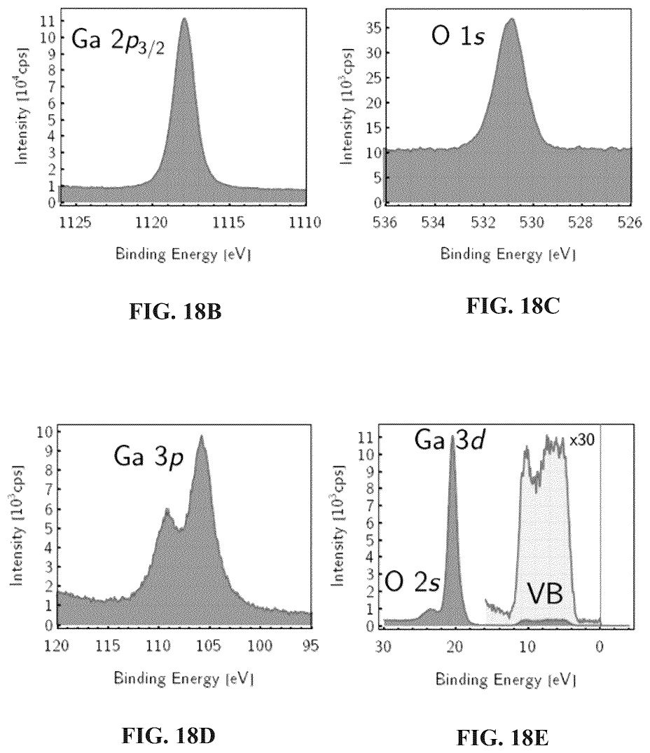

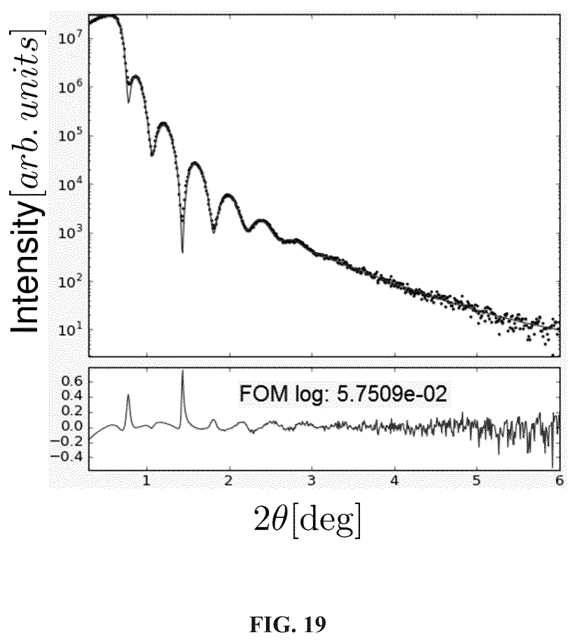

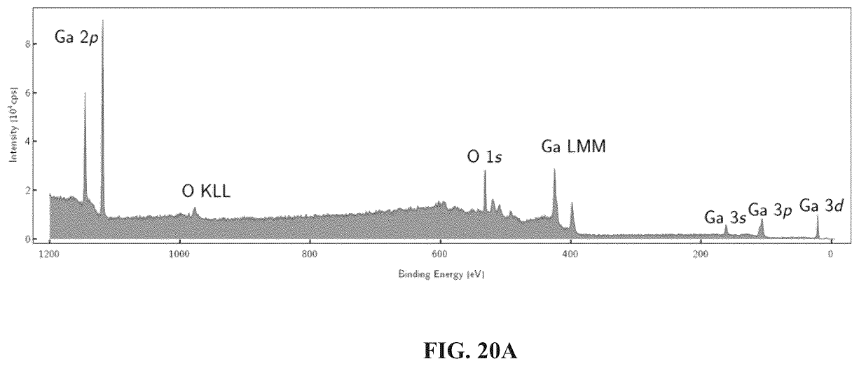

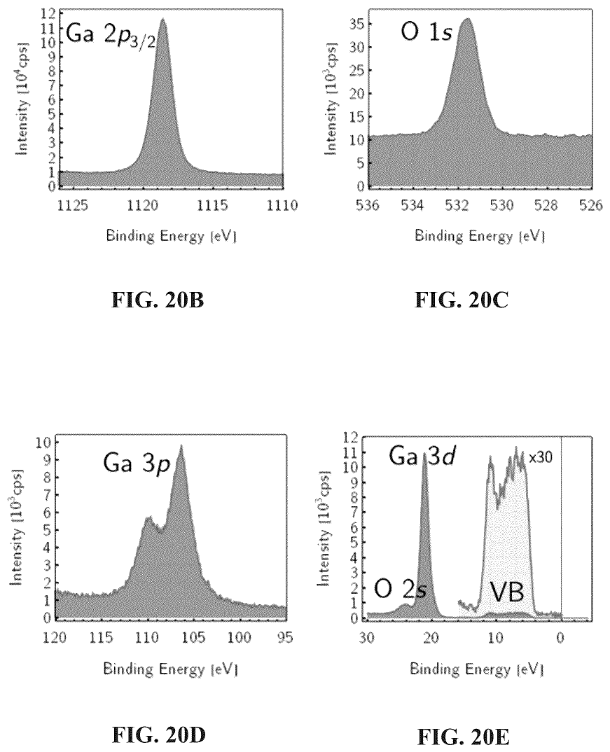

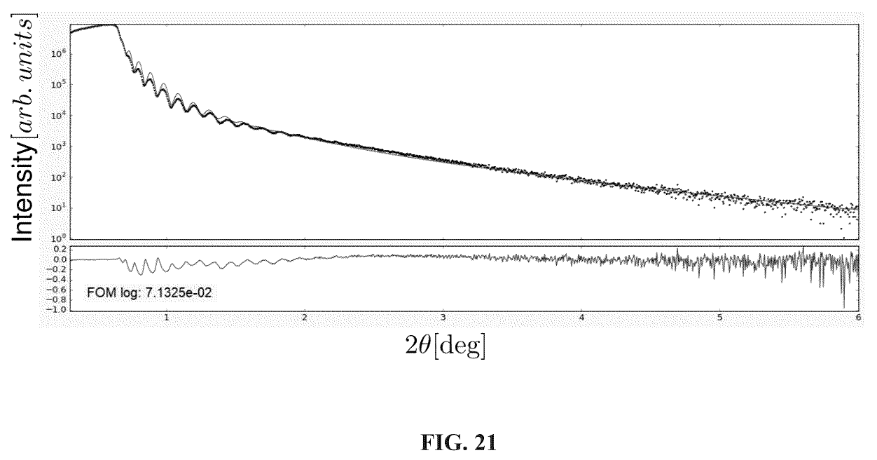

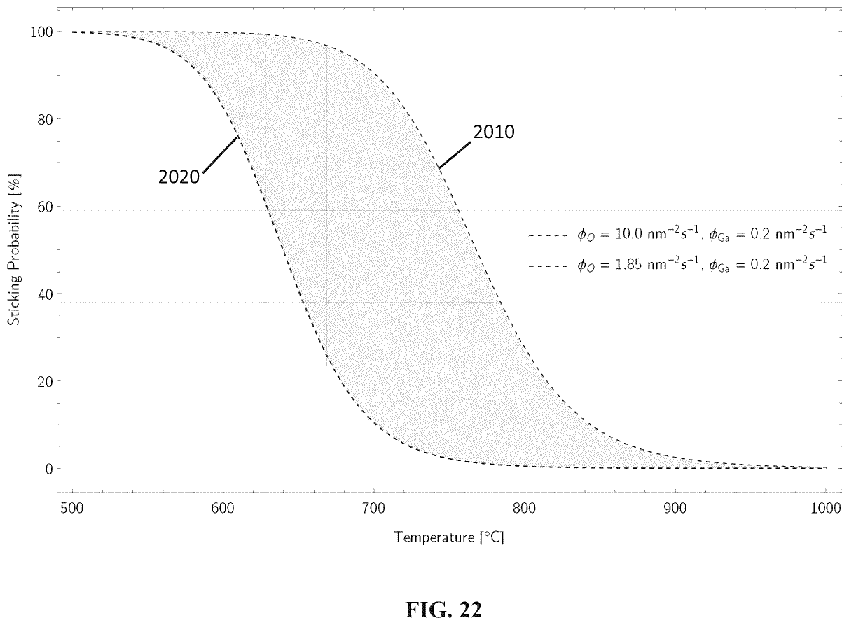

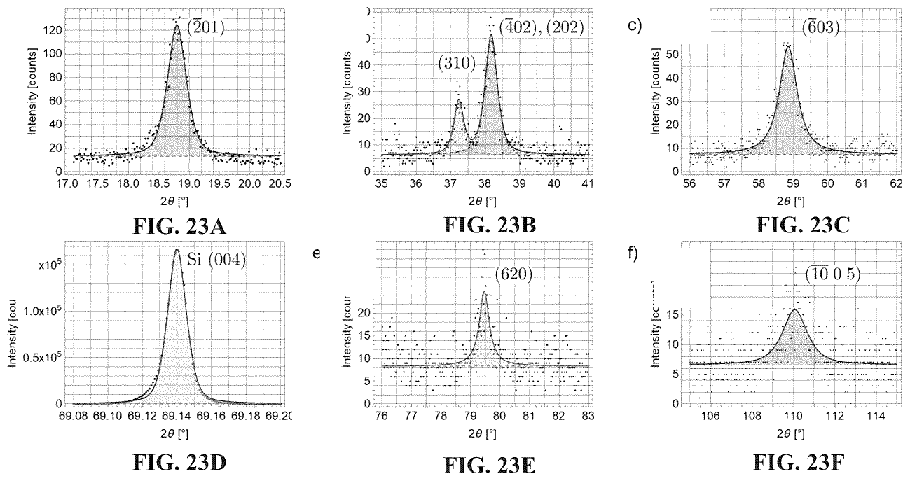

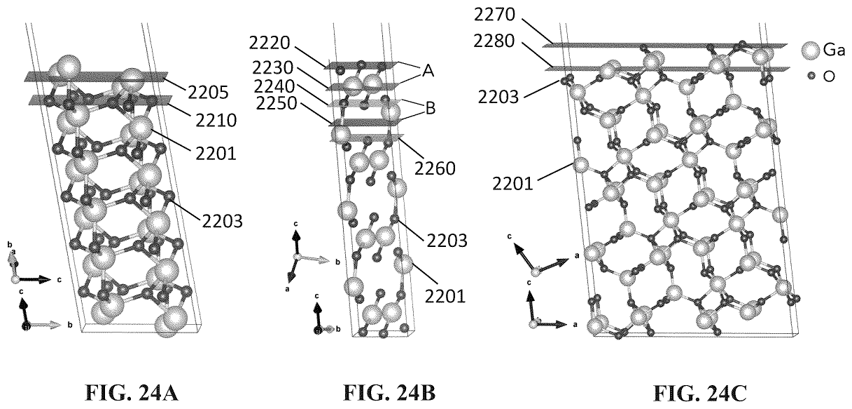

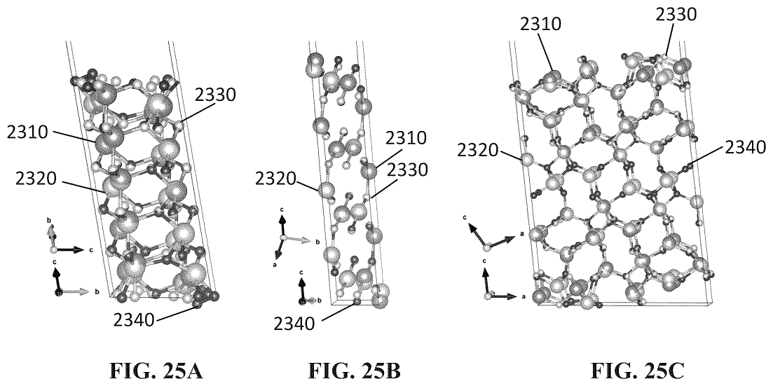

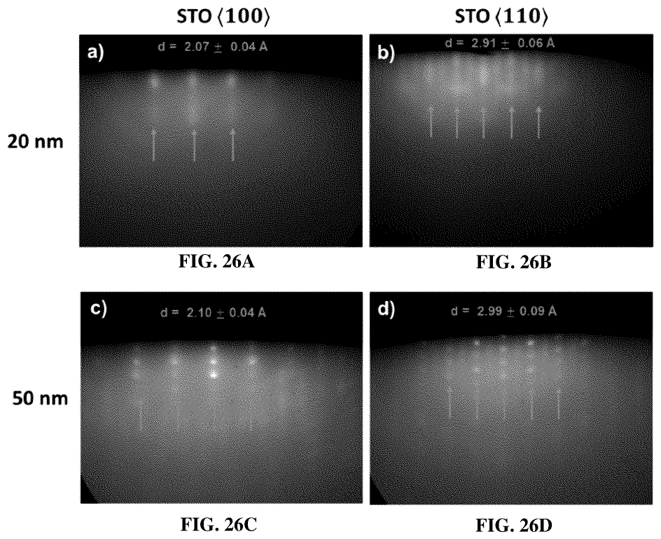

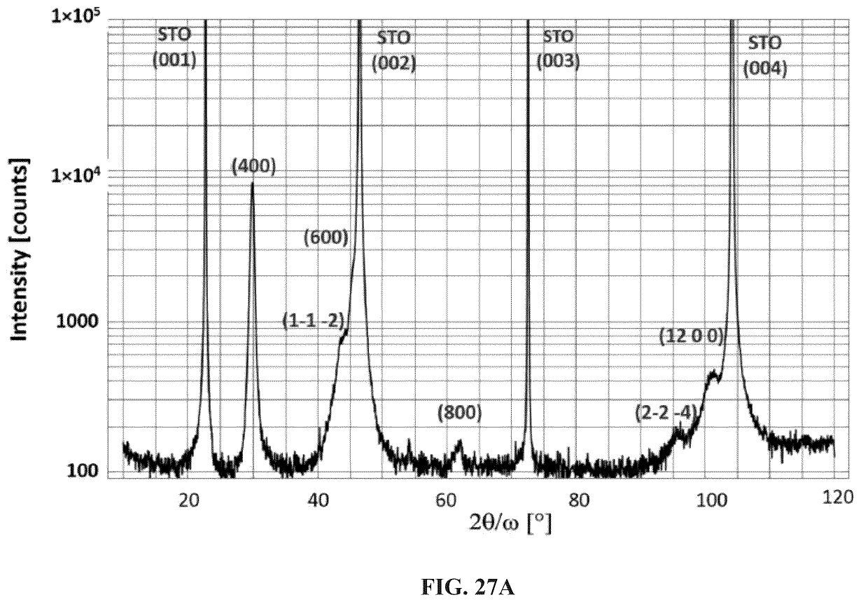

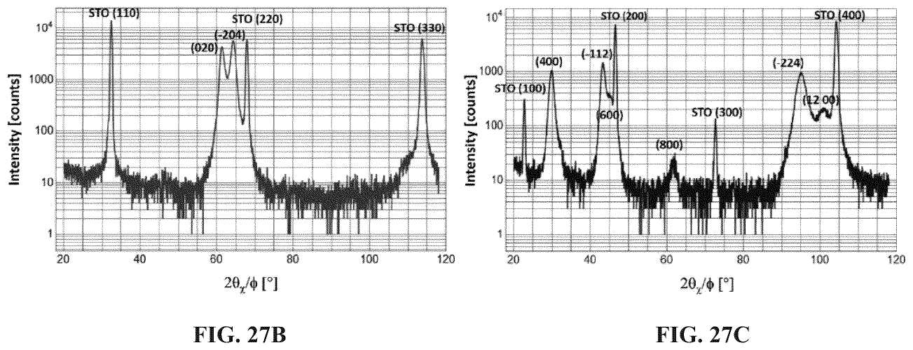

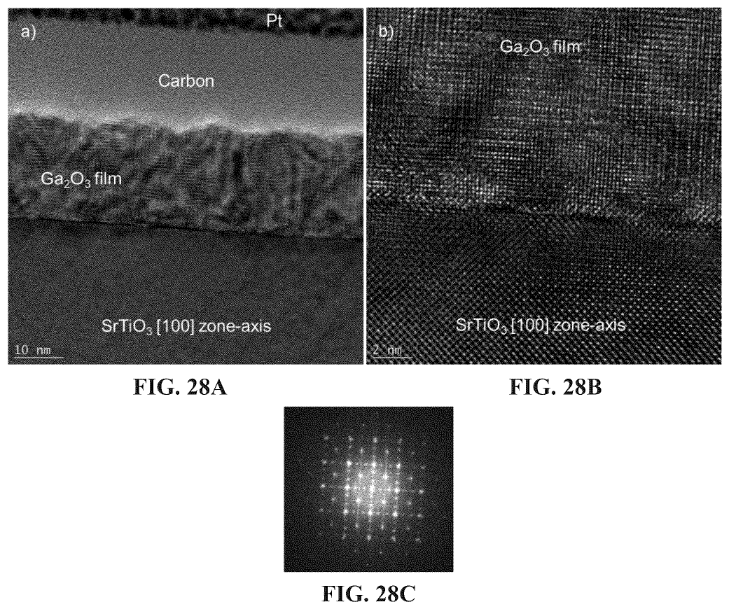

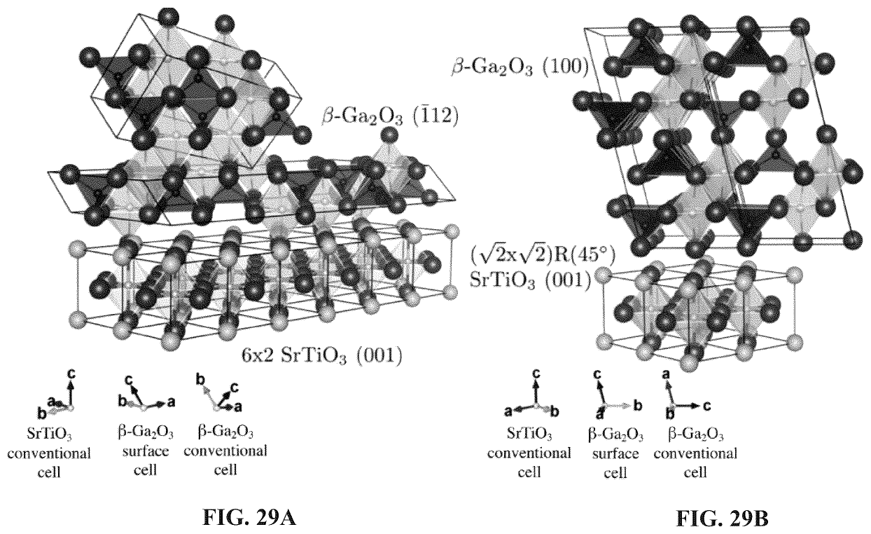

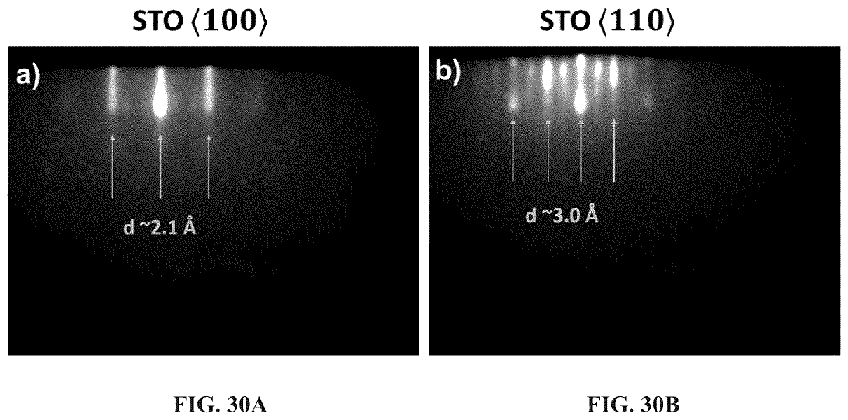

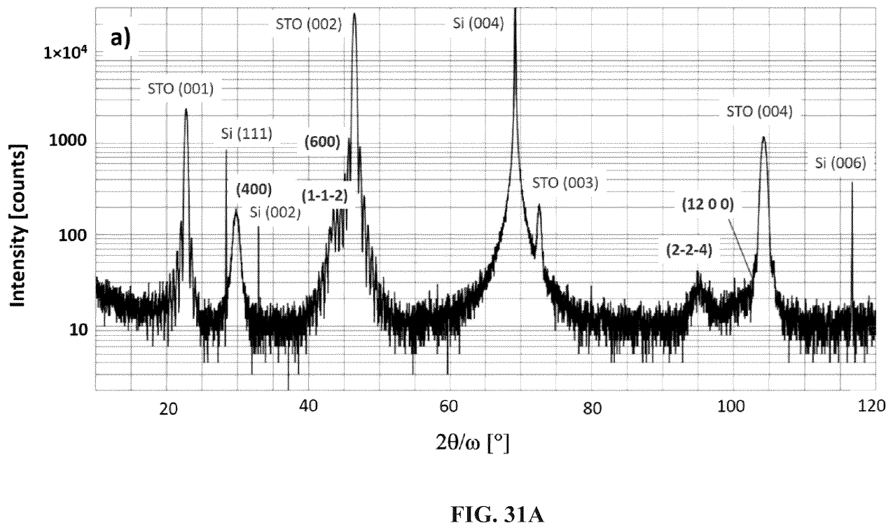

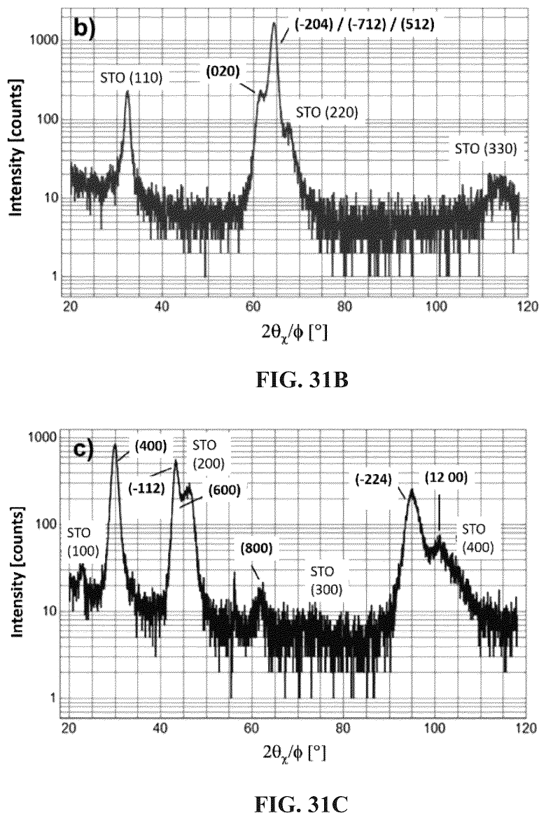

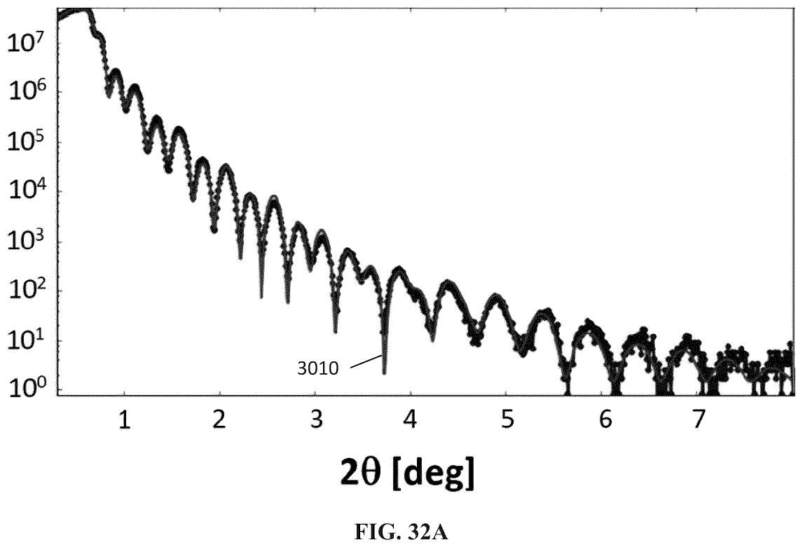

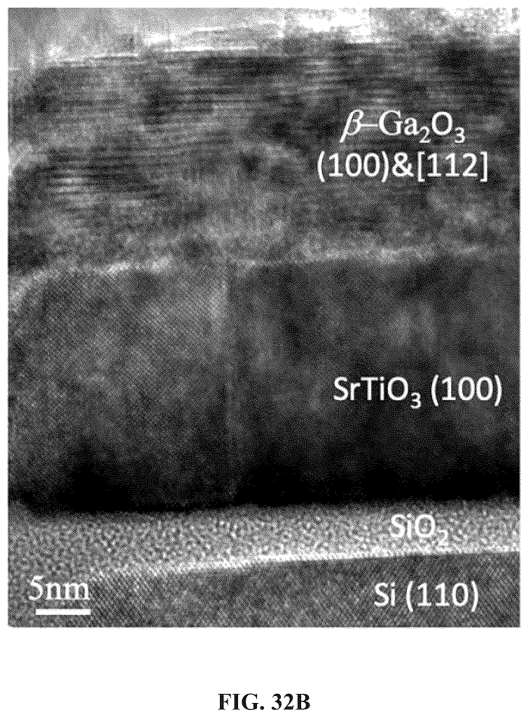

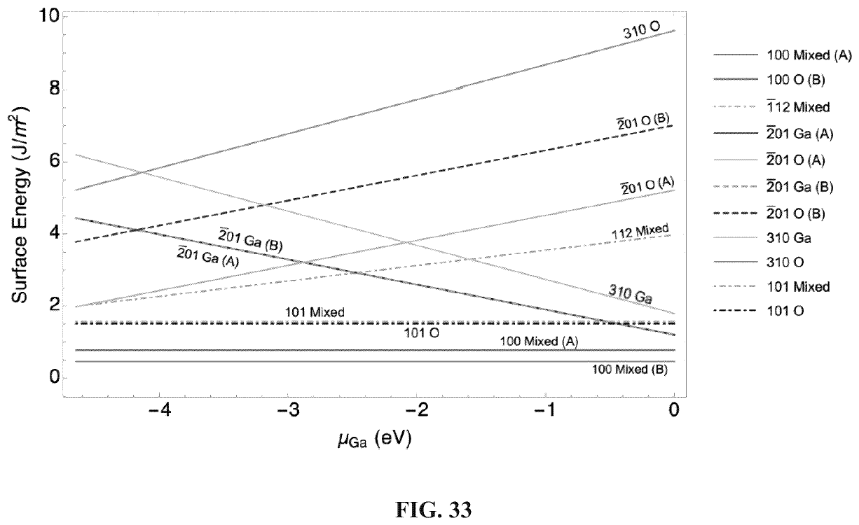

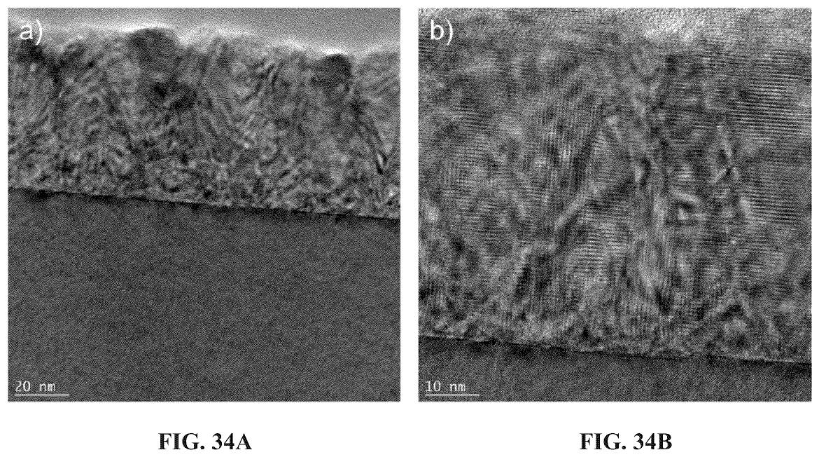

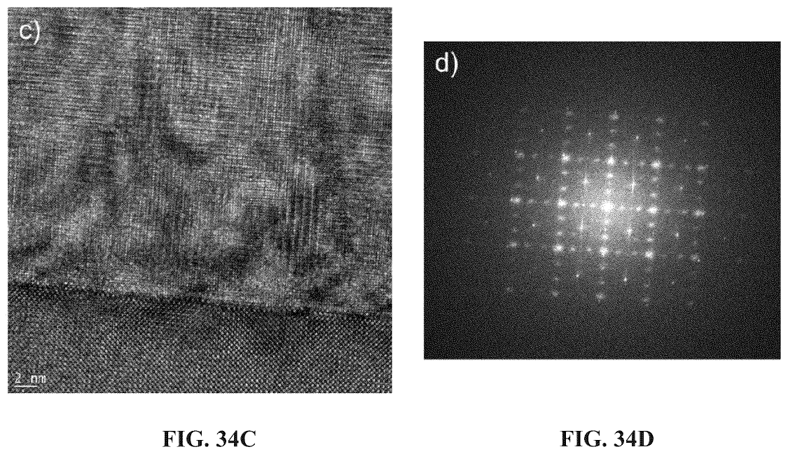

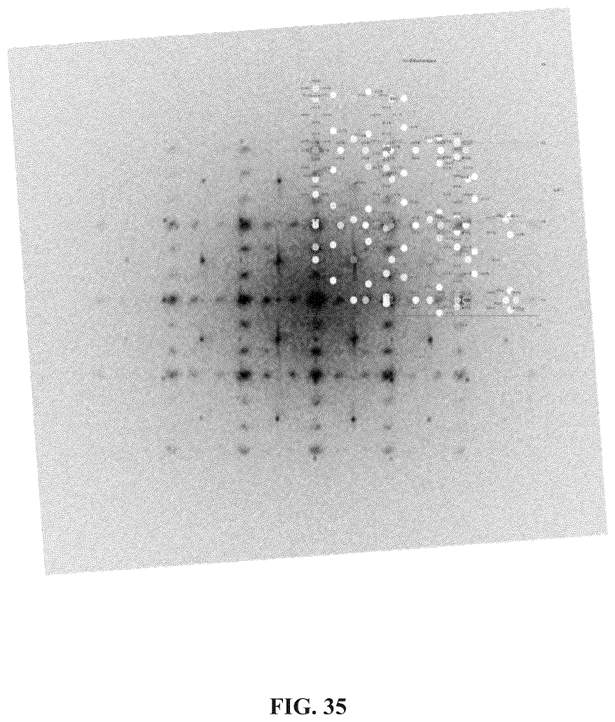

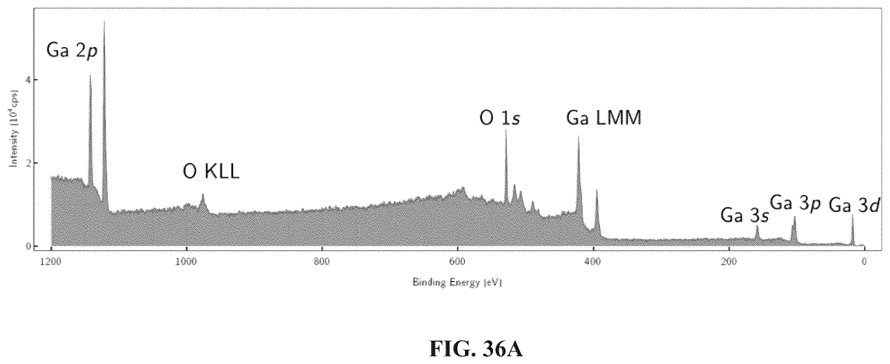

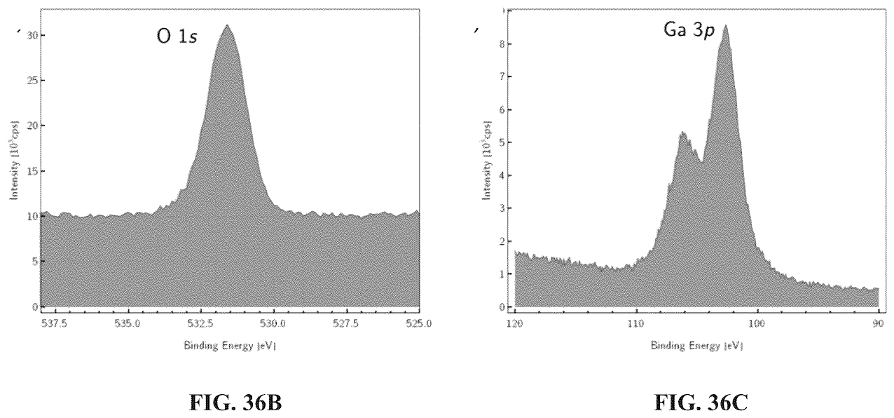

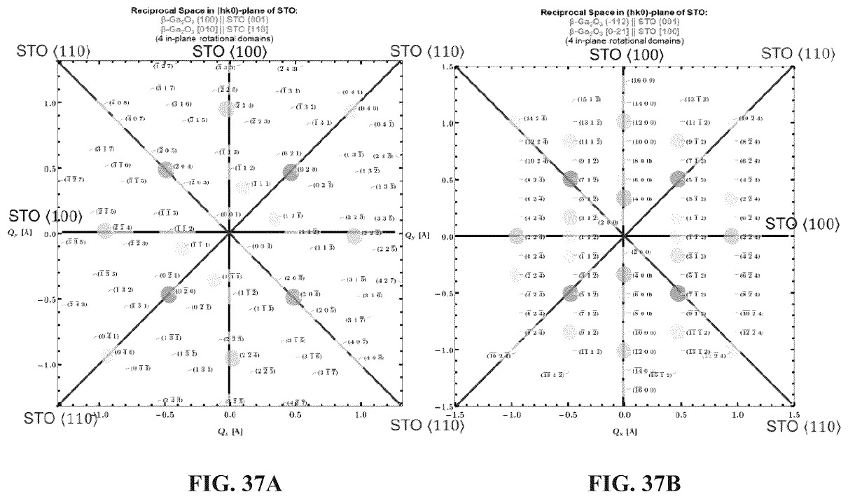

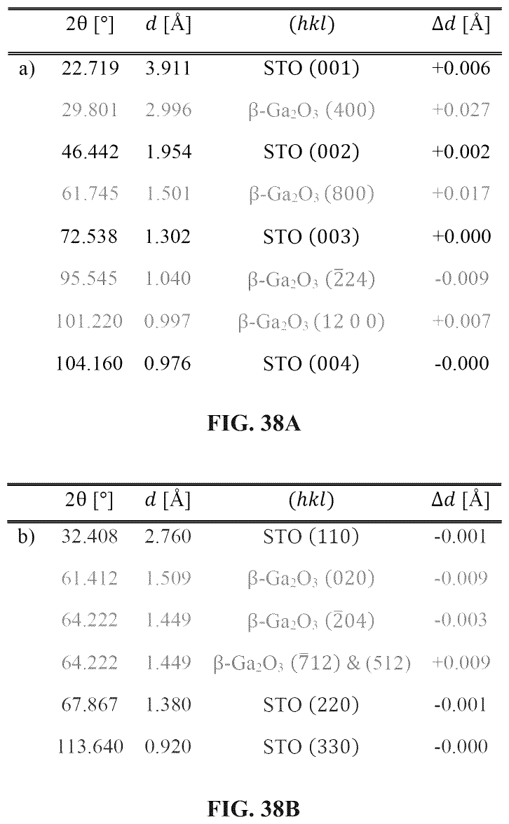

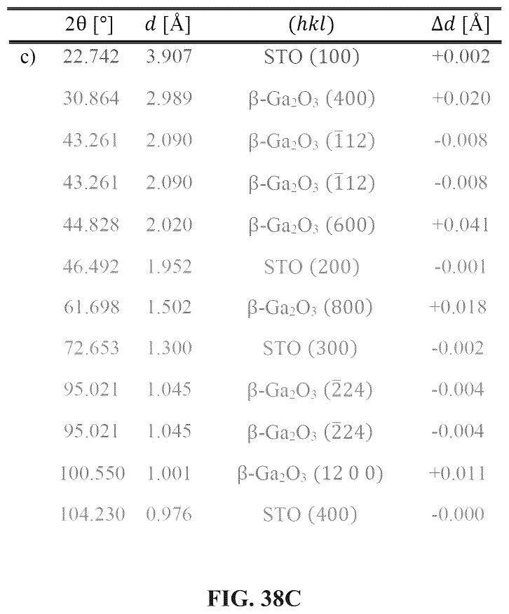

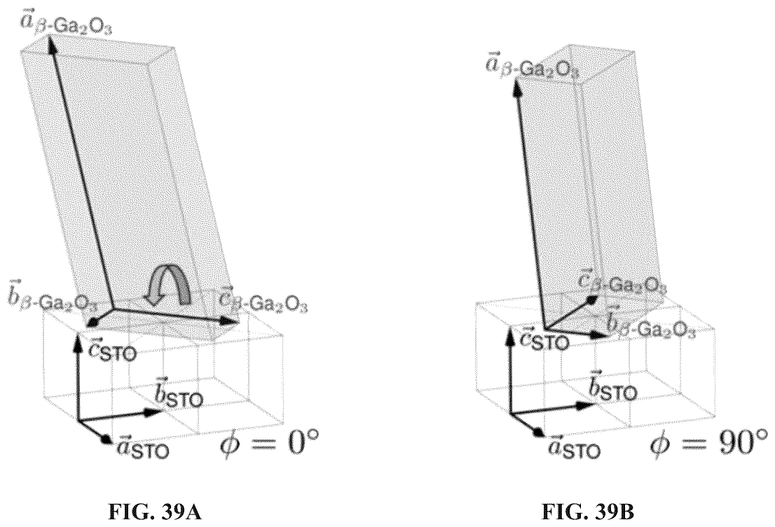

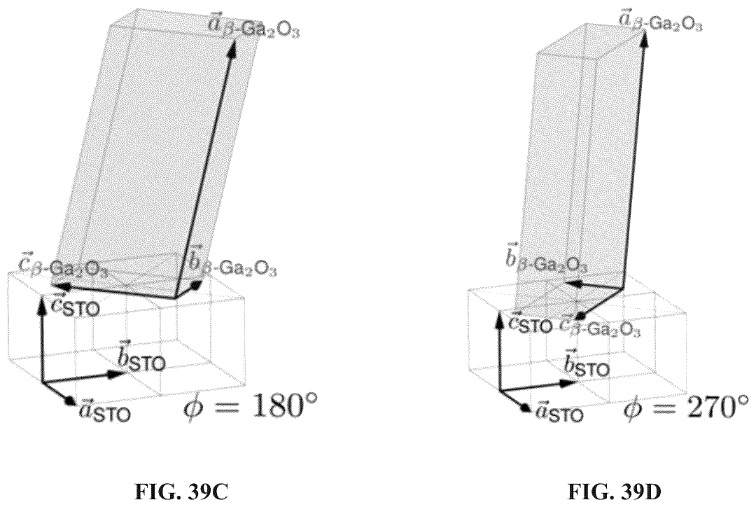

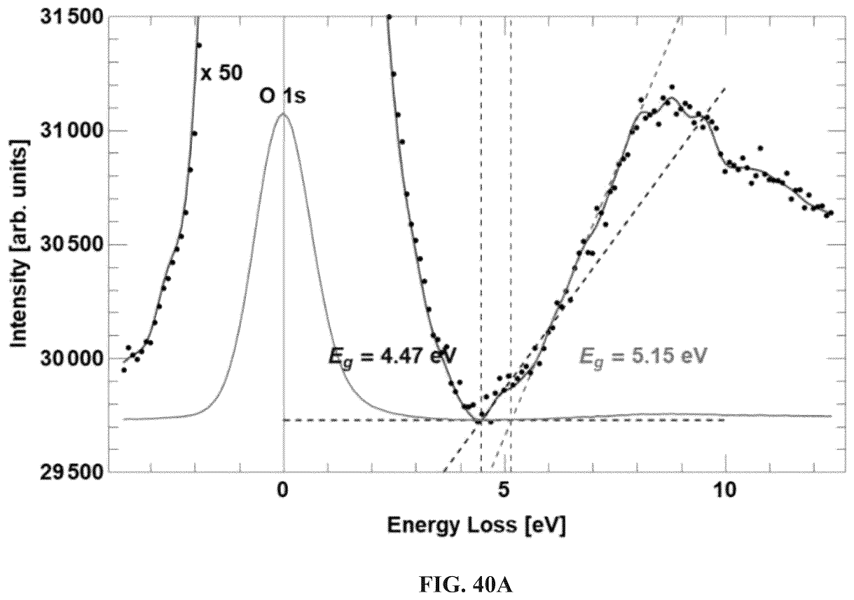

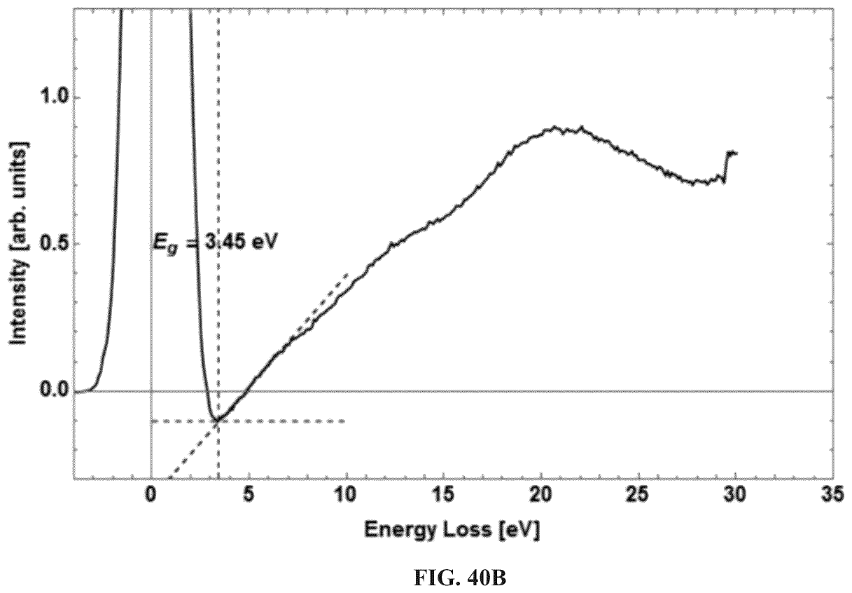

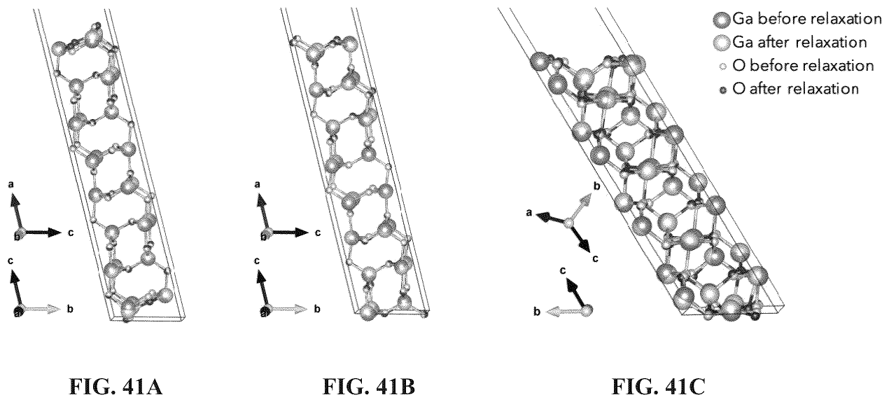

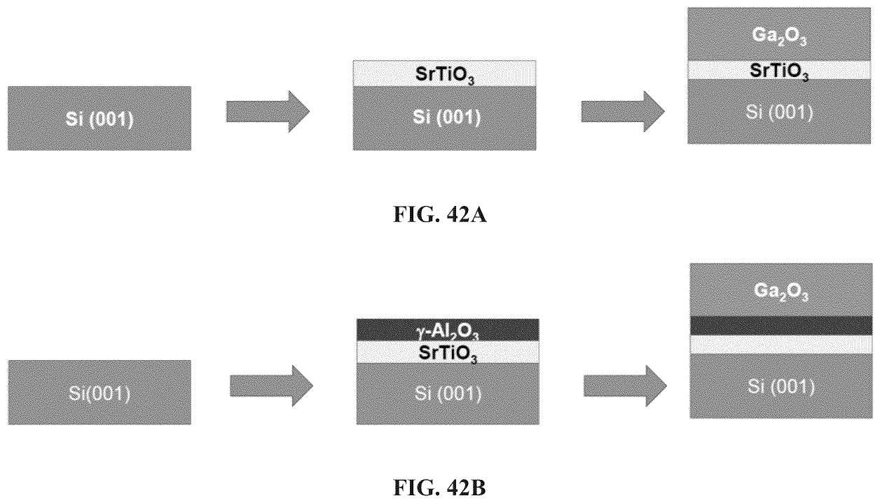

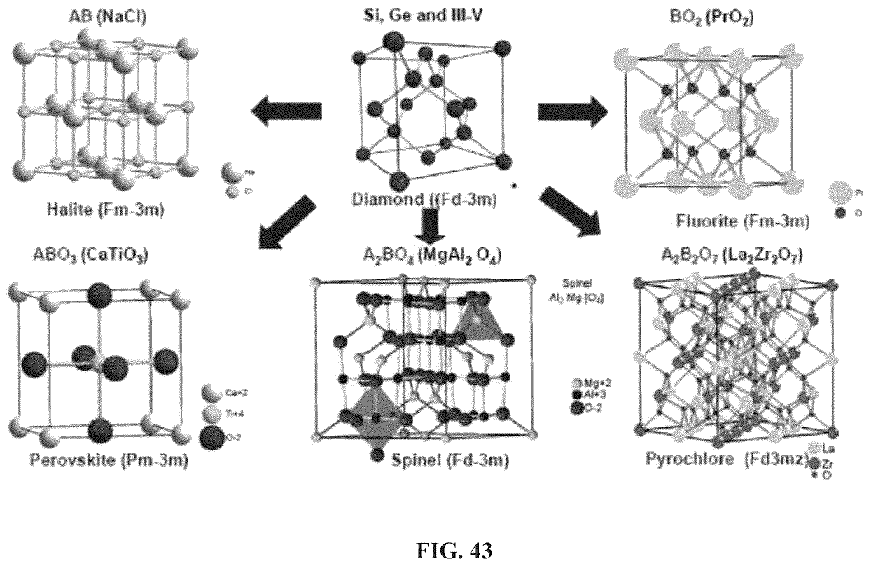

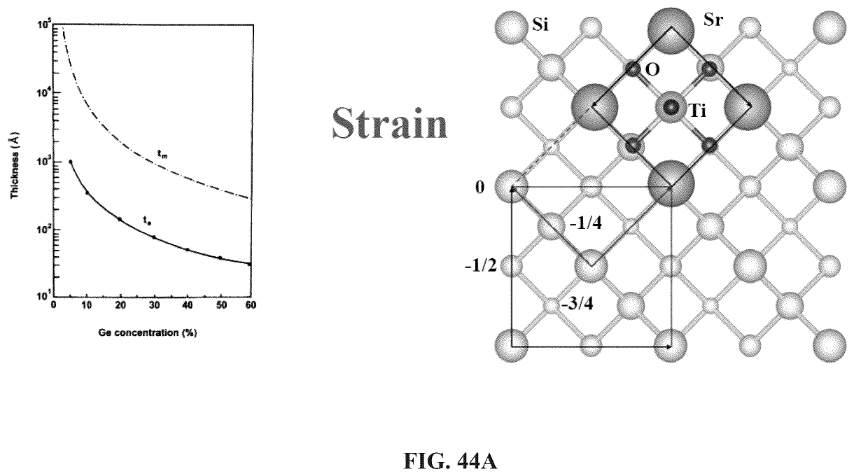

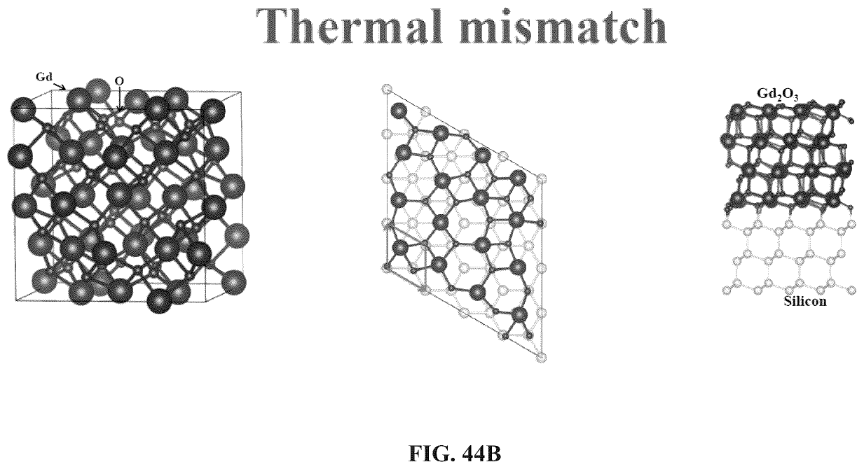

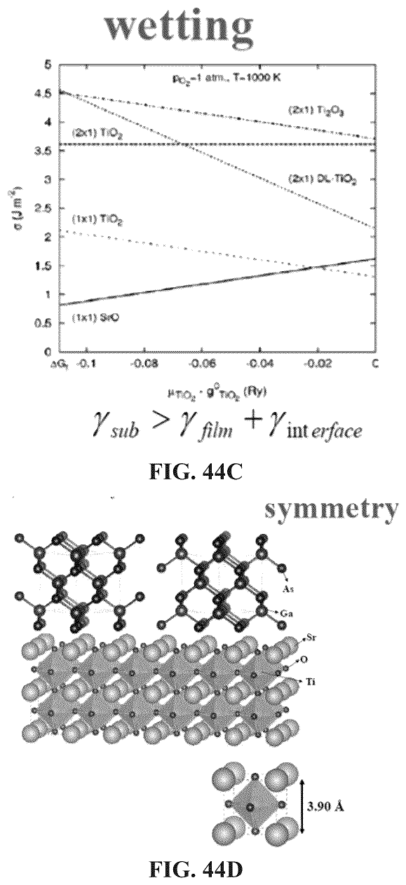

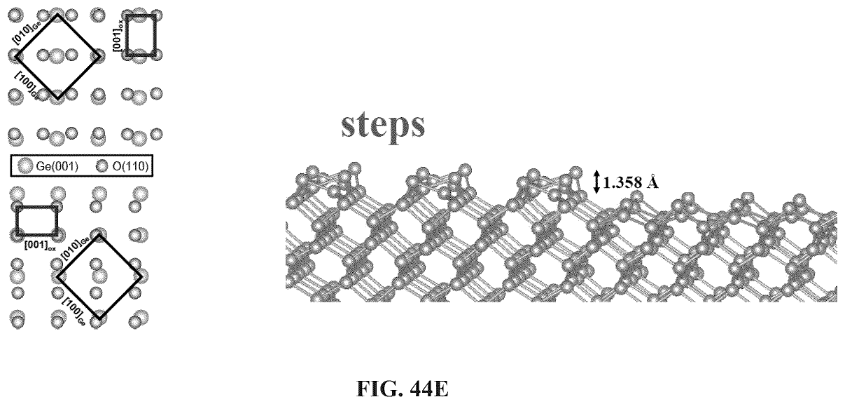

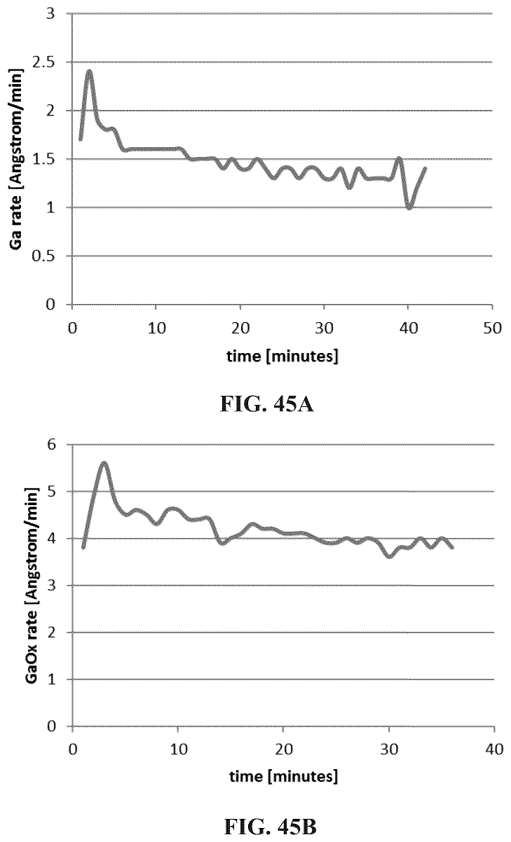

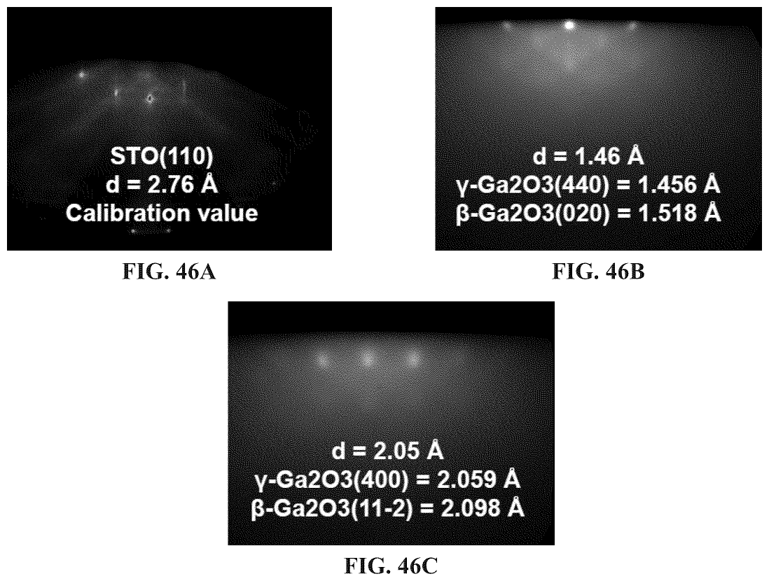

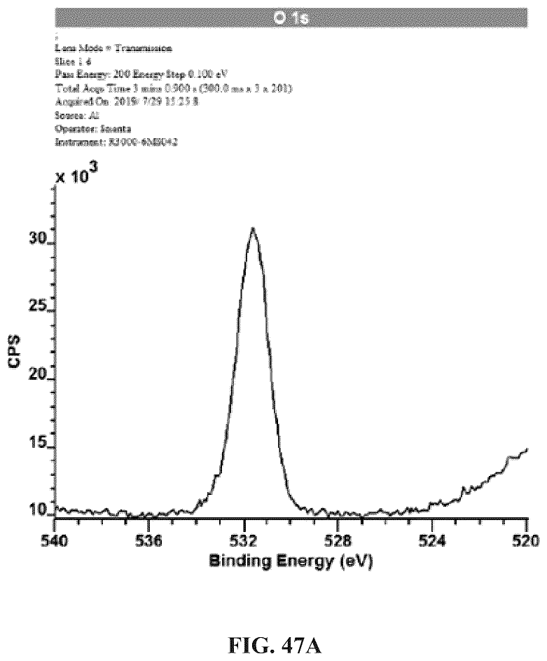

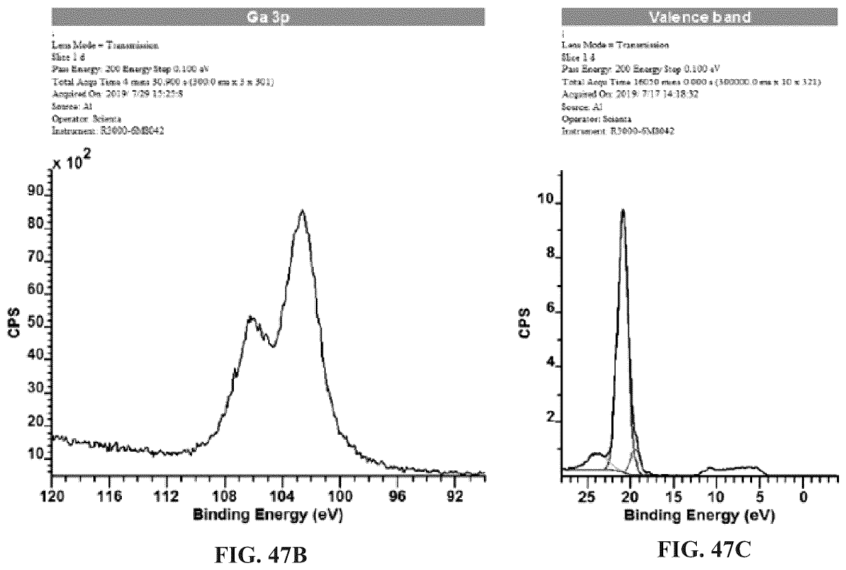

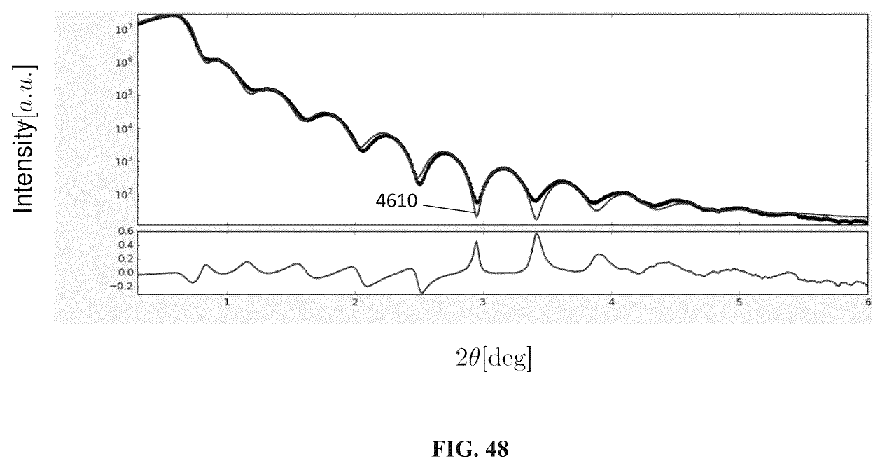

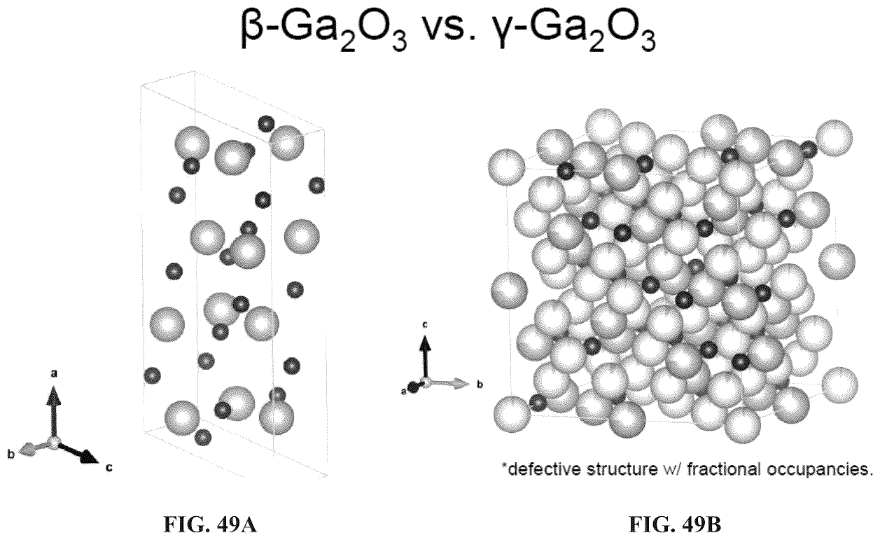

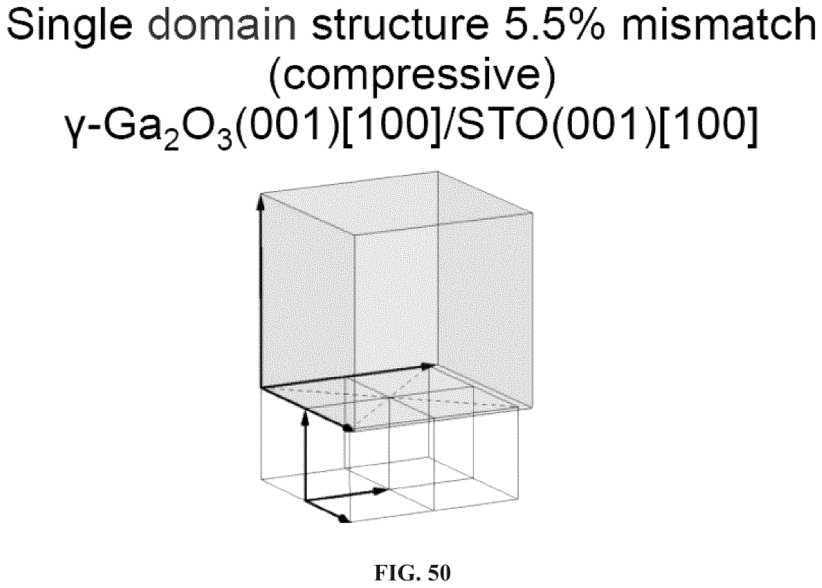

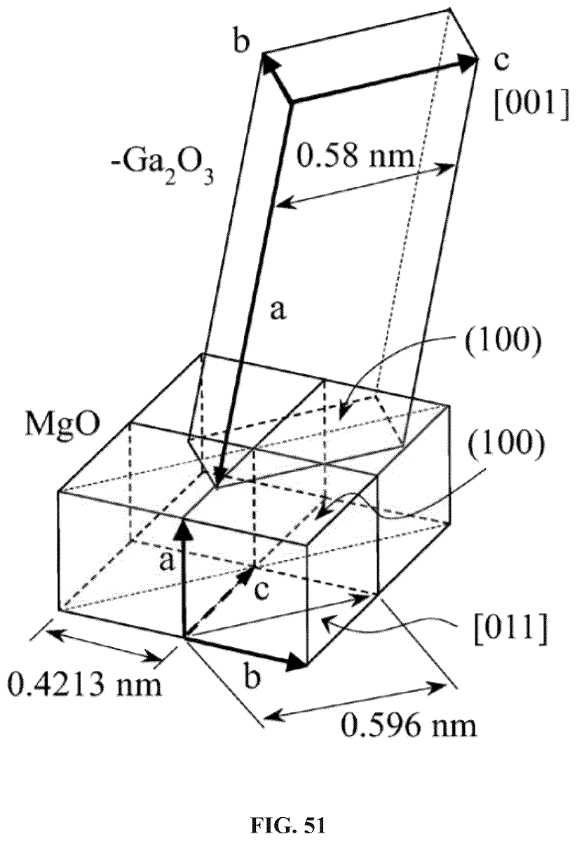

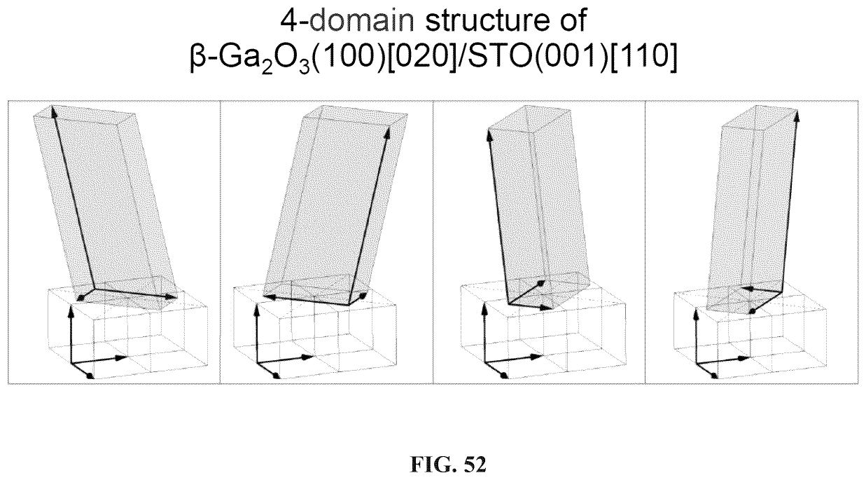

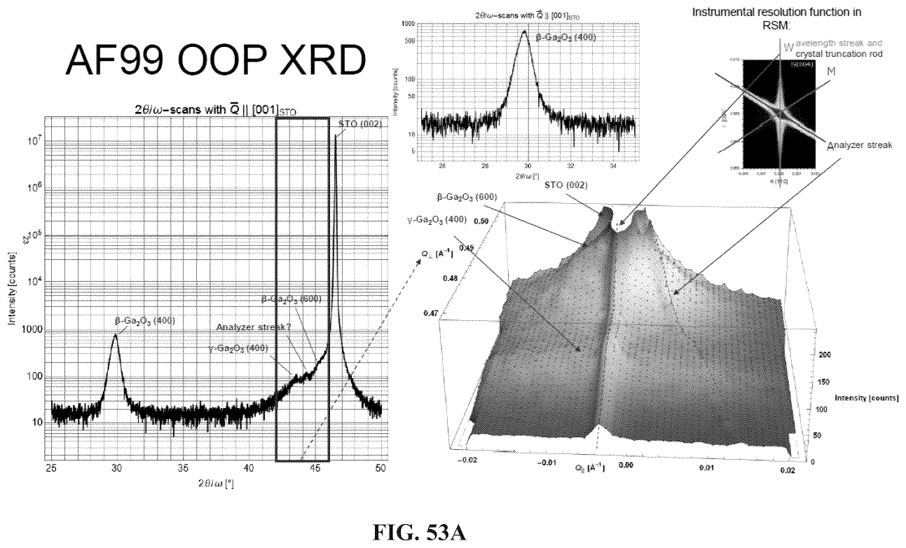

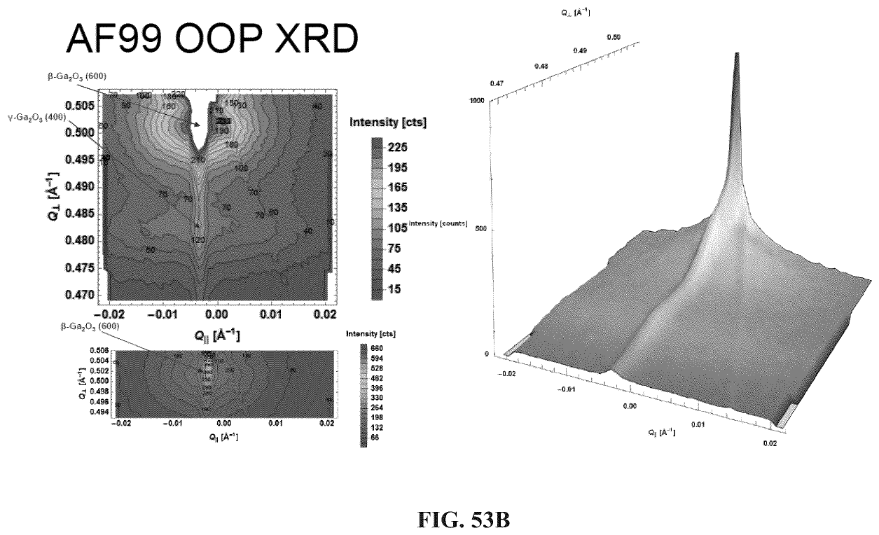

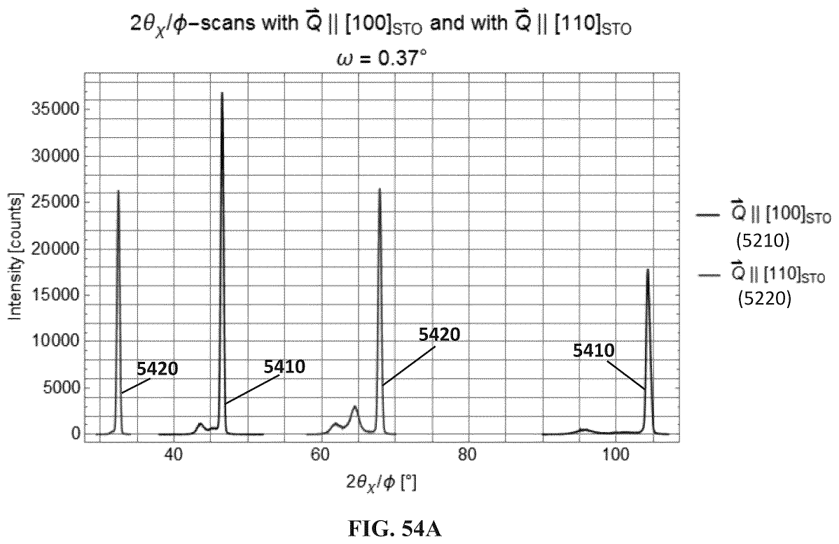

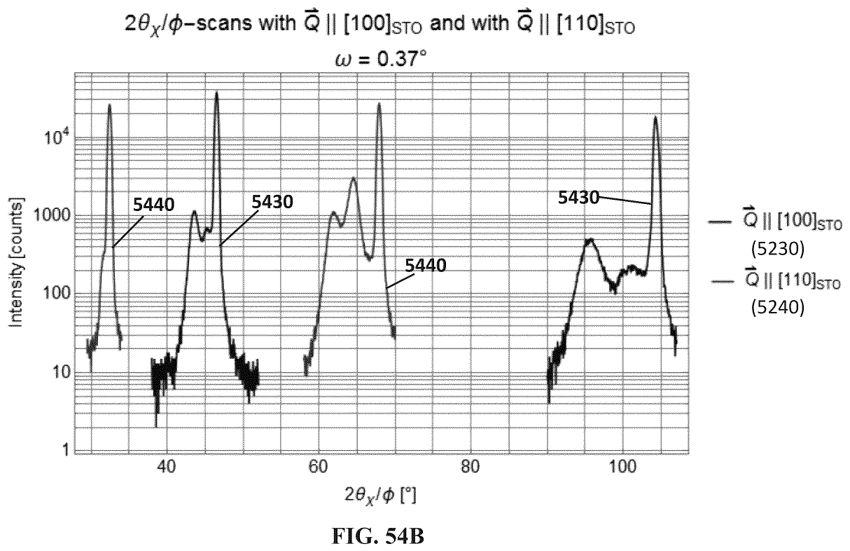

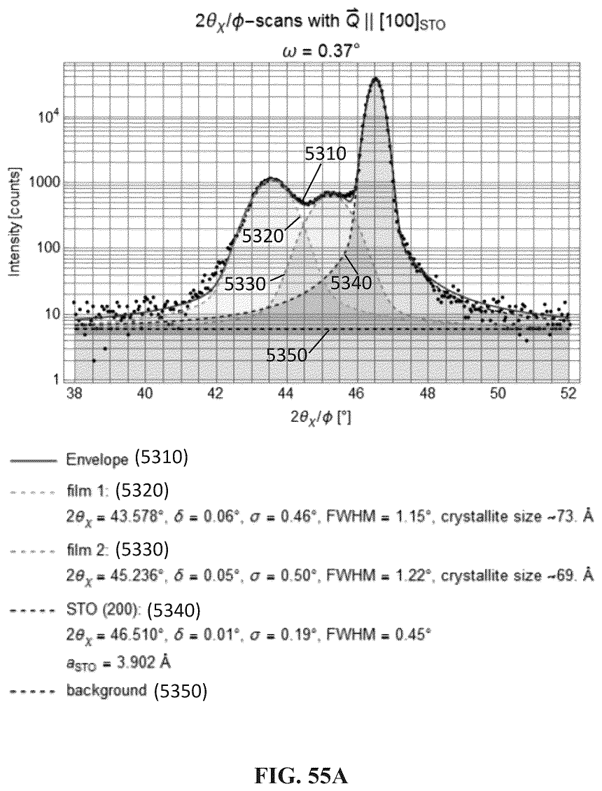

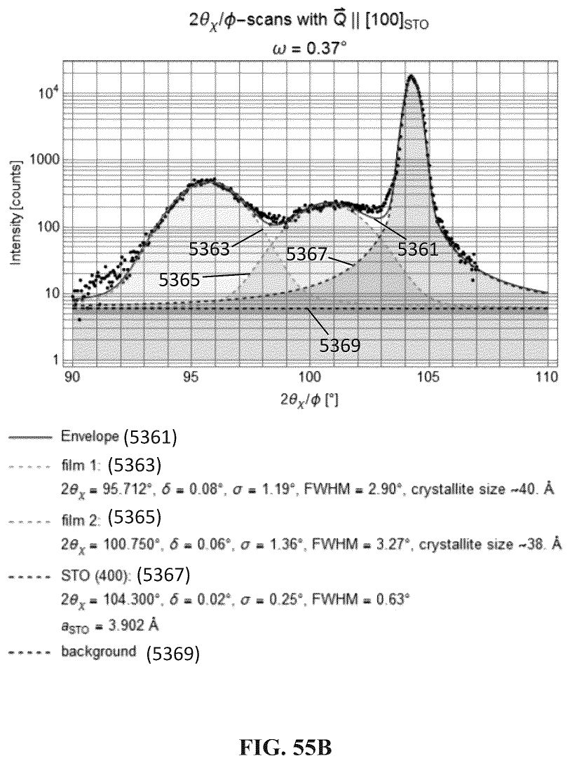

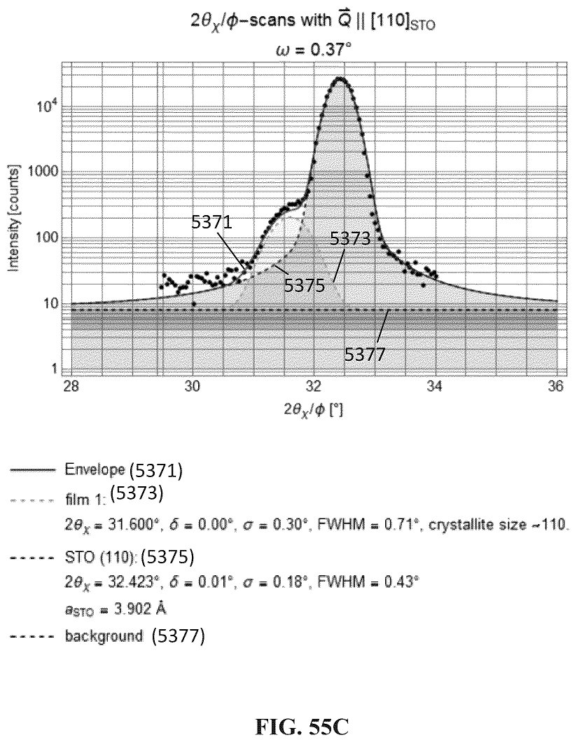

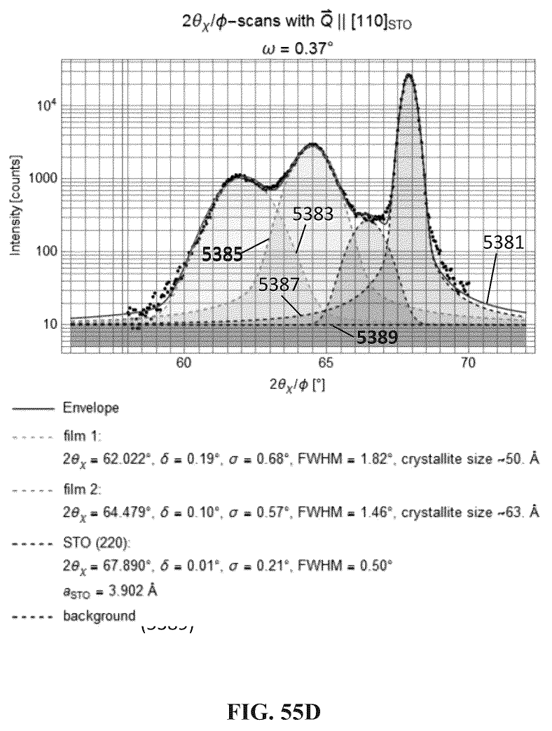

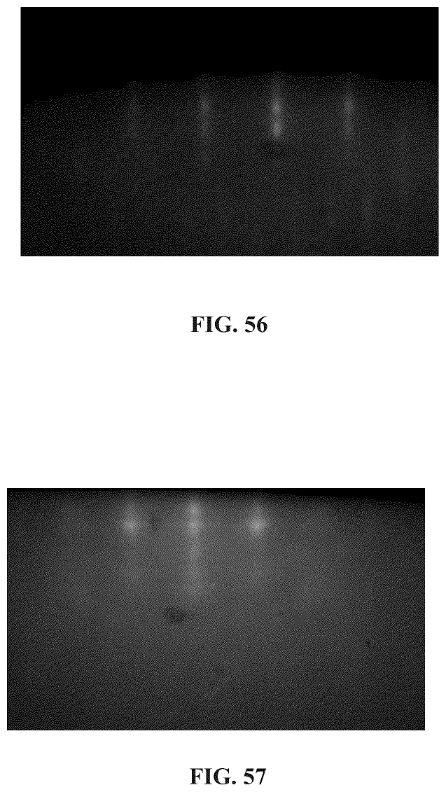

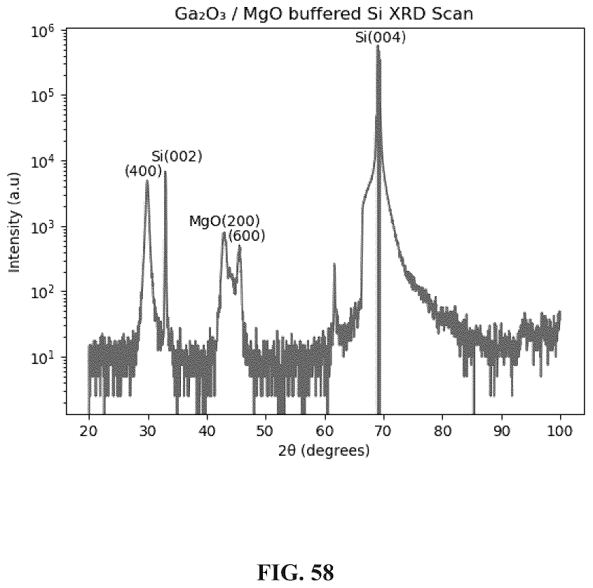

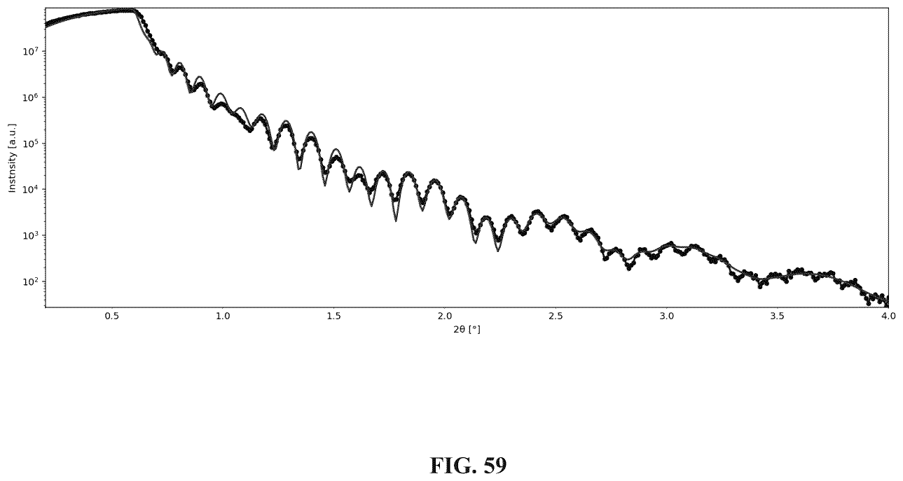

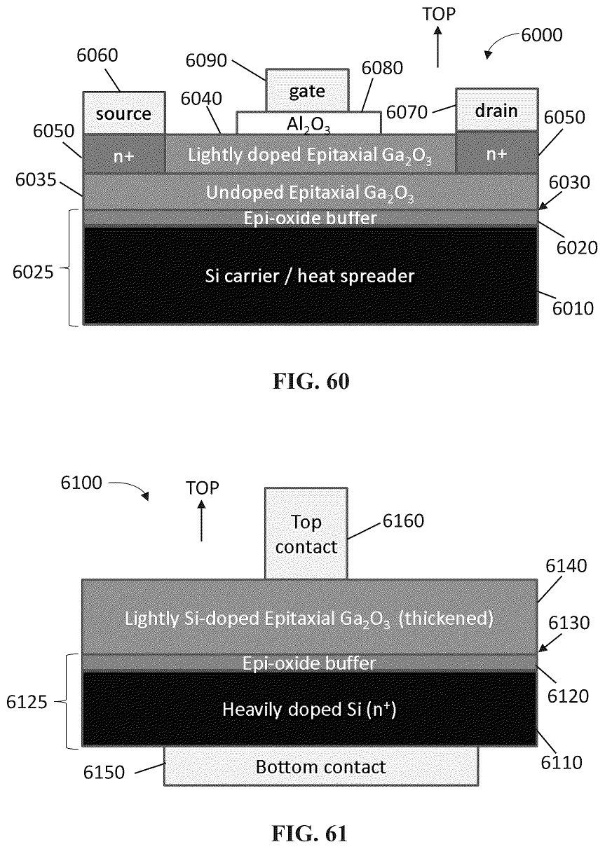

FIG. 15 depicts the θ/2θ out-of-plane diffraction pattern of the 5 nm film of alumina on Si. Due to the small film thickness we have used widely open slits with a 2 mm divergence slit and 1 mm receiving and scattering slits, hence a broad base to the Si (004) peak. The Si (004) was not scanned fully to avoid detector saturation. We see two film peaks that we attribute to γ-Al₂O₃ (222) and γ-Al₂O₃ (444). Due to the low signal to noise ratio we refrained from peak fitting and determination of the lattice constant. Combined with the quantitative result from the in-plane XRD and the twelve-fold symmetry in RHEED, this qualitative result confirms the thin film's structure to be the γ-Al₂O₃ polymorph in (111)-orientation with two in-plane variants, consistent with the literature reports for similarly grown alumina films on Si (001) [86,88,90,91].

The diffraction patterns discussed above with reference to FIGS. 12 and 13 are consistent with previous findings [86], and suggest the coexistence of two γ-Al₂O₃ (111)∥Si in-plane variants, offset by 30° from each other, with [symbol] 112̅ [symbol] γ-Al₂O₃[100]∥Si and [symbol] 110 [symbol] γ-Al₂O₃∥[100] Si. This geometry results in a surface consisting of equilateral triangles of oxygen ions, as displayed in FIG. 14.

The γ-Al₂O₃ lattice constant was calculated as @Al₂O₃=7.89 Å by measuring (44̅0) reflections with in-plane XRD shown in this supplemental material for Example 1 and assuming all three crystal axes are equally strained or relaxed, without non-cubic deformation. This value is within the range of reported γ-Al₂O₃ bulk lattice constants from 7.84 Å to 7.98 Å [87], and in excellent agreement with the reported value of (7.90±0.11) Å found for a similarly grown 6 nm γ-Al₂O₃ (111) thin film on Si (001) [86].

TABLE 2
XPS data of 5 nm Al₂O₃ film on Si including values obtained from peak fitting of the data
shown in FIGS. 12A-12D. The BE position of Si 2p indicates that no Si—O bonds are formed
at the interface. The raw area denotes the integrated peak area after Tougaard background
subtraction. The Scofield elemental subshell cross-sections are relative to C 1s.

| | | Literature BE | | Raw | | | |
|---|---|---|---|---|---|---|---|
| | Experimental | [88] γ- | FWHM | Area | Photoelectric | EAL λ | Transmission |
| Peak | BE | Al₂O₃/Si(111) | fit | A | cross-section | [83] | function |
| label | [eV] | [eV] | [eV] | [cps eV] | σ⁵ | [nm] | [arb. units] |
| Al 2p | 75.61 | 75.50 | 1.56 | 8253.5 | 0.5371 | 2.21 | 80.2 |
| Si 2p | 99.23 | 99.35 | 1.09 | 1901.6 | 0.817 | 2.19 | 81.6 |
| Al 2s | 120.42 | X | 2.31 | 11558.2 | 0.753 | 2.15 | 83.1 |
| Si 2s | 150.40 | X | 1.27 | 1465.2 | 0.955 | 2.12 | 85.4 |
| O 1s | 532.23 | X | 1.88 | 48922.8 | 2.20* | 1.62 | 100.5 |

*The O 1s cross-section had to be empirically corrected, after measuring a range of sesquioxide compounds (including Ga₂O₃, Al₂O₃, SrTiO₃), to a common value of 0.75 times the tabulated value of 2.93 [84], to obtain correct stoichiometries.

TABLE 3
Al₂O₃ film thickness d in nm estimated using equation (1)
and values from Table 2. The thickness values estimated using
Si 2p agree well with the result of 5.0 nm from XRR in FIG.
13. The thickness values using Si 2s are somewhat overestimated
compared to XRR, which could be due to an underestimation
of the integrated Si 2s peak area owing to its smaller signal
to noise ratio in the spectrum of FIG. 12C.

| d [nm] | A1 2p | A1 2s | O 1s |
|---|---|---|---|
| Si 2p | 5.1 | 5.1 | 5.1 |
| Si 2s | 5.8 | 5.8 | 5.8 |

TABLE 4
Stoichiometric ratios nₒ/n_{Al} of
oxygen to aluminum in the alumina thin film determined using
equation (2) and values from Table 2 and a alumina thickness
d = 5.0 nm (from XRR - see Supplemental FIG. 13). The
film stoichiometry, within the error of XPS, has the ideal
sesquioxide value of stoichiometric Al₂O₃
with nₒ/n_{Al} = 1.50.

| nₒ/n_{Al} | O 1s |
|---|---|
| A1 2p | 1.48 |
| A1 2s | 1.51 |

FIGS. 16A and 16B are top-views of the oxygen-terminated surface of γ-Al₂O₃ (111). Note the bulk structure of γ-Al₂O₃ has 3 symmetry, but the terminating O layer taken by itself and unreconstructed is 6-fold symmetric with the O ions being arranged in a hexagonal surface net. Two rotational variants are observed by RHEED and XRD giving rise to an apparent 12-fold pseudo-symmetry of the RHEED pattern in FIG. 3B. The triangular faces of the oxygen polyhedra surrounding the partially occupied Al cation sites are contained in the (111) surface plane. FIG. 16C is a side-view of the oxygen-terminated surface of γ-Al₂O₃ (111).

Ga₂O₃ Growth and Characterization

FIG. 17A depicts a plot of gallia rate as measured by quartz crystal microbalance (QCM) at 2×10−5 torr molecular oxygen pressure and 200 W rf-plasma power and a Ga cell temperature of 880° C., assuming a mass density of 5.95 g cm⁻³. The Ga cell charge was held at 900° C. for 40 min prior to each growth run before igniting the oxygen plasma to outgas the charge. The rate at 880° C. is stable over time apart from fluctuations about the mean of 3.15 Å/min and was also very similar between different growth runs. It can be assumed that the Ga arriving to the QCM sensor held at room temperature in the presence of O-plasma forms an oxide of Ga₂O₃ stoichiometry and represents the maximum growth rate achievable with the given Ga cell temperature and O plasma settings [92]. When assuming all the Ga arriving at the QCM sticks under O-plasma conditions the measured Ga flux is ˜0.2 nm⁻²s⁻¹. It should be mentioned that the inferred Ga flux from the QCM rate when measured without the presence of O-plasma was usually about a factor of ˜0.5 lower than the Ga flux inferred form the Ga₂O₃ rate for Ga deposition in presence of O-plasma (both Ga metal and Ga₂O₃ have nearly identical mass density, the only parameter needed for the thickness measurements of thin films by the QCM was therefore unchanged). This is likely because elemental Ga has a large surface tension and hence is not sticking well without the presence of atomic oxygen flux.

FIG. 17B depicts a plot of the gallia deposition rate measured by the QCM increases with increasing Ga effusion cell temperature for fixed oxygen plasma settings of 200 W rf-plasma power and 2.0 10⁻⁵ torr O₂ pressure. The increase in deposition rate can be modeled by an ˜exp [−E₀/k_{B}T] law (see fit in the graph). The “activation” energy E, was fit to ˜1.7 eV. The increase of gallia growth rate with increase in Ga effusion cell temperature under unchanged oxygen plasma conditions constitutes an oxygen rich growth regime. This observation is consistent with the Ga to O ratio inferred from the growth model by Vogt and Bierwagen as discussed below (under FIG. 22).

FIGS. 18A-18E depict XPS data taken in situ after 1st PAMBE growth of gallia at 670° C. on γ-Al₂O₃(111) (5 nm)/Si (001) with a VG Scienta spectrometer with monochromatic Al-Kα and R3000 hemispherical analyzer at 200 eV pass energy. FIG. 18A is the survey spectrum; no core-levels of Al or Si are observed, the film is therefore thicker than the information depth of the film layer (>5 EAL), no impurity elements or surface contamination within the accuracy of XPS. FIG. 18B is Ga 2p_{3/2} deep core-level. FIG. 18C is the O 1s core-level. FIG. 18D is the Ga 3p core-level. FIG. 16E is the valence band region with semi-core O 2s and Ga 3d states. For the quantification of oxygen to gallium ratio in the gallia film we used the O 1s, Ga 3p and Ga 2p_{3/2} core-levels. The oxygen and gallium percentages using O 1s and Ga 3p are 60% and 40%. The oxygen and gallium percentages using O 1s and Ga 2p_{3/2} are 58% and 42%. Hence within the accuracy of XPS the film is stoichiometric Ga₂O₃. We also recorded the semi-core and valence band region. We did not use the semi-core states Ga 3d and O 2s for quantification since they are already subject to non-negligible hybridization.

FIG. 19 depicts XRR data (dots in upper panel plot, in blue) and GenX simulation (curves, in red, in upper and lower panels) of Ga₂O₃/Al₂O₃/Si according to the present technology. The simulation parameters are 20.9 nm Ga₂O₃ thickness, surface roughness o value of 14.4 Å and a molecular density of 0.019 Ga₂O₃ formula units per Å³, identical to the bulk value of 0.019 Ga₂O₃ formula units per Å³ of β-Ga₂O₃ and γ-Ga₂O₃. The tabulated density values of α-Ga₂O₃ are denser with 0.021 Ga₂O₃ formula units per Å³, but they have been recorded under elevated pressures and are likely different in thin film form. The fit was somewhat improved if the alumina layer was reduced in thickness compared to the 5.0 nm used as thickness parameter in the simulation of the curve shown in FIG. 13, this could indicate intermixing of Al and Ga near the Ga₂O₃/Al₂O₃ interface. We also needed to increase the Si substrate roughness which could indicate oxidation of Si near the Al₂O₃/Si interface by oxygen diffusion through the thin alumina layer when taken into air for a prolonged time, cleaning with ozone or annealing in oxygen plasma.

FIGS. 20A-20E depict XPS data taken in situ after 2nd PAMBE growth of additional gallia at 630° C. on Ga₂O₃ (21 nm)/γ-Al₂O₃ (111) (5 nm)/Si (001) with a VG Scienta spectrometer with monochromatic Al-Kα and R3000 hemispherical analyzer at 200 eV pass energy. FIG. 20A is a survey spectrum showing no impurity elements or surface contamination within the accuracy of XPS. FIG. 20B is Ga 2p_{3/2} deep core-level. FIG. 20C is O 1s core-level. FIG. 20D is Ga 3p core-level. FIG. 20E is valence band region with semi-core O 2s and Ga 3d states. For the quantification of oxygen to gallium ratio in the gallia film we used the O 1s, Ga 3p and Ga 2p_{3/2} core-levels. The oxygen and gallium percentages using O 1s and Ga 3p are 59% and 41%. The oxygen and gallium percentages using O 1s and Ga 2p_{3/2} are 57% and 43%. Hence within the accuracy of XPS the film is stoichiometric Ga₂O₃ (possibly slightly oxygen deficient). We also recorded the semi-core and valence band region. We did not use the semi-core states Ga 3d and O 2s for quantification since they are already subject to non-negligible hybridization.

FIG. 21 depicts a plot of the Kiessig fringe spacing, which indicates a total Ga₂O₃ thickness of 66 nm.

FIG. 22 depicts a plot of the sticking probability as a function of sample temperature in the PAMBE-growth of Ga₂O₃ after the model by Vogt and Bierwagen [92]. Within the macroscopic kinetic growth model for the PAMBE growth of Ga₂O₃ (in a first approximation independent of the substrate and crystal structure) [92], a volatile suboxide Ga₂O evaporates from heated surfaces and limits the sticking probability below 100% and hence reduces the growth rate below the maximum possible growth rate at lower growth temperature (or higher O flux). The Ga₂O₃ growth rate Γ is described by a dependence on the activated O-flux φ_{O}. the Ga flux φ_{Ga} and the sample temperature T. We define the sticking probability as Γ/Γₘₐₓ, where Imax is the maximum growth rate achievable at low growth temperature. Our results for the different sticking coefficients obtained at 630° C. and 670° C. agree qualitatively with this model, however, the 1^{st} sticking probability is also related to nucleation on the substrate and therefore the model [92] may not be applicable yet. If we quantitatively apply the model to the 2nd sticking probability of 59%, a Ga flux of 0.2 nm⁻²s⁻¹, and the substrate temperature of 630° C. we can then use the model to constrain the activated O flux impinging on the sample (the only uncertain growth parameter): Both curves are for a Ga flux of 0.2 nm⁻²s⁻¹ (measured by QCM); the red curve 2010 is for an O-flux of 10 nm⁻²s⁻¹ (RGA estimate), and the blue curve is for an O-flux of 1.85 nm⁻²s⁻¹, which was chosen such that the curve intersects 59% at a temperature of 630° C. The obtained activated O flux of ˜1.85 nm⁻²s⁻¹ is about an order of magnitude lower than the estimate from the RGA O partial pressure. With this choice for the blue curve 2020 it appears that, if the inferred O-flux is correct, the 1st sticking probability of 38% at 670° C. is higher than what the curve predicts. This could be related to an enhanced sticking probability in the initial nucleation of Ga₂O₃ on the Al₂O₃/Si substrate. The growth rate I was given as an algebraic solution to simplified rate equations in a dynamic equilibrium [92], as (beware of some typos in the original reference):

$$\begin{matrix}Γ ( {ϕ}_{Ga} , {ϕ}_{O} , Υ , A ) = {A}^{- 1} ( Υ - \frac{3}{4} {ϕ}_{Ga}^{2} + {ϕ}_{Ga} {ϕ}_{O} - \frac{1}{12} {( 2 {ϕ}_{O} - A )}^{2} ) , \\ A ( {ϕ}_{Ga} , {ϕ}_{O} , Υ ) = {( 72 {Υϕ}_{O} - {( 3 {ϕ}_{Ga} - 2 {ϕ}_{O} )}^{3} + \sqrt{108} {( Υ ( 16 {Υ}^{2} - 4 Υ ( 9 {ϕ}_{Ga}^{2} - 12 {ϕ}_{Ga} {ϕ}_{O} - 8 {ϕ}_{O}^{2} ) + ( {ϕ}_{Ga} - 2 {ϕ}_{O} ) {( 3 {ϕ}_{Ga} - 2 {ϕ}_{O} )}^{3} ) )}^{1 / 2} )}^{1 / 3} , \\ Υ ( {ϕ}_{Ga} , {ϕ}_{O} , T ) = {Υ}_{0} exp [ \frac{- ( {E}_{0} - ζ \frac{{ϕ}_{Ga}}{{ϕ}_{O}} )}{{k}_{B} T} ] ,\end{matrix}$$

with model and fitting constants Y₀=exp [37.1], E₀=2.93 eV, ζ=0.90 eV.

FIGS. 23A-23F depict plots of Pseudo-Voigt function fits of x-ray diffraction θ/2θ reflections from the 66 nm β-Ga₂O₃ thin film. Based on the absolute peak positions and lattice parameters and relative areas under the curves the most likely assignments of the diffraction peaks are the β-Ga₂O₃ {310} (green), (101) (blue) and (2̅01) (blue) families of reflections. The Si (004) peak (red) is at 2θ=69.14°, slightly off from the bulk value of 69.12° (see Table I), which indicates a small instrumental offset of 0.02°. In the symmetric θ/2θ geometry with the use of an incident beam monochromator, the integrated reflection intensity per unit scattering volume at scattering angle 2θ for a crystal slab of thickness t, based on the kinematic approximation, is proportional to [93]:

$${I}_{hkl} ( θ ) ∝ \frac{1 + A {cos}^{2} 2 θ}{1 + A} \frac{1}{sin 2 θ} {\vert {F}_{hkl} \vert}^{2} ( 1 - exp [ \frac{- 2 μ t}{sin θ} ] ) , \qquad ( 3 )$$

where the first factor is the polarization factor for the incident x-rays and A=cos² 2 θ_{M}, with θ_{M}=22.6° being the Bragg angle of the Ge (220) channel cut monochromator, polarization correction due to the multilayer mirror can be neglected due to the small x-ray incidence angle onto the multilayer mirror [94], the second factor is often called Lorentz factor and stems from the change of variables from reciprocal or wavenumber coordinates to angular coordinates in the integration of the lattice interference function [95], |Fₕₖₗ|² is the modulus square of the structure factor for the given reflection, the last factor accounts for a change in sampling volume and x-ray pathlength with change in incident and exit angles, where u is the linear absorption coefficient for x-rays of Cu-Kα energy in the crystal slab. Evaluating the intensities of the harmonics of the {310}, (101) and (2̅01) reflections with regards to equation (3) we obtain scattering volume fractions for the three phases of 71%, 13% and 16%. The structure factors were calculated with the software Vesta [96], based on an imported structure file obtained from entry #1638495 of reference [87]. The linear attenuation coefficient is based on interpolated mass absorption coefficients tabulated in and assuming a mass density of 5.95 g cm⁻³ for Ga₂O₃.

TABLE 5
List of experimental θ/2θ Bragg peak positions and intensities of Ga₂O₃/γ-Al₂O₃
(111)/Si(001) and literature bulk Bragg peak positions* and their expected intensities after
equation (S.3) (unit volume) for plausible Ga₂O₃ polymorph orientations based on structure
symmetry and previous reports. Experimental peak intensities are normalized to the strongest
film peak (Peak 1). Bulk peak intensities are normalized to the strongest peak contained in the
table for a particular polymorph, i.e. the relative intensities for the bulk structures are only
meaningful within the same polymorph. By means of the normalization Q/Q₀ (with Q₀ = d(Peak
1)⁻¹) we can identify harmonic peaks in the experimental data set: Hence, peaks 1, 3, 4, and 7 are
most likely harmonics of the same plane family, and likewise Peaks 2 and 5 are likely harmonics
of the same plane family. By using this Q/Q₀ ratio we can see that: The α-polymorph in (00.1)-
orientation at first sight can be excluded based on lattice constants, but caution has to be taken
since the bulk data is for the high-pressure phase and is likely different in thin film form.

| Label | Peak 1 | Peak 2 | Peak 3 | Peak 4 | Peak 5 | Peak 6 | Peak 7 |
|---|---|---|---|---|---|---|---|
| 2θₑₓₚ [°] | 18.80 | 37.23 | 38.17 | 58.84 | 79.46 | x | 110.10 |
| Qₑₓₚ/Q₀ | 1.00 | 1.95 | 2.00 | 3.01 | 3.91 | x | 5.02 |
| dₑₓₚ [Å] | 4.72 | 2.41 | 2.36 | 1.57 | 1.21 | x | 0.94 |
| I | 1.00 | 0.17 | 0.50 | 0.82 | 0.20 | x | 0.35 |
| (h k 1) | x | x | (0 0 . 6 )_{α} | x | x | (0 0 . 12)_{α} | x |
| 2θ_{bulk} [°] | x | x | 40.24 | x | x | 86.96 | x |
| Q_{bulk}/Q₀ | x | x | 2.11 | x | x | 4.21 | x |
| d_{bulk} [Å] | x | x | 2.24 | x | x | 1.12 | x |
| I | x | x | 1.00 | x | x | 0.09 | x |
| (h k 1) | (1 1 1)_{γ} | x | (2 2 2)_{γ} | (3 3 3)_{γ} | x | (4 4 4)_{γ} | (5 5 5)_{γ} |
| 2θ_{bulk} [°] | 18.64 | x | 37.80 | 58.14 | x | 80.76 | 108.20 |
| Q_{bulk}/Q₀ | 0.99 | x | 1.98 | 2.97 | x | 3.97 | 4.96 |
| d_{bulk} [Å] | 4.76 | x | 2.38 | 1.59 | x | 1.19 | 0.95 |
| I | 0.94 | x | 1.00 | 0.90 | x | 0.31 | 0.27 |
| (h k 1) | (0 0 2)_{κ} | x | (0 0 4)_{κ} | (0 0 6)_{κ} | x | (0 0 8)_{κ} | (0 0 10)_{κ} |
| 2θ_{bulk} [°] | 19.12 | x | 38.80 | 59.76 | x | 83.26 | 112.30 |
| Q_{bulk}/Q₀ | 1.02 | x | 2.03 | 3.05 | x | 4.07 | 5.08 |
| d_{bulk} [Å] | 4.76 | x | 2.32 | 1.55 | x | 1.16 | 0.93 |
| I | 1.00 | x | 0.95 | 0.25 | x | 0.23 | 0.04 |
| (h k 1) | (2̅ 0 1)_{β} | x | (4̅ 0 2)_{β} | (6̅ 0 3)_{β} | x | (8̅ 0 4)_{β} | (1̅0̅ 0 5)_{β} |
| 2θ_{bulk} [°] | 18.94 | x | 38.42 | 59.14 | x | 82.30 | 110.70 |
| Q_{bulk}/Q₀ | 1.01 | x | 2.01 | 3.02 | x | 4.03 | 5.04 |
| d_{bulk} [Å] | 4.68 | x | 2.34 | 1.56 | x | 1.17 | 0.94 |
| I | 1.00 | x | 0.32 | 0.79 | x | 0.03 | 0.29 |
| (h k 1) | x | x | (2 0 2)_{β} | x | x | (4 0 4)_{β} | x |
| 2θ_{bulk} [°] | x | x | 38.42 | x | x | 82.32 | x |
| Q_{bulk}/Q₀ | x | x | 2.01 | x | x | 4.07 | x |
| d_{bulk} [Å] | x | x | 2.34 | x | x | 1.17 | x |
| I | x | x | 0.23 | x | x | 0.01 | x |
| (h k 1) | x | (3 1 0)_{β} | x | x | (6 2 0)_{β} | x | x |
| 2θ_{bulk} [°] | x | 37.30 | x | x | 79.50 | x | x |
| Q_{bulk}/Q₀ | x | 1.96 | x | x | 3.92 | x | x |
| d_{bulk} [Å] | x | 2.41 | x | x | 1.20 | x | x |
| I | x | 0.04 | x | x | 0.04 | x | x |

However, based on intensities this polymorph and orientation can likely be excluded. The γ-, κ-, and β-polymorphs in the given orientations are all likely candidates based on their Q/Q₀ values. However, we also see that within the considered possibilities, the harmonic Peaks 2 and 5 are only explained well by β-Ga₂O₃ in (310)-orientation. Based on intensities, a mixture of β-Ga₂O₃ epitaxial orientation variants seems to explain the data best. The absence of Peak 6 in the experimental data seems plausible for B Ga₂O₃ due to the low intensity of the (804)/(404) peaks; this is not so for γ- and κ-polymorphs. Therefore, we deem it highly likely that all peaks originate from β-Ga₂O₃. This is corroborated by the elevated growth temperatures and the pole figure scan shown in the main text of the article. By means of the pole figure scan we can exclude significant volume fractions of the α-, γ- and κ-polymorphs and confirm β-Ga₂O₃ with 48 epitaxial orientation variants as described in the main article.

We would like to mention here that the presence of the (101) phase can be easily overlooked in a θ/2θ scan since its peaks overlap with the peaks of the (2̅01) phase. Only a careful analysis of the relative peak intensity ratios and relative peak positions of the harmonic reflections belonging to the same plane family can reveal the corresponding phase's volume fraction. For instance, in the recent work the observation of the disappearing of (2̅01) and (603) peaks, and reduction of the (402) peak in β-Ga₂O₃ films grown at elevated growth temperature by PAMBE on sapphire substrate have been interpreted as a reduction in crystal quality of the epilayer. However, in consideration of the overlap of (402) and (202) peaks the data could also be interpreted as a suppression of the (2̅01) phase and instead emergence of (101) as dominant phase, since the (202) is the only harmonic of (101) with substantial diffraction intensity-see FIG. 21B and Table 5. If the {310} phase was also present the (310) peak, owing to its small structure factor, should show up as a weak shoulder to the left of the (402) and (202) peaks. Since the (620) peak is even weaker the {310} phase can also easily be missed for a thin film in a low resolution θ/2θ scan.

TABLE 6
Expected pole figure coordinates of the relevant β-Ga₂O₃ reflections, based on the orientational
model presented in the main text for each of the twelve in-plane variants arising from the four
out-of-plane orientations (101), (2̅01), {310} and {3̅1̅0}, and based on bulk lattice constants of
β-Ga₂O₃. In each row the upper angle is the polar angle θ in degree (measured from the north
pole downwards) and the lower angle in the azimuthal angle ϕ in degree. A polar angle of 0°
corresponds to the Si [001] out-of-plane direction and an azimuthal angle of 0° corresponds to
the Si [110] in-plane direction.

| | 0 | 1 | 2 | 3 | 4 | 5 | 6 | 7 | 8 | 9 | 10 | 11 |
|---|---|---|---|---|---|---|---|---|---|---|---|---|
| (401̅)₍₁₀₁₎ | | | | | | | | | | | | |
| (401̅)₍₁₀₁₎ | — | — | | | | | | | — | — | — | — |
| (2̅02)₍₁₀₁₎ | | | | | | | | | | | | |
| (2̅02)₍₁₀₁₎ | | | — | — | — | — | — | — | | | | |
| (002)₍₁₀₁₎ | | | | | | | | | | | | |
| (002)₍₁₀₁₎ | | | — | — | — | — | — | — | | | | |
| (4̅01)₍₂̅01) | | | | | | | | | | | | |
| (4̅01)₍₂̅01) | | | — | — | — | — | — | — | | | | |
| (2̅02)₍₂̅01) | | | | | | | | | | | | |
| (2̅02)₍₂̅01) | — | — | | | | | | | — | — | — | — |
| (002)₍₂̅01) | | | | | | | | | | | | |
| (002)₍₂̅01) | — | — | | | | | | | — | — | — | — |
| (401̅)₍₃₁₀₎ | | | | | | | | | | | | |
| (401̅)₍₃₁₀₎ | | — | — | — | — | — | −8.6 | | | | | |
| (202̅)₍₃₁₀₎ | | | | | | | | | | | | |
| (202̅)₍₃₁₀₎ | — | — | — | — | — | 4.0 | | | | | | |
| (002)₍₃₁₀₎ | | | | | | | | | | | | |
| (002)₍₃₁₀₎ | | | | | | — | — | — | — | — | −4.0 | |
| (4̅01)₍₃̅₁̅0) | | | | | | | | | | | | |
| (4̅01)₍₃̅₁̅0) | | | | — | — | — | — | — | — | 8.6 | | |
| (2̅02)₍₃̅₁̅0) | | | | | | | | | | | | |
| (2̅02)₍₃̅₁̅0) | | | | | | | — | — | — | — | −4.0 | |
| (002̅)₍₃̅₁̅0) | | | | | | | | | | | | |
| (002̅)₍₃̅₁̅0) | — | — | — | — | — | 4.0 | | | | | | — |

### Supplementary Density Functional Theory Calculations

Density functional theory (DFT), as implemented in the Vienna ab initio Simulation Package (VASP) code, is used to perform all calculations [99]. The Perdew-Burke-Ernzerhof (PBE) generalized-gradient approximation (GGA) is used for the exchange correlation energy functional. We use projector-augmented-wave potentials [100], to describe Ga and O with a cut-off energy of 500 eV for bulk optimizations. The valence electron configurations used are 4s²3d¹⁰4p¹ for Ga and 2s²2p⁴ for O. Each self-consistent electronic calculation is converged to within 10⁻⁶ eV per cell, and the ionic relaxation is iterated until the forces are less than 0.01 eV/Å. For the Brillouin zone integration of bulk Ga₂O₃ (space group C2/m, 12), a 5×9×11 Monkhorst-Pack grid is used. For bulk Ga (space group Abma, 64), a 12×12×12 Monkhorst-Pack k-point mesh is used.

The lattice parameters calculated for bulk Ga₂O₃ are a=12.445, b=3.084 Å, c=5.876 Å, and β=103.73°, which compare favorably with the experimental values of a=12.22 Å, b=3.04 Å, c=5.80 Å and β=103.75° [101], and theoretical values of a=12.446, b=3.083 Å, c=5.876 Å, and β=103.70° [102].

To create the slabs, we used surface-oriented basis transformations on the conventional unit cell using methods described in reference [103]. The transformation matrices used are shown in Table 7, below. Each unit cell is repeated along the c-axis to create a 15-20 Å thick supercell and a 15 Å vacuum is added to create the slab. For slab optimizations, a 600 eV energy cutoff is used, and the convergence criteria are the same as those used for the bulk optimizations. For Brillouin zone integration of the (2̅01), (310), and (101) slabs, 7×7×1, 5×7×1, and 5×25×1 Monkhorst-Pack k-point meshes are used, respectively.

We calculate the surface energies using the following equation,

$${Υ}_{surface} = \frac{1}{2 A} [ {E}_{slab} - {N}_{Ga} ( {E}_{Ga} + {μ}_{Ga} ) - \frac{1}{2} {N}_{O} ( {E}_{{O}_{2}} + {μ}_{{O}_{2}} ) ]$$

In this equation, Y_{surface} is the surface energy, A is the surface area with a factor of 2 accounting for both surfaces, E_{slab} is the energy of the Ga₂O₃ slab, N_{X} is the number of X atoms in the Ga₂O₃ slab, E_{X} is the energy of one unit cell of bulk X, and μ_{X} is the chemical potential of bulk or molecular X.

To simplify the number of variables in this equation, we use the relationship:

$${E}_{{Ga}_{2} {O}_{3}} + {μ}_{{Ga}_{2} {O}_{3}} = 2 ( {E}_{G a} + {μ}_{Ga} ) + \frac{3}{2} ( {E}_{{O}_{2}} + {μ}_{{O}_{2}} )$$

We assume that the surface is in equilibrium with its own bulk, hence μ_{Ga}_{₂}_{O}_{₃} is equal to 0 eV. The formation energy of Ga₂O₃ is defined as

$${E}_{f} = {E}_{{Ga}_{2} {O}_{3}} - 2 {E}_{Ga} - \frac{3}{2} {E}_{{O}_{2}} .$$

Using this definition and rearranging the equation above, we get the relationship

$${μ}_{Ga} = \frac{1}{2} ( {E}_{f} - \frac{3}{2} {μ}_{{O}_{2}} ) .$$

We can then allow the chemical potential to vary over the range

$$0 \leq {μ}_{{O}_{2}} \leq \frac{2}{3} {E}_{f} ,$$

where u_{O}_{₂}, =0 ev represents oxygen-rich conditions and

$${μ}_{{O}_{2}} = \frac{2}{3} {E}_{f}$$

represents Ga-rich conditions. We determined that the formation energy of Ga₂O₃ is −9.31 eV, which is less stable than the experimental value of −11.3 eV [104], but comparable to the formation energy value of −9.3 eV calculated by Zacherle et. al [102].

FIGS. 24A-24C illustrate ideally terminated surfaces with lattice planes marking the terminations studied. To the left of each slab, the top and bottom axes correspond to the axes for the β-Ga₂O₃ conventional unit cell and the axes for the slab, respectively. Ga and oxygen atoms are labeled 2201 and 2203, respectively. In FIG. 24A, the dark blue 2205 (pink 2210) plane marks the Ga-terminated (O-terminated) surface along the (310) surface termination. For the (2̅01) plane, we studied two distinct O-terminations and two distinct Ga-terminations denoted by the labels (A) and (B) in FIG. 22B. (b) The dark blue (2220), pink (2230), light blue (2240), red (2250), and green (2260) planes mark the O-terminated (A), Ga-terminated (A), O-terminated (B), Ga-terminated (B), and mixed-terminated surfaces along the (2̅01) surface termination, respectively. In FIG. 24C, the dark blue 2270 (pink 2280) plane marks the O-terminated (mixed-terminated) surface along the (101) surface termination.

FIGS. 25A-25C illustrate lowest energy terminations before and after relaxation superimposed for the (310) O-termination (FIG. 25A), (2̅01) mixed-termination (FIG. 25B), and (101) O-termination (FIG. 25C). In FIGS. 25A-25C, 2310 (gray) denotes Ga atoms before relaxation, 2320 (green) denotes Ga atoms after relaxation, 2330 (white) denotes oxygen atoms before relaxation, and 2340 (red) denotes oxygen atoms after relaxation. To the left of each slab, the top and bottom axes correspond to the axes for the β-Ga₂O₃ conventional unit cell and the axes for the slab, respectively.

To determine the lowest energy surface reconstruction of the (310) plane, we studied one Ga-terminated and one O-terminated surface (FIG. 24A). The average surface energy of the O-terminated surface (FIG. 25A) is 4.267 J m⁻², which is higher than the surface energy value of 3.671 J m⁻² of the Ga-terminated surface. For the (2̅01) plane, we studied five surface terminations shown in FIG. 24B. The lowest value for the surface energy is 0.768 J m⁻² and this was achieved with the mixed termination (FIG. 25B). Although a different calculation method was used, the surface energy and relaxation energy we determined is comparable to the values reported by Schewski et. al [105]. For the (101) plane, we studied a mixed-terminated surface and an O-terminated surface (FIG. 24C). The surface energy of the O-terminated surface (FIG. 25B) is 1.510 J m⁻², which is slightly lower than the surface energy of 1.573 J m⁻² for the mixed-terminated surface. The values we calculated are comparable to the surface energy value of 1.5-2 J m⁻² reported by Schewski et. al [105].

TABLE 7
Transformation matrices used to create surface-oriented unit cells
along the (2̅01), (310), and (101) planes.

| Surface termination | Transformation matrix |
|---|---|
| (2̅01) | $( \begin{matrix}0.5 & 0.5 & 1 \\ - 0.5 & 0.5 & - 1 \\ 0 & 0 & 1\end{matrix} )$ |
| (310) | $( \begin{matrix}- 0.5 & 1.5 & 0 \\ 0 & 0 & 1 \\ 0 & 1 & 0\end{matrix} )$ |
| (101) | $( \begin{matrix}1 & 0 & - 1 \\ 0 & 1 & 0 \\ 1 & 0 & 4\end{matrix} )$ |

TABLE 8
Computed surface energies (J m⁻²) for the ideally terminated and reconstructed surfaces.

| | | | | Average | | Average | |
|---|---|---|---|---|---|---|---|
| | | | Surface | surface | Surface | surface | |
| | | | energy | energy | energy | energy | |
| | | | before | before | after | after | Relaxation |
| Surface | Termination | Environment | relaxation | relaxation | relaxation | relaxation | energy |
| (2̅01) | Ga (A) | Ga-rich | 1.320 | 2.937 | 1.204 | 2.821 | 0.116 |
| | | O-rich | 4.554 | | 4.438 | | |
| (2̅01) | O (A) | Ga-rich | 7.347 | 5.730 | 5.212 | 3.595 | 2.135 |
| | | O-rich | 4.113 | | 1.978 | | |
| (2̅01) | Ga (B) | Ga-rich | 1.276 | 2.893 | 1.211 | 2.828 | 0.065 |
| | | O-rich | 4.510 | | 4.445 | | |
| (2̅01) | O (B) | Ga-rich | 7.268 | 5.651 | 7.014 | 5.397 | 0.254 |
| | | O-rich | 4.034 | | 3.780 | | |
| (2̅01) | Mixed | Ga-or | 2.100 | — | 0.768 | — | 1.332 |
| | | O-rich | | | | | |
| (310) | Ga | Ga-rich | 1.796 | 3.995 | 1.472 | 3.671 | 0.324 |
| | | O-rich | 6.194 | | 5.870 | | |
| (310) | O | Ga-rich | 9.618 | 7.418 | 6.466 | 4.267 | 3.151 |
| | | O-rich | 5.219 | | 2.068 | | |
| (101) | Mixed | Ga-or | 2.724 | — | 1.573 | — | 1.150 |
| | | O-rich | | | | | |
| (101) | O | Ga-or | 3.431 | — | 1.510 | — | 1.920 |
| | | O-rich | | | | | |

### Example 2: Gallia on STO-Buffered Silicon

For epitaxial integration, a buffer layer is essential since the interface between Ga₂O₃ and Si is not thermodynamically stable [126]. Integration via an oxide buffer layer is therefore an important step that provides a high-quality, well-defined template layer for subsequent growth by a faster method such as CVD, metal-organic CVD (MOCVD), or the recently reported suboxide MBE [127-129]. SrTiO₃ (001) can be routinely epitaxially integrated onto Si (001) [130], and hence it could act as a buffer layer for growth of Ga₂O₃ on Si, which would then lead to the availability of large scale Ga₂O₃ epitaxial films. Electrical transport properties of β-Ga₂O₃ films grown on STO (100) were recently reported by Wang et al. and we expect films grown on STO-buffered Si to behave similarly [131].

Here we report the deposition of β-Ga₂O₃ thin films grown on both STO (001) and STO-buffered Si (001) substrates using PAMBE and investigate their structural properties in detail. STO has the attraction of being one of the few oxide materials that can routinely be directly integrated with Si (001) [130]. Since it can be n-type doped with Nb [132], STO can also function in the dual role of epitaxial template layer for Ga₂O₃ and as conductive bottom electrode. The β-Ga₂O₃ thin films have been characterized by RHEED, XPS, XRD, XRR, reflection electron-energy-loss spectroscopy (REELS), and TEM.

### Experimental Conditions

In an embodiment of the present technology, single-side-polished STO (001) substrates with dimensions of 10×10×0.5 mm³ were cleaned ex situ in acetone, 2-propanol, and de-ionized water, each for 10 min in an ultrasonic bath. The samples were loaded into the MBE growth chamber (base pressure 5×10⁻¹⁰ torr) on Mo sample holders held in place by a Mo spring clip exerting pressure onto the backside of the sample, and a ˜0.5 mm protruding lip on the growth side of the sample. The sample was heated radiatively from the backside via a SiC heating coil placed above the sample with a set point of 775° C. (corresponding to a calibrated substrate temperature of ˜670° C. measured for a Si substrate with a pyrometer) in an oxygen plasma for 30 min. The oxygen plasma was generated by an Oxford Applied Research HD25 radio-frequency plasma generator at 200 W forward power and 2.0×10⁻⁵ torr nominal O₂ pressure measured by an ion gauge located at the top of the growth chamber. A residual gas analyzer (RGA) located on the sidewall of the chamber confirmed that O₂ was the predominant gas species, with an atomic oxygen amount of about 10% at the RGA position. Before introducing oxygen into the chamber, the dual filament Ga effusion cell was heated to 900° C. and outgassed for 20 minutes. The cell temperature was then lowered to 880° C. and the Ga rate was measured in the high-vacuum atmosphere of typically low 10⁻⁸ torr (caused by the hot effusion cell, and predominantly H₂ as measured by the RGA) by a QCM. Typical metal growth rates at this cell temperature were about 1 Å/min. After ignition of the oxygen plasma, the Ga rate was measured again, usually achieving a deposition rate that was a factor of ˜2.8 higher than for the bare Ga rate (using the same density setting for the QCM of 5.95 g/cm³ since Ga and Ga₂O₃ densities are nearly identical). This difference is most likely due to a lower sticking coefficient of bare Ga due to larger surface tension. The Ga₂O₃ growth was performed under the same Ga cell and O-plasma conditions at a manipulator set-point temperature of 775° C. This growth temperature was selected as it is the highest temperature that gives unity sticking coefficient for our oxygen flux, based on the model developed by Vogt and Bierwagen [133]. Higher substrate temperatures provide better epitaxy but should not be too high as to result in significant Ga suboxide desorption. The STO buffer layer on Si was grown on a 2-inch Si (001) wafer [132], and the Ga₂O₃ film was grown on this pseudo-substrate under nominally the same conditions as used for the bare STO substrates. The QCM-measured GaOₓ growth rate matched the observed rate of Ga₂O₃ on bare STO, as confirmed by ex situ XRR thickness measurements. The film surfaces grown on bare STO were monitored in situ during growth by RHEED with a 21-keV electron beam and in situ after growth in a secondary analysis chamber with a 15-keV electron beam for the STO-Si substrate. The thin film stoichiometry was measured in situ and post-growth by XPS with monochromatic Al-Kα and a VG Scienta R3000 hemispherical analyzer set at 200-eV pass energy and 0.8-mm slit size. The sample grown on STO-Si was also studied by REELS with 1.9-keV electrons and a Staib Auger probe. To determine the sample thickness, morphology, and crystal structure, XRD and XRR measurements were performed ex situ on a Rigaku Ultima IV diffractometer (Cu-Kα). TEM observations were made using an image-corrected Titan 80-300 operated at 300 kV.

### Results

FIGS. 26A and 26B show RHEED patterns for the Ga₂O₃ thin films as grown on bare STO along STO [symbol] 100 [symbol] and [symbol] 110 [symbol] azimuths for a 20-nm film, while FIGS. 26C and 26D show the same azimuths for a 50-nm film. For each of those figures, the Ga₂O₃ films were grown on STO at 775° C. Each of the RHEED patterns show four-fold symmetry upon azimuthal rotation of the sample. The horizontal spot spacings were used to infer the in-plane lattice spacings at the film surface after calibration to the known STO substrate spacings and are given as insets in each figure. The RHEED patterns have a spot-like nature indicating a slightly rough film surface or small lateral crystal grain size. It is apparent that the thicker film shows more modulation along the RHEED streaks, suggesting surface roughening with increasing film thickness. The RHEED patterns formed within minutes after deposition was initiated, and they confirmed that the sample surface remained crystalline throughout growth. Each pattern shows 4-fold symmetry, commensurate with the substrate symmetry on the high-symmetry azimuths. The horizontal streak spacing, indicating lattice spacings perpendicular to the electron beam direction, was determined by calibration to the substrate lattice constant of a=3.905 Å. The RHEED streaks of the 50-nm film show stronger modulation along their length than observed for the 20-nm film, indicating a rougher surface; this is corroborated by XRR and cross-sectional TEM (see discussion of FIGS. 32A-32D and 33, below).

XPS measurements conducted in situ after growth indicated stoichiometric Ga₂O₃ films, as shown in FIGS. 36A-36C and discussed below. To characterize the crystal structure of the thin films, XRD was performed ex situ, and the results are shown in FIGS. 27A-27C for the 50-nm Ga₂O₃ film grown by PAMBE at 775° C. on STO (001). FIG. 25A displays a 2θ-θ out-of-plane diffraction pattern with the diffraction vector Q aligned along STO [001]; FIGS. 25B and 25C show 2θ_{χ}-φ in-plane diffraction patterns taken at a grazing angle of incidence of 0.325°, with Q aligned along STO in FIG. 27B, and along STO in FIG. 25C. The diffraction patterns are indexed by the Miller indices of the observed substrate and film reflections. These reflections are assigned to the β-Ga₂O₃ polymorph with (100) and (1̅12) out-of-plane orientation for this basal-plane thin-film growth. The presence of (100) follows from the peak positions and the peak area ratios of the harmonics in FIG. 25A [134], whereas the presence of (1̅12) was corroborated from in-plane XRD measurements in FIGS. 25B and 25C due to overlapping peaks in FIG. 27A [134]. The observed diffraction peaks are consistent with each of the two growth planes having four rotational domain variants aligned with the STO substrate, as shown in a reciprocal space simulation in FIGS. 37A and 37B, discussed below.

The epitaxial relationships observed can be written as: β-Ga₂O₃ (100) ∥ SrTiO₃ (110), and β-Ga₂O₃ (1̅12) [02̅1]∥SrTiO₃ (100). The (1̅12) peak has a structure factor that is about one fifth of the (400) peak. Therefore, despite the smaller relative peak height in FIG. 27A, a significant fraction of the sampled crystalline volume is crystalized in the (1̅12)-orientation. A deconvolution by peak fitting of the (600) and (1̅12) peaks, and the (12 0 0) and (2̅24) peaks, is complicated by overlaps with the strong substrate signal and the broad width and small relative intensity of the film peaks. Considering the peak height ratio of the (12 0 0) and (2̅24) peaks (FIG. 25A) in comparison with the β-Ga₂O₃ powder pattern intensity ratio as a rough approximation for the volume fractions in the thin film scattering volume, the volume fraction of the (100)-orientation is estimated to be about 3 times greater than that of the (1̅12)-orientation. The prominent (400) peak in FIG. 25C is asymmetric which could indicate a strain gradient of the plane spacing along the growth direction. The fitted XRD peak positions and plane spacings along with and their deviation from the bulk values of β-Ga₂O₃ from FIGS. 27A-27C are given in the tables provided in FIGS. 38A-38C, discussed below.

The epitaxial texture of the films is confirmed by cross-sectional TEM images displayed in FIGS. 28A-28C. FIG. 28A is a low-magnification TEM image of a 20 nm Ga₂O₃ film grown at 775° C., as observed along the zone axis of STO. FIG. 28B is a high-magnification TEM image, where the film appears ordered with atomic planes running parallel and perpendicular to the substrate film interface. FIG. 28C is an FFT of the image in FIG. 28B; spots originating from the Ga₂O₃ thin film are consistent with the model obtained from XRD. The crystallinity in the film extends from the substrate up to the film surface, but strong granularity of the film is apparent, indicating a small crystal grain size of ˜5-10 nm, and leads to the observation of Moiré patterns in some regions due to overlap in the electron-beam direction. FIG. 28A shows a low magnification image and reveals an uneven film surface, while the high-magnification image in FIG. 28B shows atomic planes of the film running parallel and perpendicular to the substrate surface, closely aligned with the substrate planes. In FIG. 28C, the FFT spots can be indexed by reference to the STO substrate peaks and by the prominent β-Ga₂O₃ peaks, which are consistent with the XRD data.

Based on the observed epitaxial relationships, a structural model is presented in FIGS. 29A and 29B. Lattice matching is illustrated for β-Ga₂O₃ (1̅12) in FIG. 29A and (100) in FIG. 29B surface-oriented cells placed on top of STO (001). The conventional cells of β-Ga₂O₃ in (1̅12)-orientation or (100)-orientation are also shown in relation to the surface-oriented cells (details can be found in FIGS. 39A-39D, discussed below). The surface-oriented cells are shifted from the STO (001) surface by half a STO unit cell for clarity. The implied atomic bonding at the interface is not necessarily representative of the actual experimental bonding geometry and needs further investigation. However, the O and Sr—O sub-lattice matching can be seen to play an important role for the epitaxial relationships. The β-Ga₂O₃ (1̅12) surface-oriented cell was constructed such that the \vec{a}ₛ and \vec{b}_{S} lattice vectors are: 1) contained in the (1̅12) plane of the conventional cell; 2) enclose an angle of nearly) 90° (89.989°; and 3) have the shortest lengths compatible with this structural arrangement. Their lengths are as =23.75 Å and b_{S}=8.40 Å, leading to lattice mismatches of −1.2% and −2.4% with respect to the STO 6×2 surface cell shown in FIG. 29A. The surface-oriented cell of β-Ga₂O₃ (100) is obtained by relabeling the unit cell vectors such that the \vec{a}_{S} and \vec{b}_{S} lattice vectors are contained in the (100) plane of the conventional cell, and by doubling the cell along the original direction. The lattice mismatch is then given with regards to a (\sqrt{2}×\sqrt{2})R(45°) surface cell of STO as −9.0% for a_{S}=6.08 Å and −4.8% for b_{S}=5.81 Å. The additional domain orientations of β-Ga₂O₃ (1̅12) and (100) can be obtained by rotating the depicted surface-cells by multiples of 90° about the STO direction.

Motivated by the epitaxial matching, despite rotational symmetry mismatch, of monoclinic β-Ga₂O₃ and cubic SrTiO₃ (001), we have performed epitaxial integration with a 2-inch-diameter Si wafer using a SrTiO₃ buffer layer under nominally identical growth conditions as used for the bare STO substrate. The structural, morphology, and thickness characterization results are shown in FIGS. 28A, 28B, 29A-29C, 30A and 30B. FIGS. 30A and 30B are RHEED images for STO <100> and STO <110>, respectively, taken with a 15 keV electron beam of Ga₂O₃/SrTiO₃/Si. The RHEED pattern of FIG. 28 is qualitatively similar to the RHEED patterns of Ga₂O₃ grown on bulk STO, as shown in FIGS. 24A-24D. Differences in brightness and contrast are likely due to the use of a different RHEED chamber system with smaller electron beam energy, and larger wafer size allowing shallower incidence angle.

FIG. 31A depicts XRD patterns showing a θ-2θ diffractogram of a 15 nm film of Ga₂O₃ grown by PAMBE at 775° C. on the STO (100) buffer layer on Si. The diffractogram of FIG. 31A looks very similar to the diffraction patterns of Ga₂O₃ directly grown on STO, except for the finite-size oscillations of the STO (001) and (002) peaks and the presence of the Si substrate peaks. FIGS. 31B and 31C depict XRD patterns showing 0-20 diffractogram of in-plane XRD scans along STO and [100], respectively. The STO peaks are comparatively weak relative to the bulk substrate scans in FIGS. 25B and 25C. However, the same Ga₂O₃ peaks appear as for the case of the STO bulk substrate, although with different intensity ratios.

FIG. 32A depicts an XRR curve of Ga₂O₃ grown on STO-buffered Si. The simulation (red curve 3010) reveals a thickness of 15.4 nm for Ga₂O₃ and 18.2 nm for STO, which is consistent with the high resolution TEM cross-section images. FIG. 32B depicts a low-magnification TEM image of a 15-nm Ga₂O₃ film grown at 775° C. on STO-buffered Si (001) projected along the Si (110) zone-axis (equivalent to the STO (100) zone-axis). Columnar growth of Ga₂O₃ is observed along with a Moiré pattern caused by the overlap of granular but ordered crystallites. A thin SiO₂ interlayer can be observed between STO and the Si substrate.

Additional electron-energy-loss spectroscopy (EELS) experiments were performed on the β-Ga₂O₃ film grown on Si. A band gap of 4.5-5.2 eV is extracted from the fits, consistent with literature data for Ga₂O₃ [106]. For details see FIGS. 38A and 38B, discussed below.

### Discussion

Unlike the MOCVD growth of Ga₂O₃ on STO [122], in the present study we observe crystallization of Ga₂O₃ as-grown with the use of MBE and growth temperature of 670° C. Beside the (100)-orientation, we additionally observe the (1̅12) out-of-plane orientation of β-Ga₂O₃. The STO in this study is TiO₂-terminated due to the water treatment of the surface [135]. The TiO₂-plane contains an oxygen surface net that is like the face of an oxygen-based fcc cell and hence provides a template layer for the β-Ga₂O₃ distorted fcc oxygen sublattice. This fcc oxygen-sub-lattice of β-Ga₂O₃ has its six cube faces roughly aligned with the plane families {100}: (100), (1̅00); and {112}: (1̅12), (11̅2̅), (112̅), and (1̅1̅2). Furthermore, the Ga—O bonds of the distorted oxygen octahedra about the octahedral Ga2 sites of β-Ga₂O₃ are roughly aligned with the normal vectors of these planes. Hence, epitaxy on a cubic (001) substrate like SrTiO₃ is expected to be determined by the matching of these sub-lattice planes with the substrate basal plane in a “cube-on-cube” manner, and the octahedral cation-oxygen bonding direction being continued across the interface.

The (1̅12) family of surfaces do not appear to have been reported as growth surfaces for β-Ga₂O₃ bulk growth or epitaxy in the literature, and it is also not a commonly known surface cut for bulk substrates [107]. This may indicate that they are high energy surfaces, which is partially corroborated by the observations in this study that they are observed at high growth temperature. To support this assessment, we performed a detailed theoretical analysis. Using density functional theory, we calculated the surface energies of the (100) and (1̅12) surface terminations of β-Ga₂O₃.

To calculate the surface energy, we used the following relation:

$${Υ}_{surface} = \frac{1}{2 A} [ {E}_{slab} - {N}_{Ga} ( {E}_{Ga} + {μ}_{Ga} ) - \frac{1}{2} {N}_{O} ( {E}_{{O}_{2}} + {μ}_{{O}_{2}} ) ]$$

In this equation, Y_{surface} is the surface energy, A is the surface area with a factor of 2 accounting for the top and bottom surfaces, E_{slab} is the energy of the Ga₂O₃ slab, N_{Ga} (N_{O}) is the number of Ga (O) atoms in the Ga₂O₃ slab, E_{Ga} (E_{O}_{₂}) is the energy of one unit cell of bulk Ga (molecular O₂), and U_{Ga} (μ_{O}_{₂}) is the chemical potential of bulk Ga (molecular O₂). To simplify the number of variables in this equation, we use the relationship:

$${E}_{{Ga}_{2} {O}_{3}} + {μ}_{{Ga}_{2} {O}_{3}} = 2 ( {E}_{Ga} + {μ}_{Ga} ) + \frac{3}{2} ( {E}_{{O}_{2}} + {μ}_{{O}_{2}} )$$

The details of the methods used for these calculations are outlined, below, in the section entitled “Supplemental Material for Example 2.” For the (100) surface, we used two stoichiometric slabs and found that the surface energy of the mixed-terminated surface is 0.5 J/m² and it is 0.8 J/m² for the O-terminated surface. The surface energy values we have calculated are lower than the values reported by Bermudez who used different computational methods. However, we do find that the 0.3 J/m² difference in energy between the (100)-A and (100)-B is comparable to the energy difference of 0.5 J/m² reported by Bermudez. To our knowledge, calculations of the (1̅12) surface termination have not been reported previously. For the (1̅12) termination, we used a non-stoichiometric slab with a mixed-termination and found the surface energy is 4.0 J/m² in a Ga-rich environment and 2.0 J/m² in an O-rich environment. This suggests that thermodynamics would not favor the (1̅12) termination. However, thermal expansion mismatch and lattice mismatch to the substrate, or symmetry considerations as well as growth kinetics, could also play a crucial role in the observation of this growth surface for β-Ga₂O₃ on STO (001).

FIG. 33 depicts a plot of surface energies of several surface terminations along the (100), (1̅12), (2̅01), (310) and (101) surfaces with respect to the Ga chemical potential where 0 and −4.65 eV represent Ga-rich and O-rich environments, respectively. In FIG. 33, we compare the surface energies of the (100) and (1̅12) surfaces to several other β-Ga₂O₃ surface terminations we have previously reported [125], and confirm that the (100) mixed terminated surface is the most energetically stable surface termination under Ga- or O-rich environments whereas the (1̅12) surface termination is not energetically favorable when solely considering surface energies.

The horizontal RHEED spot spacings in FIGS. 24A and 24C along STO [100]-azimuths are 2.1±0.1 Å, commensurate with either β-Ga₂O₃ {11-2} planes of bulk lattice spacing 2.098 Å (for (100)-oop-orientation) or {600} of 1.979 Å (for {-1̅12} oop-orientation). The lattice spacings in FIGS. 26B and 24D along STO [110]-azimuths are 2.9±0.1 Å, commensurate with either β-Ga₂O₃ {020} of 1.518 Å and {−1,0,2} of 2.903 Å (for {100}-oop-orientation), or β-Ga₂O₃ {7,−1,−2} of 1.440 Å and {5,1,2} of 1.440 Å (for {-1̅12}-oop-orientation). The RHEED analysis is complicated by the multi-domain structure of the film and the large quantitative error inherent to this method, but the observed spacings are in good agreement with the expected values in comparison with the other structural results from XRD and TEM.

The epitaxial growth of (100) β-Ga₂O₃, even in the case of homo-epitaxy on a non-vicinal substrate, gives rise to stacking faults and twin boundaries (mirror about (100) with a c/2-glide) [137]. The mirror twin and stacking faults could possibly be avoided by using a vicinal (100) substrate with off-cut along at an optimal angle of ˜6°. Such substrates give rise to terrace steps formed by the energetically low (2̅01) surface facet (˜0.8 J/m²) of 1 ML height (1 ML=5.8 Å) preventing the stacking faults, as opposed to the high-energy (001) surface facet (˜1.25 J/m²) for off-cut along which shows 1-2 ML step heights [137]. Such faceting could also be a contributing factor to the roughening observed in these Ga₂O₃ thin films with increasing film thickness. For the hetero-epitaxy of β-Ga₂O₃ on STO (001), additional defects are expected based on the in-plane lattice mismatch and stacking faults due to the non-commensurate terrace step height of a_{STO}/2 for mixed-terminated STO or a_{STO} for singly terminated STO. Further, in-plane rotational variants are observed, due to the higher four-fold symmetry of STO in the growth plane compared to the low symmetry of monoclinic β-Ga₂O₃ [138, 139]. It should be mentioned that the (100) planes have a stacking height of 11.9 Å ˜3 a_{STO}=11.7 Å. Thus, in order to avoid stacking faults for (100) β-Ga₂O₃ it could be useful to achieve a step bunching of 3-unit-cell height on a vicinal STO substrate. The vicinal substrate could further contribute to reducing the number of in-plane variants of β-Ga₂O₃. Such an approach, using a vicinal substrate to suppress in-plane variants, has been used successfully in the hetero-epitaxy of β-Ga₂O₃ on corundum Al₂O₃[127]. The ML height for the (1̅12) planes is ˜2.1 Å and is therefore better matched to a single multiple of a_{STO}. We have observed no evidence for any γ-Ga₂O₃ interlayer by TEM or XRD.

### Concluding Remarks for Example 2

In summary, we have demonstrated the successful epitaxial integration of β-Ga₂O₃ on SrTiO₃ (001) and SrTiO₃-buffered Si (001). The films are crystalline as grown. Two basal growth planes (100) and (1̅12) of β-Ga₂O₃, each with four in-plane rotational domain variants, are observed. Small crystal grains result from the symmetry and lattice mismatch between film and substrate. STO serves as a buffer layer to prevent Si oxidation and reaction between Ga₂O₃ and Si during growth and also acts as a template to guide oxide-on-oxide epitaxial growth. The epitaxial integration of Ga₂O₃ with Si serves as a template layer for subsequent fast deposition methods and could enable the fabrication of large area wafers that in turn could advance Ga₂O₃-based technologies.

### Supplemental Material for Example 2

This supplementary material for Example 2 provides additional supporting figures and tables, electron energy loss spectroscopy measurements, and for the details of density functional calculations.

### Additional TEM Analysis

FIGS. 34A-34C depict cross-section TEM images taken along the STO zone axis at progressively higher magnification, as indicted by the scale bar. FIG. 34D depicts the FFT of FIG. 34C.

FIG. 35 depicts an indexing of FFT of a TEM image of 50-nm Ga₂O₃ film, consistent with the model of four rotational in-plane variants for the (100) and (1̅12) basal growth planes.

### X-Ray Photoelectron Spectroscopy

FIGS. 36A-36C: XPS data taken in situ after PAMBE growth of a 50 nm gallia film on STO with a VG Scienta spectrometer with monochromatic Al-Kα and R3000 hemispherical analyzer at 200 eV pass energy. FIG. 36A is a survey spectrum, no core-levels of Sr or Ti are observed, the film is therefore thicker than the information depth of the film layer (>5 EAL), no impurity elements or surface contamination within the accuracy of XPS. FIG. 36B is the O 1s core-level. FIG. 36C is the Ga 3p core-level. For the quantification of oxygen to gallium ratio in the gallia film we used the O 1s and Ga 3p core-levels. We obtain a ratio of 1.52, i.e., the oxygen and gallium percentages are 60% and 40%. Hence within the accuracy of XPS the film is stoichiometric Ga₂O₃.

### X-Ray Analysis Details

FIGS. 37A and 37B: Reciprocal space simulation δ-Ga₂O₃ (100) and (1̅12) basal in the (hk0) plane of STO. Each out-of-plane orientation should give rise to four rotational variants due to symmetry mismatch between the β-Ga₂O₃ growth planes and STO (001) [140, 141]. The color of the reciprocal lattice points fades between white and either orange or green, and the fading scales with the square of the structure factor for the given reflection. Lattice spacings consistent with the ones expected based on this model are observed along the anticipated directions in the in-plane XRD of FIGS. 27A-27C and the RHEED images of FIGS. 24A-24D.

The fitted peak positions and plane spacings in FIG. 27A-25C are given in FIGS. 38A-38C, discussed below, along with their deviation from the bulk values of β-Ga₂O₃. The assigned Miller indices are consistent with the reciprocal space simulation shown in FIG. 35. The fitted peak areas are not reported for the in-plane measurements since, in FIGS. 25B and 25C, those strongly depend on the incidence angle of the x-rays with respect to the film surface. The incident angle was set at @ ˜0.325° but may slightly change upon azimuthal rotation of the sample during measurement resulting in a non-constant incidence angle.

FIGS. 38A, 38B and 38C provide tables of fitted peak positions and determined lattice spacing from the peaks in FIGS. 25A, 25B and 25C, respectively. The peak assignments are labelled by their Miller indices and association with the basal growth plane is color-coded. The lattice spacing deviations from the bulk values are also given. Black/red/blue refers to peaks from the STO layer; orange is for peaks from β-Ga₂O₃ (100); and green is for peaks from β-Ga₂O₃ (1̅12).

### Lattice Matching

These cells shown in FIGS. 29A and 29B were obtained using the transformations given in Table 9, below, acting on the basis vectors of the conventional unit cell.

TABLE 9
Transformation matrices P used to create surface-oriented basis (\vec{a}_{S}, \vec{b}_{S}, \vec{c}_{S})
vectors of the cells depicted in FIGS. 29A and 29B from the conventional
basis (\vec{a}, \vec{b}, \vec{c}) according to the transformation (\vec{a}_{S}, \vec{b}_{S}, \vec{c}_{S}) =
(\vec{a}_{S}, \vec{b}_{S}, \vec{c}_{S})P.

| Surface Termination | Transformation Matrix P |
|---|---|
| (1̅12) | $( \begin{matrix}2 & 0 & 0 \\ 0 & 2 & 1 \\ 1 & - 1 & 0\end{matrix} )$ |
| (100) | $( \begin{matrix}0 & 0 & 1 \\ 2 & 0 & 0 \\ 0 & 1 & 0\end{matrix} )$ |

FIGS. 39A-39D illustrate mutual orientation of the parallelepipeds for the unit cells of (100)-β-Ga₂O₃ and (001)-STO. In FIG. 39A, the b-axis points along STO [1-10] and the c-axis along STO [110]. In FIGS. 39B-39D, epitaxial variants are related by a rotation about the z-axis of ϕ=n· 90°. The orientation of the conventional cell parallelepiped corresponding to (1-1-2)-β-Ga₂O₃ is not as easy to picture: The first variant corresponds to a −90° rotation about the y-axis of the β-Ga₂O₃ parallelepiped in FIG. 39A, indicated by the rotating arrow. The other in-plane variants of (1-1-2) are also related by 90°-rotations about the z-axis.

### Electron Energy Loss Spectroscopy

Additional electron-energy-loss spectroscopy (EELS) experiments were performed on the β-Ga₂O₃ film grown on Si. FIG. 40A depicts a plot showing the spectrum from the high binding energy side of the O 1s XPS peak. The loss onset is fitted by straight lines and a band gap of 4.5-5.2 eV is extracted from the fits, consistent with literature data for Ga₂O₃. [142] FIG. 40B depicts a plot showing the EEL spectrum from REELS experiments with low-incidence-angle electrons at 1.9 keV recorded under normal exit with a Staib Auger Probe. [143] (The negative intensity is attributed to a detector aberration). The band gap is underestimated due to the lower resolution of the measurement compared to FIG. 40A. The qualitative shape of the curve, however, agrees very well with the literature. [144, 145] For FIG. 40A, the EEL spectrum was obtained from the low kinetic energy side of the O 1s core-level in XPS with monochromatic Al-Kα and recorded with a VG Scienta R3000 analyzer with 200-eV pass energy and 0.8-mm slit size. For FIG. 40B, the EEL spectrum was obtained from REELS experiment with low-incidence-angle electrons at 1.9 keV recorded under normal exit.

### Density Functional Theory Calculations

To perform our calculations, we used density functional theory (DFT) as implemented in the Vienna ab Initio Simulation Package (VASP). [146] For the exchange energy correlation functional, we used the generalized-gradient approximation (GGA) parametrized by Perdew-Burke-Ernerhof (PBE). We use a cutoff energy of 500 eV for all bulk optimizations and 600 eV for all slab calculations. We use projector-augmented-wave potentials to describe Ga and O and the valence electron configurations used are 4s²3d¹⁰4p¹ for Ga and 2s²2p⁴ for O. Each self-consistent electronic calculation is converged to within 10⁻⁶ eV per cell, and the ionic relaxation is iterated until the forces are less than 0.01 eV/Å. For the Brillouin zone integration of bulk Ga₂O₃ (space group C2/m) and bulk Ga (space group Abma), 5×9×11 and 12×12×12 Monkhorst-Pack k-point grids are used, respectively. The lattice parameters calculated for bulk Ga₂O₃ are a=12.445, b=3.084 Å, c=5.876 Å, and B=103.73°, which compare favorably with the experimental values of a=12.22 Å, b=3.04 Å, c=5.80 Å, and β=103.75° and theoretical values of a=12.446, b=3.083 Å, c=5.876 Å, and β=103.70°. [149]

TABLE 10
Transformation matrices used to create surface-oriented unit cells along
the (1̅12) and (100) planes.

| Surface Termination | Transformation Matrix P |
|---|---|
| (1̅12) | $( \begin{matrix}- 0.5 & - 1.5 & - 1 \\ 0.5 & - 0.5 & 0 \\ 0 & 0 & - 1\end{matrix} )$ |
| (100) | $( \begin{matrix}0 & 1 & 0 \\ 0 & 0 & 1 \\ 1 & 0 & 0\end{matrix} )$ |

The transformation matrices used to create unit cells for each surface were derived using the methods described in reference and are provided in Table 10. For Brillouin zone integration of the (100) and (1̅12) slabs, 5×9×1 and 5×7×1 Monkhorst-Pack k-point meshes are used, respectively. Each slab was built using a supercell and vacuum regions that are at least 10 Å thick. FIGS. 39A-39C illustrate surfaces before and after relaxation superimposed for the (100) (FIG. 41A), (100)-A (FIG. 41B), and (1̅12) (FIG. 41C) mixed terminations. To determine the lowest energy surface reconstruction of the (100) plane, we study the two stoichiometric mixed-terminated surfaces, shown in FIGS. 39A and 39B. For the (1̅12) plane, we study one nonstoichiometric mixed-terminated surface shown in FIG. 41C.

TABLE 11
Computed surface energies (J m⁻²) for the
ideally terminated and reconstructed surfaces.

| | | Surface | Surface | |
|---|---|---|---|---|
| | | energy before | energyafter | Relaxation |
| Surface | Environment | relaxation | relaxation | energy |
| (100)-A | | 1.264 | 0.774 | 0.490 |
| (100)-B | | 0.688 | 0.459 | 0.229 |
| (112) | Ga-rich | 4.919 | 3.976 | 0.943 |
| | O-rich | 2.933 | 1.990 | |

To calculate the surface energy values listed in Table 11, we used the following relation:

$${Υ}_{surface} = ( 1 / 2 A ) [ {E}_{slab} - a ( {E}_{Ga} + {μ}_{Ga} ) - ( 1 / 2 ) {N}_{O} {{O}_{2}}_{} + {μ}_{{O}_{2}} ) ]$$

In this equation, Y surface is the surface energy, A is the surface area with a factor of 2 accounting for the top and bottom surfaces, E_{slab} is the energy of the Ga₂O₃ slab, N_{Ga} (N_{O}) is the number of Ga (O) atoms in the Ga₂O₃ slab, E_{Ga} (E_{O}_{₂}) is the energy of one unit cell of bulk Ga (molecular O2), and μ_{Ga} (μ_{O}_{₂}) is the chemical potential of bulk Ga (molecular O₂).

To simplify the number of variables in this equation, we use the relationship:

$${E}_{{Ga}_{2} {O}_{3}} + {μ}_{{Ga}_{2} {O}_{3}} = 2 ( {E}_{Ga} + {μ}_{Ga} ) + ( 3 / 2 ) ( {E}_{{O}_{2}} + {μ}_{{O}_{2}} ) -$$

Assuming the surface is in equilibrium with its own bulk, μ_{Ga}_{₃}_{O}_{₃} is equal to 0 eV. We define the formation energy of Ga₂O₃ as

$${E}_{f} = {E}_{{Ga}_{3} {O}_{3}} - 2 {E}_{Ga} - \frac{3}{2} {E}_{{O}_{2}} .$$

Using this definition and rearranging the previous equation, we define the chemical potential of bulk Ga as

$${μ}_{Ga} = \frac{1}{2} ( {E}_{f} - \frac{3}{2} {μ}_{{O}_{2}} ) .$$

We can then allow the chemical potential to vary over the range

$$0 \leq {μ}_{{O}_{2}} \leq \frac{2}{3} {E}_{f} ,$$

where μ_{O}_{₂}=0 eV and

$${μ}_{{O}_{2}} = \frac{2}{3} {E}_{f}$$

represent O-rich and Ga-rich conditions, respectively. We determined that the formation energy of Ga₂O₃ is −9.31 eV which is comparable to the formation energy value of −9.3 eV calculated by Zacherle et al. [149], but lower in magnitude compared to the experimental value of −11.3 eV [151].

### Example 3: Extension Cases for Examples 1-2

We present a route to integrate crystalline gallium oxide grown epitaxially on a silicon (001) substrate via an epitaxial strontium titanate (STO) buffer layer. Specifically, we produce samples with the following layer stack: silicon (001) substrate/thin film SrTiO₃ (buffer layer)/thin film Ga₂O₃. Such a materials system could be used as a seed layer for thick bulk-like MOCVD-grown Ga₂O₃ films or layers directly integrated on silicon, or can yield, via an etching process, free-standing gallium oxide films that can be transferred to other substrates. Gallium oxide is likely to find use in a wide variety of microelectronic (e.g., integrated circuits), micro-electromechanical system (MEMS), optoelectronic and power-electronics applications and devices. The STO buffer can be as thin as 5 nm or can be thicker (up to 20 nm) while the Ga₂O₃ epitaxial seed layer can range from 20 nm to 100 nm.

The layer stack according to the present technology has not previously been prepared, to the best of our knowledge. Present technologies for power-electronics applications tend to focus on millimeter-sized bulk-crystals of Ga₂O₃ grown by conventional crystal growth methods or thin films grown on isostructural substrates. The hetero-epitaxial integration of Ga₂O₃ onto silicon allows processing of gallium oxide technology in state-of-the-art semiconductor fabs specialized in the processing of silicon devices on large scale wafer diameters allowing for cost-effective production.

Ga₂O₃ cannot be directly grown on silicon due to a thermodynamically unstable interface favoring the formation of SiO₂ hence the SrTiO₃ seed, or buffer, layer is a crucial part of the present technology of epitaxial integration of Ga₂O₃ directly onto Si. The layer stacks according to the present technology enable the growth of large scale Ga₂O₃ bulk-like films on the Si wafer platform by serving as a template for subsequent fast deposition techniques like MOCVD or sputtering. An additional etching and polishing process could produce large scale free-standing Ga₂O₃ films that can be layer transferred to other substrates for use in power-electronics devices. Power-electronics devices may require large area, bulk-like, Ga₂O₃ crystals and therefore a substrate like silicon that is available in large wafer diameters (200-300 mm) is more suitable than the available isostructural substrates commonly used for hetero-epitaxy of Ga₂O₃. “Bulk-like” in this context refers to the Ga₂O₃ being epitaxial rather than polycrystalline, and with thicknesses on the order of microns.

The present technology has the advantage of integrating the wide-gap semiconductor Ga₂O₃ directly on the Si semiconductor platform for which many etching and processing technologies are widely available. The current hetero-epitaxial growth of Ga₂O₃ are limited to the small wafer sizes of the currently available substrate materials.

Since the silicon/STO platform is not very well lattice matched to Ga₂O₃, initially grown films are defective. However, if they act as a seed layer for further deposition of Ga₂O₃ by MOCVD or a similar method, this problem can be overcome as it is expected that the crystalline quality will drastically improve with increasing film thickness as long as there is a highly ordered nucleation layer. Furthermore, post-processing methods like annealing can further improve crystalline quality and polishing or etching can smoothen out a rough surface of such grown films to obtain high-quality free-standing Ga₂O₃ or Si/STO/Ga₂O₃ stacks. Another method to improve the lattice matching is to use a compositionally graded AlₓGa₁₋ₓO₃ alloy as the initial seed layer, as Al₂O₃ has a smaller lattice constant more closely-matched with STO.

Ga₂O₃ is a material with prospective use in high-power-electronics. In order to be useful for power-electronics applications, bulk-size crystals are needed. The size of currently grown epitaxial thin films is limited by the substrate wafer size.

The present technology comprises the epitaxial integration of a Ga₂O₃ layer on a silicon (001) substrate by means of a thin SrTiO₃ buffer layer. The present technology also enables the integration and processing of Ga₂O₃ directly into the silicon processing line and allows for growth on large scale wafer substrates.

Layer stacks according to the present technology would allow the growth of large scale Ga₂O₃ bulk-like films on the Si wafer platform, which are required for power-electronics applications of Ga₂O₃. The present technology opens the door for a multitude of new use cases that have not yet been considered. Ga₂O₃ is also a potential semiconductor for optoelectronic applications due to its large bandgap which makes it transparent into the UV range. The epitaxial integration onto silicon layer enables the construction of a wide range of novel devices relying on the electronic and optical properties of Ga₂O₃. Potential examples include field-effect transistors, semiconductor devices, and sensor technology.

FIGS. 42A and 42B illustrate a wafer according to some embodiments of the present technology. In one embodiment, as shown in FIG. 40A, the buffer layer is STO deposited onto Si according to the present technology. In an example, Ga₂O₃ is then deposited onto the STO layer. In another embodiment, as shown in FIG. 40B, STO is deposited onto Si and then a layer of γ-Al₂O₃ is then deposited onto the STO layer. In an example, Ga₂O₃ is then deposited onto the aforementioned Al₂O₃ layer.

FIG. 43 provides examples of combining oxides with semiconductors epitaxially. As described in A. A. Demkov and A. B. Posadas, “Integration of Functional Oxides with Semiconductors,” Spring, New York (2014), Si has been combined with perovskites and bixbyites. Other examples include spinel (MgAl₂O₄, γ-Al₂C), fluorite (e.g., CaF₂, ZrO₂), and rocksalt (e.g., MgO). Germanium has been combined with BaTiO₃ and Gd₂O₃. Silicon carbide has been combined with MgO and LiNbO₃.

As shown in FIGS. 44A-44E, difficulties of oxide/semiconductor epitaxy may arise from strain, thermal mismatch, wetting, and symmetry effects, as well as steps.

In one embodiment, gallia was grown on STO buffered Si under the following process conditions. The STO-buffered Si wafer was ex situ cleaned (acetone, 2-propanol, distilled water, each for minutes in sonicator). UHV was loaded on a molybdenum sample holder. Degassing was performed under O-plasma exposure (200 W, 3×10⁻⁵ torr O₂ partial pressure). Ga₂O₃ growth was done at 775° C. with O-plasma and Ga cell temperature of 880° C. Then, a cool down in O-plasma to 200° C. was done. In situ analysis included RHEED and XPS (using floodgun), and ex situ measurements were done using AFM, XRR and XRD. FIGS. 45A and 45B provide results of QCM flux measurements according to the example, where the Ga density used was 5.95 g/cm³ for QCM (Ga metal and Ga₂O₃ densities are almost identical). FIG. 45A shows the measured Ga flux in the absence of O-plasma of 1.35 Å/min (average min 20 to 44), while FIG. 45B shows the measured GaOₓ flux of 3.95 Å/min (average min 20 to 38), showing an increase in the accumulation rate by a factor of ˜2.9 in the presence of O-plasma.

FIGS. 46A-46C provide results of the analysis of the RHEED patterns in the example. For the analysis of the RHEED patterns, diffraction patterns emerged after ˜5 min of film growth in the example. Extracted plane spacings (normalized to STO azimuth) were consistent with (001)-oriented γ-Ga₂O₃ or a 4-domain (100)-oriented β-Ga₂O₃. FIG. 44A shows the STO layer azimuth from which the spot spacing is calibrated. FIG. 44B shows the b-Ga₂O₃ [020]/g-Ga₂O₃ azimuth with a measured spacing of 1.46 Å, while FIG. 44C shows the b-Ga₂O₃ [11-2]/g-Ga₂O₃ azimuth with a measured spacing of 2.05 Å.

FIGS. 47A-47C provide XPS results of the analysis in an example. The XPS results demonstrated a stoichiometry of O:Ga=˜60:40 (from O 1s & Ga 3p). The XPS results further showed a valence band shape characteristic of Ga₂O₃.

FIG. 48 provides XRR results of the analysis in the example. The data are shown as blue dots while the model fit is the solid red line (4610). The model fit indicates a 21 nm thickness for the Ga₂O₃ layer with a surface roughness of 11 Å.

FIGS. 49A and 49B illustrate differences between the crystal structures of β-Ga₂O₃ and γ-Ga₂O₃. As shown in this figure, γ-Ga₂O₃ can be considered a defective spinel structure with fractional occupancies.

FIG. 50 shows that the example provides a single domain structure 5.5% mismatch (compressive), which can be denoted as γ-Ga₂O₃ (001) [001]/STO (001) [100].

FIG. 51 illustrates expected epitaxy for β-Ga₂O₃ on STO (001), which is the same as that observed on MgO (100) substrates, for an example.

(100)-oriented β-Ga₂O₃ thin film is formed on the (100) MgO substrate with a fourfold domain structure rotated every 90°. In addition, the c-axis direction of β-Ga₂O₃ was parallel to the <011> direction of MgO. These results were the same as that observed for the crystal orientation of β-Ga₂O₃ formed on the (100) MgO substrate, as shown in reference [66], although different methods for film formation were employed. This should show the in-plane spacings (020) and (11-2) in RHEED & XRD at ˜45° (actual separation 46.3°) azimuthal direction.

FIG. 52 shows the expected 4-domain structure of β-Ga₂O₃ (100) [020] on STO (100) [110].

Table 11, below, provides the expected 20 peak positions in an out-of-plane XRD scan for the example.

TABLE 11
Expected 2θ peaks out-of-plane
LAMBA = 1.5406 Å

| | |
|---|---|
| STO: | (001) = 22.7535 |
| | (002) = 46.4721 |
| | (003) = 72.5668 |
| | (004) = 104.192 |
| γ-Ga₂O₃: | (004) = 43.9301 |
| | (008) = 96.849 |
| β-Ga₂O₃: | (200) = 14.9088 |
| | (400) = 30.0778 |
| | (600) = 45.811 |
| | (800) = 62.5237 |
| | (1000) = 80.8855 |

FIGS. 53A and 53B depict plots of out-of-plane (oop) XRD results for the example with sample label AF99. The plot on the left of FIG. 51A is the normal out of plane XRD identifying the presence of both b- and g-Ga₂O₃. The contour plot on the bottom right is a reciprocal space map of the scanned region. Some instrumental artifacts (“streaks”) are observable and identified as well.

FIGS. 54A and 54B depict combined in-plane 2q_{□}/f plots for the example taken along two different azimuths. The blue curves (5410) are taken along the STO azimuth, while the red curves (5420) are taken along the STO azimuth. FIG. 54A is a plot on a linear scale, while FIG. 54B provides curves 5430 (same data as 5410) and 5440 (same data as 5420) plotted on a log scale to better see the film peaks, which are to the left of the intense, narrow substrate peaks.

FIGS. 55A-55D depict peak decompositions of each of the four features in FIGS. 54A and 54B. The peaks are color-coded with the following scheme. Orange refers to g-Ga₂O₃, green is b-Ga₂O₃, blue is STO, and purple is unidentified. These results confirm the presence of both phases of Ga₂O₃.

Measured XRD reflections in the example indicated a mix of β and γ polymorphs. The following relation provides lattice constants d obtained from the Miller indices (hkl) for a monolithic crystal:

$$\frac{1}{{d}^{2}} = {h}^{2} \frac{1}{{a}^{2} {sin}^{2} β} + {k}^{2} \frac{1}{{b}^{2}} + {l}^{2} \frac{1}{{c}^{2} {sin}^{2} β} + h \cdot l \frac{cos β}{ac {sin}^{2} β}$$

where

$$\frac{1}{{a}^{2} {sin}^{2} β} ≡ {ξ}_{1} , \frac{1}{{b}^{2}} ≡ {ξ}_{2} , \frac{1}{{c}^{2} {sin}^{2} β} ≡ {ξ}_{3} , and \frac{cos β}{ac {sin}^{2} β} ≡ {ξ}_{4}$$

and where

ξ₄=\sqrt{ξ₁ξ₃} cos β

For the γ polymorph, a=8.01 Å (in-plane 20 nm film), and a=8.3 Å (oop RSM 50 nm film), compared to the bulk value of 8.23 Å. For the β polymorph, reflections were not sufficient to determine all lattice parameters (need on more lattice parameter off-symmetry). The b lattice parameter can be extracted as 2.99 Å (20 nm film), compared to the bulk value of 3.04 Å.

### Example 4: Extension Cases For Examples 1-3

Interfacing between the monoclinic β-gallia and silicon requires a buffer that grows epitaxially on silicon while at the same time having structural commonality with the β-gallia crystal structure. SrTiO₃ (STO) is well-known to be able to grow epitaxially on Si (100) also with 100 orientation. The b lattice vector and twice the c lattice vector match reasonably well with the STO (110) spacing. Thus, the β-Ga₂O₃ may grow with its bc-plane epitaxially aligned on the STO (001) surface with a 45° rotation. Additionally, the oxygen sublattice in this orientation of β-Ga₂O₃ is only a slightly distorted continuation from that in STO, which can allow for a low energy interface.

Another approach is to grow a buffer layer that has a crystal structure which Ga₂O₃ can also take. While the β-gallia structure is unique to Ga₂O₃, Ga₂O₃ can also undergo the corundum (α), spinel (γ), and bixbyite (d) crystal structures. Both spinel (γ-Al₂O₃) and bixbyite (rare earth oxides) materials have been demonstrated as epitaxial films on Si(100) previously. Such buffers may force the Ga₂O₃ to initially take these alternative crystal structures and transition to its normal β-gallia structure as it grows thicker. Because the atomic distortions among the different polymorphs is not large, such buffers may enable the continuation of the atomic structure from the buffer to the β-gallia structure. In the case of γ-Al₂O₃, it has been reported that when grown on Si (100), it initially grows pseudomorphically as γ-Al₂O₃ (100), but surface energy considerations cause it to transition to (111) orientation. The oxygen framework of γ-Al₂O₃ (111) (which is the same as corundum 0001) induces the (2̅01) plane of β-gallia to form in order to continue the oxygen sublattice via a γ-Ga₂O₃ (111) transition layer. The same mechanism is expected in the case of a bixbyite oxide (e.g., Gd₂O₃ or Er₂O₃) where the transition is through a thin layer of Δ-Ga₂O₃.

In some embodiments, use of compositional grading in the case of spinel or bixbyite buffers may alleviate lattice mismatch. For example, after the γ-Al₂O₃ layer, one may then switch to an intermediate AlGaO₃ composition before putting pure Ga₂O₃. In another embodiment, one can also use continuously graded layers AlₓGa₂₋ₓO₃ with x going from 1 to 0 smoothly, The same concept can be used for bixbyite oxides, e.g., Gd₂O₃ initially then GdxGa₂₋ₓO₃ then Ga₂O₃. Additionally, use of vicinal surfaces may eliminate other domains, as discussed above in Example 2.

### Example 5: Gallia on MgO-Buffered Silicon

### Experimental Conditions

In an experiment, to grow a Ga₂O₃ film on MgO-buffered Si, the Ga₂O₃ film was first grown on a single-side polished 10 mm×10 mm×0.5 mm MgO single crystal using rf magnetron sputtering to confirm that the deposition process and lattice matching would work. Prior to Ga2O3 deposition, the as-received MgO substrate was exposed, without any solvent cleaning, to 30 min of UV/ozone to volatilize any adsorbed hydrocarbon contaminants [154]. The MgO substrate was then outgassed at a substrate temperature of 700-800° C. in high vacuum (˜10⁻⁷ Torr) for 15 minutes to outgas the surface. After this substrate preparation, the Ga₂O₃ growth was done using off-axis rf magnetron sputtering in a gas mixture with 5 to 20% oxygen and with argon for the balance. The forward power used for the Ga₂O₃ deposition was 75 W (37 W/cm² power density). A substrate temperature of 700-800° C. and a total sputtering pressure of 15-25 mtorr were used for this process. These growth conditions resulted in a growth rate of 5.4 nm/min. It is theorized that other methods of depositing Ga₂O₃ should work as well so long as the growth rate is not too high to prevent epitaxy.

FIG. 56 provides a RHEED image of the Ga₂O₃ formed to confirm that the film is well-ordered with only two domains. The absence of secondary streaks within the image of FIG. 56 indicates a single crystallographic orientation. After formation of the Ga₂O₃ film, X-ray diffraction analysis was used to confirm that the film is purely 100-oriented β-Ga₂O₃ in the out of plane direction, with no significant amounts of the undesired (−112) orientation that shows up when the β-Ga₂O₃ is grown on STO. Film thickness analysis using x-ray reflection shows a Ga₂O₃ film thickness of 50 nm was formed using this process. Rocking curve analysis of the Ga₂O₃ (400) peak indicates a full-width-half-maximum of 2.5°.

After confirmation that the Ga₂O₃ film can be grown in a MgO without significant formation of undesirable orientations, we then grew the Ga₂O₃ film on MgO-buffered Si. The MgO buffer was formed by first outgassing the Si wafer at 700° C. then thermally desorbing the native SiO₂ layer at 900° C. Once a clean Si (001) surface is achieved, the substrate temperature is reduced to 350° C. and MgO is evaporated from single crystal pieces of MgO using electron beam evaporation. The MgO buffer layer is grown to a thickness of 8-10 nm prior to Ga₂O₃ deposition by off-axis sputtering, using the same growth conditions as for the trial growth on MgO single crystal. FIG. 57 provides a RHEED image along the direction of Ga₂O₃ film grown on MgO-buffered Si. The RHEED image illustrates that while there is some roughness and slight polycrystallinity (e.g., disorder), the overall crystallographic orientation of Ga₂O₃ film remains intact. The increased disorder of the Ga₂O₃ film is due to the somewhat lower MgO crystal quality when grown on Si due to partial plane tilting of MgO planes relative to Si to accommodate lattice mismatch. However, the Ga₂O₃ grown on top is still predominantly 100-oriented (no competing orientations) as confirmed by x-ray diffraction provided in FIG. 58.

Additionally, FIG. 59 provides an X-ray reflectivity analysis showing that the Ga₂O₃ film surface has a roughness of about 1.6 nm (compared to 0.4 nm when grown on single crystal MgO). As shown, the plot in FIG. 59 provides the X-ray reflectivity measurements (dots) and the fit (line) for a Ga₂O₃ film having a thickness of 59 nm on 8 nm thick MgO buffer layer formed on Si. The surface roughness parameter used to best fit the reflectivity model is 1.6 nm for the top surface and 0.8 nm for the interface.

### Example 6: Applications to Power Electronics

Larger breakdown fields can lead to the miniaturization of power electronic devices with associated reductions in cost and weight. The enhanced radiation hardness of Ga₂O₃ [6] additionally makes it suitable for space applications. Today an estimated 30% of all electricity flows through power electronics and this is projected to reach 80% in the future [7]. Efficient n-type doping of Ga₂O₃ can be achieved by Si, Ge, Sn and Nb incorporation [3]. Recently p-type doping with H has been demonstrated [8]. This, in combination with a way to create shallow p-type doping, could lead to realization of new kinds of optoelectronics operating in the deep-UV due to the large band gap of Ga₂O₃.

FIG. 60 is a diagram of transistor-type power electronic device 6000 embodied as an epi-Ga₂O₃ Power MOSFET, according to some embodiments of the present technology. In some embodiments, such a transistor 6000 may include an Si carrier 6010 serving the function of a substrate as well as a heat spreader. Transistor 6000 may include an epi-oxide buffer layer 6020 formed atop the Si carrier 6010, as shown in FIG. 60. In an example, Si carrier 6010 with epi-oxide buffer 6020 formed thereon may together comprise a wafer 6025 according to the present technology. In one example, epi-oxide buffer 6020 may be formed, at least in part, of at least one thin film layer of alumina formed on the Si carrier 6010, as described herein, for instance, with reference to Examples 1 and 6. In another example, epi-oxide buffer 6020 may be formed, at least in part, of at least one thin film layer of epitaxial STO formed on the Si carrier 6010, as described above, for instance, with reference to Examples 2 and 6 (see, e.g., FIG. 40A). In another example, epi-oxide buffer 6020 may be formed, at least in part, of at least one thin film layer of epitaxial STO formed on the Si carrier 6010, and then at least one layer of γ-Al₂O₃ deposited onto the STO layer(s), as described above, for instance, with reference to Examples 3 and 6 (see, e.g., FIG. 40B). In still another example, epi-oxide buffer 6020 may be formed, at least in part, of at least one thin film layer of epitaxial STO formed on the Si carrier 6010, and then at least one layer of a rare earth oxide, alumina, a gallium-rare earth oxide alloy, and/or a gallium-aluminum oxide alloy, as described above, for instance, with reference to Examples 4 and 6. In any of the aforementioned examples described above with reference to FIG. 60, the wafer 6025 may also include the thin film 6030 including a gallium oxide formed on the epi-oxide buffer layer 6020. Wafer 6025 may be manufactured for use in transistor 6000 using any of the processes or methods as described herein according to the present technology.

One or more additional layers of gallia may be formed on the thin film 6030 including a gallium oxide. In the embodiment illustrated in FIG. 60, a first layer 6035 is, or includes, undoped epitaxial Ga₂O₃ formed on the aforementioned thin film 6030. Next, at least a second layer 6040 is, or includes, lightly doped epitaxial Ga₂O₃ formed on the aforementioned first layer 6035. In the example shown in FIG. 60, the second layer 6040 is formed on the first layer 6035 over only a portion of the first layer 6035, so as to leave at least one (e.g., bordering) space(s). As such, transistor 6000 also includes at least one n+ block 6050 also formed atop portion(s) of the second layer 6040.

In some embodiments, as shown for example in FIG. 60, transistor 6000 may include a source 6060 formed atop a first n+ block 6050 and a drain 6070 formed atop a second n+ block 6050. In an example, an alumina layer 6080 may be formed atop another portion of the aforementioned second layer 6040. Transistor 6000 may also include a gate 6090 formed atop the alumina layer 6080. In power electronic devices according to the present technology embodied in transistor 6000 or equivalent devices readily envisaged and practiced by persons having ordinary skill in the art without undue experimentation, components such as the aforementioned source 6060, drain 6070 and gate 6090, and their functional equivalents, may receive and/or transmit electric current during operation of the power electronic device. Accordingly, such components may be referred to herein as means for transmitting and/or receiving a first, and at least a second, electric current coupled (e.g., electrically) to and/or from one or more portions of wafer 6025, as shown for example in FIG. 60.

FIG. 61 is a diagram of rectifier-type power electronic device 6000 embodied as a Ga₂O₃ vertical rectifier, according to some embodiments of the present technology. In some embodiments, such a rectifier 6100 may include a heavily doped (n+) Si carrier 6110. In a example, Si carrier 6110 may serve the function of a substrate as well as a heat spreader. Rectifier 6100 may include an epi-oxide buffer layer 6120 formed atop the Si carrier 6110, as shown in FIG. 61. In an example, Si carrier 6110 with epi-oxide buffer 6120 formed thereon may together comprise a wafer 6125 according to the present technology. In one example, epi-oxide buffer 6120 may be formed, at least in part, of at least one thin film layer of alumina formed on the Si carrier 6110, as described herein, for instance, with reference to Examples 1 and 6. In another example, epi-oxide buffer 6120 may be formed, at least in part, of at least one thin film layer of epitaxial STO formed on the Si carrier 6110, as described above, for instance, with reference to Examples 2 and 6 (see, e.g., FIG. 40A). In another example, epi-oxide buffer 6120 may be formed, at least in part, of at least one thin film layer of epitaxial STO formed on the Si carrier 6110, and then at least one layer of γ-Al₂O₃ deposited onto the STO layer(s), as described above, for instance, with reference to Examples 3 and 6 (see, e.g., FIG. 40B). In still another example, epi-oxide buffer 6020 may be formed, at least in part, of at least one thin film layer of epitaxial STO formed on the Si carrier 6110, and then at least one layer of a rare earth oxide, alumina, a gallium-rare earth oxide alloy, and/or a gallium-aluminum oxide alloy, as described above, for instance, with reference to Examples 4 and 6. In any of the aforementioned examples described above with reference to FIG. 61, the wafer 6125 may also include the thin film 6130 including a gallium oxide formed on the epi-oxide buffer layer 6120. Wafer 6125 may be manufactured for use in rectifier 6100 using any of the processes or methods as described herein according to the present technology.

One or more additional layers of gallia may be formed on the thin film 6130 including a gallium oxide. In the embodiment illustrated in FIG. 61, at least one layer 6140 is, or includes, lightly Si-doped epitaxial Ga₂O₃ (thickened) formed on the aforementioned thin film 6130. In some embodiments, as shown for example in FIG. 61, rectifier 6100 may include a bottom contact 6150 formed beneath Si carrier 6110 and a top contact 6160 formed atop the layer(s) 6140 of lightly Si-doped epitaxial Ga₂O₃ (thickened). In power electronic devices according to the present technology embodied in rectifier 6100 or equivalent devices readily envisaged and practiced by persons having ordinary skill in the art without undue experimentation, components such as the aforementioned contacts 6150 and 6160, and their functional equivalents, may receive and/or transmit electric current during operation of the power electronic device. Accordingly, such components may be referred to herein as means for transmitting and/or receiving a first, and at least a second, electric current coupled (e.g., electrically) to and/or from one or more portions of wafer 6125, as shown for example in FIG. 61.

Epitaxial growth onto Si wafers would open up numerous avenues for the large scale integration but, unfortunately, Ga₂O₃ cannot be directly grown on Si. In additional to the examples of power electronics devices described above with reference to FIGS. 54 and 55, a person of ordinary skill in the art is expected to readily envisage, and practice without undue experimentation, Si-based optoelectronic, MEMS, switching devices combined with a Ga₂O₃-based rectifier, monolithically integrated on a Si bulk substrate, and manufactured according to the present technology.

### CONCLUSION

The phrases “in some embodiments,” “according to some embodiments,” “in the embodiments shown,” “in other embodiments,” and the like generally mean the particular feature, structure, or characteristic following the phrase is included in at least one implementation of the present technology and may be included in more than one implementation. In addition, such phrases do not necessarily refer to the same embodiments or different embodiments.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “on,” “connected,” or “coupled” means having any attachment, connection or coupling, either direct or indirect, between two or more elements; the attachment, coupling. or connection between the elements can be physical, logical, or a combination thereof. Similarly, the phrase “directly on” means a direct attachment, connection, or coupling without any intermediate elements, layers, etc. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel, or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, various aspects may be presented in other system claims, composition of matter claims, method claims, or in other forms, such as being embodied in a means-plus-function claim. Any claims intended to be treated under 35 U.S.C. § 112(f) will begin with the words “means for”, but use of the term “for” in any other context is not intended to invoke treatment under 35 U.S.C. § 112(f). Accordingly, the applicant reserves the right to pursue additional claims after filing this application to pursue such additional claim forms, in cither this application or in a continuing application.

What is claimed is:

1. A wafer comprising:
a Si substrate;
a buffer layer comprising a thin film of at least one of epitaxial strontium titanate (STO) or magnesium oxide (MgO) formed on the Si substrate; and
a thin film comprising a gallium oxide formed on the buffer layer.

2. The wafer of claim 1, wherein the buffer layer comprises:
a first layer comprising the at least one of STO or MgO formed on the Si substrate; and
a second layer comprising an aluminum oxide formed on the first layer,
and wherein the thin film including the gallium oxide is formed on the second layer.

3. The wafer of claim 2, wherein the aluminum oxide comprises gamma-aluminum oxide (γ-Al₂O₃).

4. The wafer of claim 2, wherein the aluminum oxide comprises an aluminum-gallium alloy oxide.

5. The wafer of claim 1, wherein the thin film comprising the gallium oxide is integrated hetero-epitaxially onto the Si substrate via the buffer layer.

6. The wafer of claim 1, wherein the wafer further comprises one or more additional layers of a gallium oxide formed on the thin film comprising the gallium oxide.

7. The wafer of claim 6, wherein at least a first layer of the one or more additional layers of the gallium oxide comprises a layer of an aluminum-gallium alloy oxide formed on the thin film comprising the gallium oxide, and wherein at least a second layer of the one or more additional layers of the gallium oxide is formed on the layer of the aluminum-gallium alloy oxide.

8. The wafer of claim 1, wherein at least a portion of the thin film comprising gallium oxide comprises bulk-like crystals of gallium oxide.

9. The wafer of claim 1, wherein at least a portion of the thin film comprising the gallium oxide is gamma-gallium oxide (γ-Ga₂O₃).

10. The wafer of claim 1, wherein at least a portion of the thin film comprising the gallium oxide is beta-gallium oxide (β-Ga₂O₃).

11. A method of forming an epitaxial stack structure, wherein the method comprises comprising:
forming, on a silicon (Si) substrate, a buffer layer comprising at least one of strontium titanate (STO) or magnesium oxide (MgO); and
forming a thin film comprising gallium oxide on the buffer layer.

12. The method of claim 11, wherein forming the buffer layer comprises:
forming a first layer comprising the at least one of STO or MgO on the Si substrate;
forming a second layer comprising a seed layer on the first layer; and
wherein forming the thin film comprising the gallium oxide comprises forming the thin film comprising the gallium oxide on the second layer.

13. The method of claim 12, wherein forming the second layer comprises forming the seed layer comprising gamma-aluminum oxide (γ-Al₂O₃).

14. The method of claim 11, wherein forming the thin film comprising the gallium oxide comprises hetero-epitaxially integrating the thin film comprising the gallium oxide onto the Si substrate via the buffer layer.

15. The method of claim 11, wherein the method further comprises forming one or more additional layers of gallium oxide on the thin film comprising the gallium oxide.

16. The method of claim 15, wherein forming the one or more additional layers of gallium oxide comprises growing the one or more additional layers of gallium oxide on the thin film comprising the gallium oxide via chemical vapor deposition.

17. The method of claim 11 further comprising at least one of: etching, polishing, and annealing, at least a portion of the thin film comprising gallium oxide.

18. The method of claim 11, wherein forming the thin film comprising the gallium oxide comprises forming at least a portion of the thin film comprising the gallium oxide as (β-Ga₂O₃).

19. A power electronics device comprising:
a wafer comprising an epitaxial stack structure, wherein the epitaxial stack structure comprising a silicon (Si)-substrate and a thin film comprising gallium oxide;
means for receiving a first electric current coupled to a first portion of the wafer, and
means for transmitting a second electric current coupled to a second portion of the wafer.

20. The power electronics device of claim 19, wherein the power electronics device further comprises at least one of structural and functional components of: a rectifier, or a transistor.
